(19) United States
(12) Patent Application Publication
(10) Pub. No.: US 2023/0197746 A1
(43) Pub. Date: Jun. 22, 2023

(54) IMAGE SENSOR

(71) Applicant: Samsung Electronics Co., Ltd., Suwon-si (KR)

(72) Inventors: Minkwan KIM, Hwaseong-si (KR); Hyunchul Kim, Seoul (KR); Junhong Kim, Suwon-si (KR); Kwangmin Lee, Seoul (KR); Beomsuk Lee, Seoul (KR); Insung Joe, Seoul (KR); Jinsun Pyo, Suwon-si (KR)

(73) Assignee: Samsung Electronics Co., Ltd., Suwon-si (KR)

(21) Appl. No.: 18/066,656

(22) Filed: Dec. 15, 2022

(30) Foreign Application Priority Data
Dec. 17, 2021 (KR) 10-2021-0181501

(51) Int. Cl. H01L 27/146

(52) U.S. Cl. CPC H01L 27/1462; H01L 27/14645; H01L 27/14621; H01L 27/14636; H01L 27/1464; H01L 27/14685

(57) ABSTRACT

An image sensor includes a substrate having first and second surfaces opposing each other; photodiodes in the substrate; circuit and wiring structures below the first surface of the substrate; an insulating structure on the second surface of the substrate; a plurality of color filters on the insulating structure; and a grid structure on the insulating structure, wherein at least a portion of the grid structure is between adjacent color filters of, wherein the plurality of color filters include first and second color filters configured to selectively transmit light of different wavelength spectra associated with different colors, wherein the insulating structure includes a first and second regions having respective, different first and second thicknesses, and a boundary region between the first region and the second region that vertically overlaps the first color filter and is horizontally offset from a vertical central axis of the grid structure.

### CROSS-REFERENCE TO RELATED APPLICATION

This application claims benefit of priority under 35 U.S.C. § 119 to Korean Patent Application No. 10-2021-0181501 filed on Dec. 17, 2021 in the Korean Intellectual Property Office, the disclosure of which is incorporated herein by reference in its entirety.

### BACKGROUND

Some example embodiments of the present inventive concepts relate to image sensors.

An image sensor, capturing an image and converting the image into an electrical signal has been used in consumer electronic devices such as digital cameras, a camera for mobile phones and portable camcorders, and also in cameras mounted on vehicles, security devices, and robots. Since miniaturization and high resolution are required for such image sensors, various research has been conducted to satisfy the requirement.

### SUMMARY

Some example embodiments of the present inventive concepts provide image sensors having increased sensitivity.

According to some example embodiments of the present inventive concepts, an image sensor includes a substrate having first and second surfaces opposing each other; photodiodes in the substrate; circuit and wiring structures below the first surface of the substrate; an insulating structure on the second surface of the substrate; a plurality of color filters on the insulating structure; and a grid structure on the insulating structure, wherein at least a portion of the grid structure is between adjacent color filters of the plurality of color filters, wherein the plurality of color filters include a first color filter and a second color filter configured to selectively transmit light of different wavelength spectra associated with different colors, wherein the insulating structure includes a first region having a first thickness, a second region having a second thickness different from the first thickness, and a boundary region between the first region and the second region that vertically overlaps the first color filter and is horizontally offset from a vertical central axis of the grid structure.

According to some example embodiments of the present inventive concepts, an image sensor includes a substrate having first and second surfaces opposing each other; photodiodes in the substrate; circuit and wiring structures below the first surface of the substrate; an insulating structure on the second surface of the substrate; and a plurality of color filters on the insulating structure, wherein the plurality of color filters include a first color filter and a second color filter configured to selectively transmit light of different wavelength spectra associated with different colors, wherein the insulating structure includes a sequential stack of a lower layer, an intermediate layer and an upper layer, wherein the lower layer has a substantially uniform thickness, wherein the upper layer has a substantially uniform thickness, and wherein the intermediate layer includes two or more regions having different thicknesses from each other.

According to some example embodiments of the present inventive concepts, an image sensor includes a substrate having first and second surfaces opposing each other; photodiodes in the substrate; a separation structure between the photodiodes in the substrate; circuit and wiring structures below the first surface of the substrate; an insulating structure on the second surface of the substrate; a plurality of color filters on the insulating structure; and a grid structure on the insulating structure, wherein at least a portion of the grid structure is between adjacent color filters of the plurality of color filters, wherein the portion of the grid structure vertically overlaps at least a portion of the separation structure, wherein the plurality of color filters include a blue color filter configured to selectively transmit blue light, a green color filter configured to selectively transmit green light, and a red color filter configured to selectively transmit red light, wherein the insulating structure includes a sequential stack of a lower layer, an intermediate layer and an upper layer, wherein the lower layer has a substantially uniform thickness, wherein the upper layer has a substantially uniform thickness, wherein the intermediate layer includes two or more regions having different thicknesses from each other, wherein a minimum thickness of a first portion of the insulating structure vertically overlapping the blue color filter is smaller than a maximum thickness of a second portion of the insulating structure vertically overlapping the red color filter, and wherein the lower surface of the grid structure is flat such that the lower surface of the grid structure at least partially defines a plane extending parallel to at least one of the first surface or the second surface of the substrate.

### BRIEF DESCRIPTION OF DRAWINGS

The above and other aspects, features, and advantages of the present inventive concepts will be more clearly understood from the following detailed description, taken in combination with the accompanying drawings, in which:

FIG. 1 is a diagram illustrating an image sensor according to some example embodiments of the present inventive concepts, viewed from above;

FIG. 2 is a cross-sectional diagram illustrating an example of an image sensor according to some example embodiments of the present inventive concepts;

FIG. 3 is a cross-sectional diagram illustrating a modified example of an image sensor according to some example embodiments of the present inventive concepts;

FIG. 4A is a cross-sectional diagram illustrating a modified example of an image sensor according to some example embodiments of the present inventive concepts;

FIG. 4B is a cross-sectional diagram illustrating a modified example of an image sensor according to some example embodiments of the present inventive concepts;

FIG. 4C is a cross-sectional diagram illustrating a modified example of an image sensor according to some example embodiments of the present inventive concepts;

FIG. 4D is a cross-sectional diagram illustrating a modified example of an image sensor according to some example embodiments of the present inventive concepts;

FIG. 5 is a diagram illustrating an image sensor according to some example embodiments of the present inventive concepts, viewed from above;

FIG. 6 is a cross-sectional diagram illustrating an example of an image sensor according to some example embodiments of the present inventive concepts;

FIG. 7 is a cross-sectional diagram illustrating a modified example of an image sensor according to some example embodiments of the present inventive concepts;

FIG. 8A is a cross-sectional diagram illustrating a modified example of an image sensor according to some example embodiments of the present inventive concepts;

FIG. 8B is a cross-sectional diagram illustrating a modified example of an image sensor according to some example embodiments of the present inventive concepts;

FIG. 9A is a cross-sectional diagram illustrating a modified example of an image sensor according to some example embodiments of the present inventive concepts;

FIG. 9B is a cross-sectional diagram illustrating a modified example of an image sensor according to some example embodiments of the present inventive concepts;

FIG. 10 is a diagram illustrating an image sensor according to some example embodiments of the present inventive concepts, viewed from above;

FIG. 11 is a cross-sectional diagram illustrating an example of an image sensor according to some example embodiments of the present inventive concepts;

FIG. 12 is a cross-sectional diagram illustrating a modified example of an image sensor according to some example embodiments of the present inventive concepts;

FIG. 13 is a cross-sectional diagram illustrating a modified example of an image sensor according to some example embodiments of the present inventive concepts;

FIG. 14 is a cross-sectional diagram illustrating a modified example of an image sensor according to some example embodiments of the present inventive concepts;

FIG. 15 is a diagram illustrating an image sensor according to some example embodiments of the present inventive concepts, viewed from above;

FIG. 16 is a cross-sectional diagram illustrating an example of an image sensor according to some example embodiments of the present inventive concepts;

FIG. 17 is a cross-sectional diagram illustrating a modified example of an image sensor according to some example embodiments of the present inventive concepts;

FIG. 18A is a cross-sectional diagram illustrating a modified example of an image sensor according to some example embodiments of the present inventive concepts;

FIG. 18B is a cross-sectional diagram illustrating a modified example of an image sensor according to some example embodiments of the present inventive concepts;

FIG. 19 is a diagram illustrating an image sensor according to some example embodiments of the present inventive concepts, viewed from above;

FIG. 20 is a cross-sectional diagram illustrating an example of an image sensor according to some example embodiments of the present inventive concepts;

FIG. 21 is a cross-sectional diagram illustrating a modified example of an image sensor according to some example embodiments of the present inventive concepts;

FIG. 22 is a cross-sectional diagram illustrating a modified example of an image sensor according to some example embodiments of the present inventive concepts;

FIG. 23 is a cross-sectional diagram illustrating a modified example of an image sensor according to some example embodiments of the present inventive concepts;

FIG. 24 is a diagram illustrating an image sensor according to some example embodiments of the present inventive concepts, viewed from above;

FIG. 25 is a cross-sectional diagram illustrating an example of an image sensor according to some example embodiments of the present inventive concepts;

FIG. 26 is a cross-sectional diagram illustrating a modified example of an image sensor according to some example embodiments of the present inventive concepts;

FIG. 27 is a cross-sectional diagram illustrating a modified example of an image sensor according to some example embodiments of the present inventive concepts;

FIG. 28 is a cross-sectional diagram illustrating a modified example of an image sensor according to some example embodiments of the present inventive concepts;

FIG. 29 is a diagram illustrating an image sensor according to some example embodiments of the present inventive concepts, viewed from above;

FIG. 30 is a cross-sectional diagram illustrating an example of an image sensor according to some example embodiments of the present inventive concepts;

FIG. 31 is a cross-sectional diagram illustrating a modified example of an image sensor according to some example embodiments of the present inventive concepts;

FIG. 32 is a diagram illustrating an image sensor according to some example embodiments of the present inventive concepts, viewed from above;

FIG. 33 is a cross-sectional diagram illustrating an example of an image sensor according to some example embodiments of the present inventive concepts;

FIG. 34 is a cross-sectional diagram illustrating a modified example of an image sensor according to some example embodiments of the present inventive concepts;

FIG. 35 is a diagram illustrating an image sensor according to some example embodiments of the present inventive concepts, viewed from above;

FIG. 36 is a cross-sectional diagram illustrating an example of an image sensor according to some example embodiments of the present inventive concepts;

FIG. 37 is a diagram illustrating an image sensor according to some example embodiments of the present inventive concepts, viewed from above;

FIG. 38 is a cross-sectional diagram illustrating an example of an image sensor according to some example embodiments of the present inventive concepts;

FIG. 39 is a diagram illustrating an image sensor according to some example embodiments of the present inventive concepts, viewed from above;

FIG. 40 is a cross-sectional diagram illustrating an example of an image sensor according to some example embodiments of the present inventive concepts;

FIG. 41 is a diagram illustrating an image sensor according to some example embodiments of the present inventive concepts, viewed from above;

FIG. 42 is a cross-sectional diagram illustrating an example of an image sensor according to some example embodiments of the present inventive concepts;

FIG. 43 is a diagram illustrating an image sensor according to some example embodiments of the present inventive concepts, viewed from above;

FIG. 44 is a diagram illustrating an image sensor according to some example embodiments of the present inventive concepts, viewed from above;

FIG. 45 is a diagram illustrating an image sensor according to some example embodiments of the present inventive concepts, viewed from above;

FIGS. 46 and 47 are graphs illustrating properties of an image sensor according to some example embodiments of the present inventive concepts;

FIG. 48 is a flowchart illustrating processes of a method of manufacturing an image sensor according to some example embodiments of the present inventive concepts;

FIGS. 49, 50A, 50B, and 50C are diagrams illustrating a method of manufacturing an image sensor according to some example embodiments of the present inventive concepts; and

FIGS. 51, 52A, 52B, and 52C are diagrams illustrating a method of manufacturing an image sensor according to some example embodiments of the present inventive concepts.

### DETAILED DESCRIPTION

Hereinafter, some example embodiments of the present inventive concepts will be described as follows with reference to the accompanying drawings.

Hereinafter, terms such as ‘on,’ ‘upper portion,’ ‘upper surface,’ ‘below,’ ‘lower portion,’ ‘lower surface,’ ‘side surface,’ and the like can be understood as referring to the spatial relationship between elements, components, regions, layers, and/or sections, based on the orientation of those elements, components, regions, layers, and/or sections in the drawings, unless otherwise indicated.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present such that the element and the other element are isolated from direct contact with each other by one or more interposing spaces and/or structures. In contrast, when an element is referred to as being “directly on” another element, there are no intervening elements present such that the element and the other element are in direct contact with each other. As described herein, an element that is “on” another element may be above, beneath, and/or horizontally adjacent to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, elements that are described to be in contact with other elements may be understood to be in “direct” contact with the other elements.

As described herein, an element that is described to be “spaced apart” from another element, in general and/or in a particular direction (e.g., vertically spaced apart, laterally spaced apart, etc.) may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) may be understood to be isolated from direct contact with each other, in general and/or in the particular direction (e.g., isolated from direct contact with each other in a vertical direction, isolated from direct contact with each other in a lateral or horizontal direction, etc.).

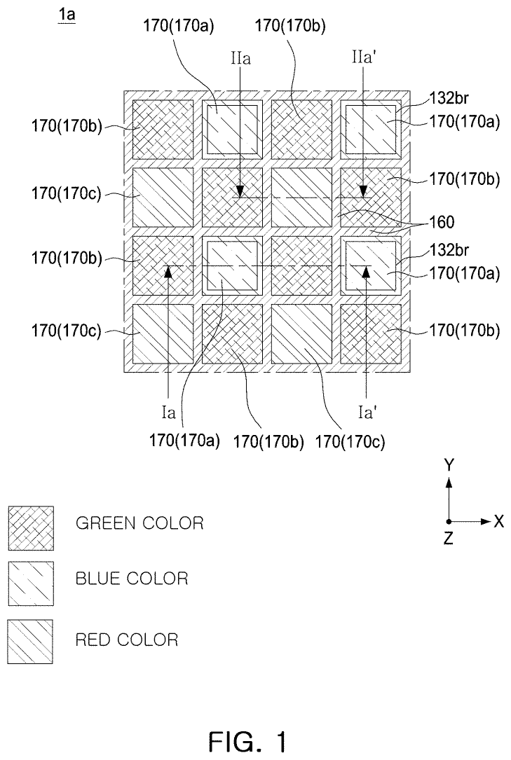

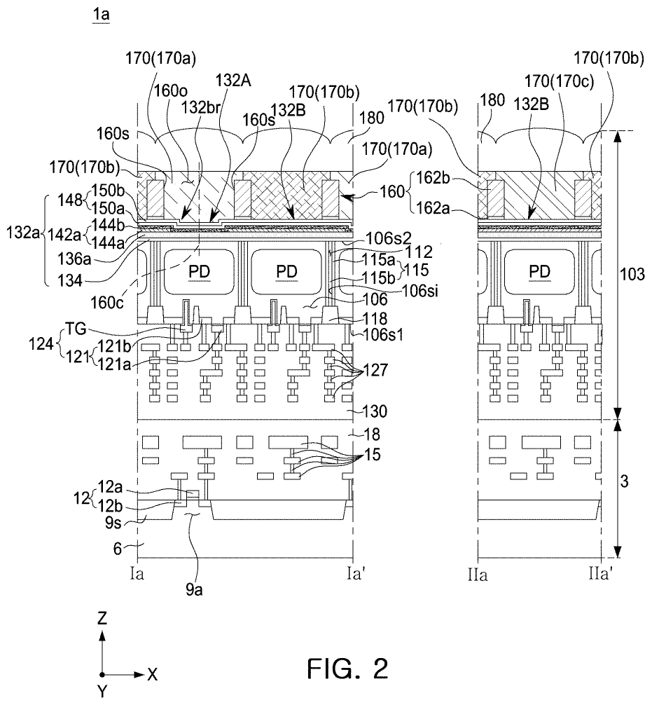

some example embodiments of an image sensor in some example embodiments will be described with reference to FIGS. 1 and 2.

FIG. 1 is a diagram illustrating an image sensor according to some example embodiments, viewed from above. FIG. 2 is a cross-sectional diagram illustrating regions taken along lines Ia-Ia′ and IIa-IIa′ in FIG. 1 according to some example embodiments.

Referring to FIGS. 1 and 2, an image sensor 1a may include a first chip structure 3 and a second chip structure 103 on the first chip structure 3. The first chip structure 3 may be configured as a logic chip, and the second chip structure 103 may be configured as an image sensor chip. In some example embodiments, the first chip structure 3 may be configured as a stack chip structure including a logic chip and a memory chip.

The first chip structure 3 of the image sensor 1a may include a first substrate 6, a device isolation layer 9s defining an active region 9a on the first substrate 6, a first circuit device 12 and a first wiring structure 15 on the first substrate 6, and a first insulating layer 18 covering the first circuit device 12 and the first wiring structure 15 covering the first substrate 6.

The first substrate 6 may be a semiconductor substrate. For example, the first substrate 6 may be a substrate formed of a semiconductor material, such as, for example, a single crystal silicon substrate. The first circuit device 12 may include a device such as a transistor including a gate 12a and a source/drain 12b.

The second chip structure 103 may include a second substrate 106 having a first surface 106s1 and a second surface 106s2 opposing each other, a device isolation layer 118 disposed on the first surface 106s1 of the second substrate 106 and defining an active region, a second circuit device 124 disposed between the first surface 106s1 of the second substrate 106 and the first chip structure 3, and a second insulating layer 130 covering the second circuit device 124 and the second wiring structure 127 between the first surface 106s1 of the second substrate 106 and the first chip structure 3. A first surface 106s1 of the second substrate 106 may oppose the first chip structure 3. The first circuit device 12, the first wiring structure 15, the second circuit device 124 and the second wiring structure 127 may be circuit and wiring structures. Accordingly, the image sensor 1 may be include the circuit and wiring structures 12, 15, 124 and 127 disposed below the first surface 106s1 of the second substrate 106.

The second substrate 106 may be a semiconductor substrate. For example, the second substrate 106 may be a substrate formed of a semiconductor material, such as, for example, a single crystal silicon substrate.

The image sensor 1a may further include photoelectric conversion devices PD. The photoelectric conversion devices PD may generate and accumulate electric charges corresponding to incident light. For example, the photoelectric conversion devices PD may include a photodiode, a phototransistor, a photogate, a pinned photodiode (PPD), and combinations thereof.

The photoelectric conversion devices PD may be formed in the second substrate 106 and may be spaced apart from each other.

The second chip structure 103 may further include a separation structure 115. The separation structure 115 may be disposed to surround each of the photoelectric conversion devices PD. The separation structure 115 may be disposed in the opening 112 penetrating through the second substrate 106.

The separation structure 115 may penetrate through the second substrate 106. The opening 112 may be connected to the device isolation layer 118. Accordingly, the separation structure 115 may be connected to the device isolation layer 118. The device isolation layer 118 may be formed of an insulating material such as silicon oxide. The separation structure 115 may include a separation pattern 115b and a separation insulating layer 115a covering a side surface of the separation pattern 115b. For example, the separation insulating layer 115a may include silicon oxide, and the separation pattern 115b may include polysilicon.

The second circuit device 124 may include a transfer gate TG and active elements 121. The active elements 121 may be configured as transistors including a gate 121a and a source/drain 121b. The transfer gate TG may transfer electric charges from an adjacent photoelectric conversion device PD to an adjacent floating diffusion region, and the active elements 121 may be configured as at least one of a source-follower transistor, a reset transistor, and a select transistor.

The transfer gate TG may be configured as a vertical transfer gate including a portion extending into the second substrate 106 from the first surface 106s1 of the second substrate 106.

The second wiring structure 127 may include a plurality of layers of interconnection lines disposed on different levels, and vias electrically connecting the plurality of layers of the interconnection lines to each other and electrically connecting the plurality of layers of the interconnection lines to the second circuit device 124.

The first insulating layer 18 and the second insulating layer 130 may be in contact with and bonded to each other. Each of the first and second insulating layers 18 and 130 may be formed as a plurality of layers including different types of insulating layers. For example, the second insulating layer 130 may be formed as a multilayer including at least two types or more of a silicon oxide layer, a low dielectric layer, and a silicon nitride layer.

The second chip structure 103 may further include an insulating structure 132a disposed on the second surface 106s2 of the second substrate 106. The insulating structure 132a may cover the separation structure 115.

The second chip structure 103 may include the grid structure 160. The grid structure 160 may be disposed on the insulating structure 132a.

The grid structure 160 may include a first layer 162a and a second layer 162b stacked in sequence. It will be understood that elements herein described to be “stacked in sequence” may be referred to as a “sequential stack” of said elements. The first layer 162a may be in contact with the insulating structure 132. A thickness of the second layer 162b may be greater than a thickness of the first layer 162a. As described herein, a “thickness” of a layer may refer to a thickness of the layer in the Z direction perpendicular to the first surface 106s1 and/or second surface 106s2 of the substrate 106.

The first layer 162a may include a first material, and the second layer 162b may include a second material different from the first material.

In some example embodiments, the first material of the first layer 162a may include a conductive material. For example, the first layer 162a may be formed of a conductive material including at least one of a metal or a metal nitride. For example, the first layer 162a may include at least one of Ti, Ta, TiN, TaN, and W.

In some example embodiments, the second material of the second layer 162b may include an insulating material. The second material of the second layer 162b may be configured as a low refractive index (LRI) material. For example, a refractive index of the second layer 162b may be in a range of about 1.1 to about 1.8. The second layer 162b may include an oxide or nitride including Si, Al, or a combination thereof. For example, the second layer 162b may include silicon oxide having a porous structure or silica nanoparticles having a network structure.

The first layer 162a formed of a conductive material may work as a charge path for removing charges, and the second layer 162b may not include a conductive material reducing sensitivity in pixel regions and may be formed of a low refractive index (LRI) material, such that an optical cross-talk phenomenon of the image sensor 1a may be addressed.

The second chip structure 103 may further include the color filters 170 including first to third color filters 170a, 170b, and 170c. The color filters 170 may include first color filters 170a of a first color, second color filters 170b of a second color different from the first color, and third color filters 170c of a third color different from the first and second colors. For example, the first color filters 170a may be blue color filters, the second color filters 170b may be green color filters, and the third color filters 170c may be red color filters.

As described herein, each color filter that is described to be or have a particular “color” may be interchangeably referred to as being configured to selectively transmit light of a particular wavelength spectrum associated with the particular color (e.g., red light, blue light, green light, or the like), which may further be interchangeably referred to as selectively transmitting the particular color (e.g., selectively transmitting a red color, a blue color, a green color, or the like). For example, as described herein, a blue color filter may be understood to be configured to selectively transmit light of a blue wavelength spectrum (e.g., blue light) and thus may be understood to be configured to selectively transmit a blue color, a green color filter may be understood to be configured to selectively transmit light of a green wavelength spectrum (e.g., green light) and thus may be understood to be configured to selectively transmit a green color, and a red color filter may be understood to be configured to selectively transmit light of a red wavelength spectrum (e.g., red light) and thus may be understood to be configured to selectively transmit a red color. Additionally, color filters described herein to have different colors from each other may be understood to be configured to selectively transmit light of different wavelength spectra associated with different colors, also referred to as being configured to selectively transmit different colors. For example, a first color filter 170a and a second color filter 170b may be configured to selectively transmit light of different wavelength spectra associated with different colors (e.g., blue and green light, respectively), and a third color filter 170c may be configured to selectively transmit a wavelength spectrum of light that is different from wavelength spectra of light selectively transmitted by either of the first color filter 170a or the second color filter 170b (e.g., red light).

The color filters 170 may be disposed on the insulating structure 132a. The color filters 170 may allow light of a specific wavelength to pass and to reach the photoelectric conversion devices PD. For example, the color filters 170 may be formed of a material in which a pigment including a metal or a metal oxide is mixed with a resin. A thickness of each of the color filters 170 may be greater than a thickness of the grid structure 160. The color filters 170 may cover the grid structure 160 on the insulating structure 132a. The color filters 170 may cover side surfaces and upper surfaces of the grid structure 160 on the insulating structure 132a.

As shown, in some example embodiments, at least a portion of the grid structure 160 may be between adjacent color filters of the among the first to third color filters 170a, 170b, and 170c. In some example embodiments, the grid structure 160 may be disposed between filters of different colors among the first to third color filters 170a, 170b, and 170c.

In some example embodiments, the grid structure 160 may vertically overlap the separation structure 115. As described herein, elements that “vertically overlap” other elements may be understood to vertically overlap the other elements, for example, in the Z direction perpendicular to the first surface 106s1 and/or second surface 106s2 of the second substrate 106.

In some example embodiments, the grid structure 160 may have a width different from that of the separation structure 115. For example, a width of the grid structure 160 may be greater than a width of the separation structure 115.

The second chip structure 103 may further include microlenses 180 on the color filters 170. The microlenses 180 may overlap the photoelectric conversion devices PD, respectively. Each of the microlenses 180 may have a curved shape, curved in a direction away from the first chip structure 3. The microlenses 180 may condense incident light into the photoelectric conversion devices PD. The microlenses 180 may be formed of a transparent photoresist material or a transparent thermosetting resin material. For example, the microlenses 180 may be formed of a TMR-based resin (manufactured by Tokyo Ohka Kogo, Co.) or an MFR-based resin (manufactured by Japan Synthetic Rubber Corporation), but some example embodiments thereof is not limited thereto.

The insulating structure 132a may include an anti-reflective layer which may reduce or prevent reflection of light caused by a sudden change in refractive index on the second surface 106s2 of the second substrate 106, which may be formed of silicon. For example, the insulating structure 132a may include a plurality of layers stacked in sequence. The insulating structure 132a may include an anti-reflective layer which may provide incident light to travel to the photoelectric conversion devices PD with high transmittance by adjusting a refractive index. For example, the insulating structure 132a may include at least three layers. Accordingly, the insulating structure 132a may be referred to as an anti-reflective structure.

In some example embodiments, the insulating structure 132a may include a lower layer 134, an intermediate layer 136a and 142a on the lower layer 134, and an upper layer 148 on the intermediate layer 136a and 142a.

The lower layer 134 may be in contact with the second surface 106s2 of the second substrate 106. The lower layer 134 may have transmittance in a visible wavelength, and may include a material exhibiting a negative charge for reducing or preventing charges by a dangling bond of the second surface 106s2 of the second substrate 106. The intermediate layers 136a and 142a may have transmittance in a visible wavelength, and may including a material which may adjust a peak of transmittance by adjusting a thickness. The upper layer 148 may have transmittance in a visible wavelength, and may include a material passivating the intermediate layers 136a and 142a.

The lower layer 134 may include a material having a first refractive index, such as, for example, a material having a refractive index of about 2, the intermediate layers 136a and 142a may include a material having a second refractive index smaller than the first refractive index, such as, for example, a material having a refractive index of about 1.5, and the upper layer 148 may include a material having a refractive index greater than the second refractive index, such as, for example a material having a refractive index of about 2.

The lower layer 134 may include a high-κ dielectric, such as, for example, aluminum oxide.

The intermediate layers 136a and 142a may include a first intermediate layer 136a and a second intermediate layer 142a stacked in sequence.

The first intermediate layer 136a may include a material different from the material of the lower layer 134 and the material of the second intermediate layer 142a. For example, the first intermediate layer 136a may include a high-κ material different from that of the lower layer 134. For example, the first intermediate layer 136a may include hafnium oxide. The second intermediate layer 142a may include silicon oxide.

A thickness of the first intermediate layer 136a may be greater than a thickness of the lower layer 134.

The upper layer 148 may include at least one material layer. The upper layer 148 may include at least two layers. For example, the upper layer 148 may include a first upper layer 150a and a second upper layer 150b stacked in sequence. For example, in the upper layer 148, the first upper layer 150a may include a hafnium oxide layer, and the second upper layer 150b may include an aluminum oxide layer.

The first upper layer 150a of the upper layer 148 may be formed of the same material as that of the first intermediate layer 136a, such as, for example, hafnium oxide. The second upper layer 150b of the upper layer 148 may be formed of the same material as that of the lower layer 134, such as, for example, aluminum oxide. The second upper layer 150b of the upper layer 148 may have substantially the same thickness as that of the lower layer 134. The second upper layer 150b of the upper layer 148 may be in contact with the color filters 170 and the grid structure 160.

The insulating structure 132a may include a first region 132A having a first thickness and a second region 132B having a second thickness different from the first thickness. The second thickness may be greater than the first thickness.

In the second region 132B of the insulating structure 132a, the second intermediate layer 142a may include a first layer 144a and a second layer 144b stacked in sequence, and, in the first region 132A of the insulating structure 132a, the second intermediate layer 142a may include the second layer 144b. Accordingly, the second intermediate layer 142a may include a relatively thick portion including the first and second layers 144a and 144b and a relatively thin portion including the second layer 144b. According to the thickness difference depending on the position of the second intermediate layer 142a, there may be a difference in thickness between the first and second regions 132A and 132B of the insulating structure 132a.

In the second intermediate layer 142a, the first layer 144a and the second layer 144b may be formed of the same material, such as, for example, silicon oxide.

In the second intermediate layer 142a, a maximum thickness portion, such as, for example, the thickness of the thick portion including the first and second layers 144a and 144b, may be greater than a thickness of the lower layer 134.

In the second intermediate layer 142a, a maximum thickness portion, such as, for example, the thickness of the thick portion including the first and second layers 144a and 144b, may be greater than a thickness of the first intermediate layer 136a.

In the second intermediate layer 142a, a minimum thickness portion, such as, for example, the thickness of the thin portion including the second layer 144b, may be greater than a thickness of the lower layer 134.

In the second intermediate layer 142a, a minimum thickness portion, such as, for example, a thickness of the thin portion including the second layer 144b may be different from a thickness of the first intermediate layer 136a. In some example embodiments, in the second intermediate layer 142a, a minimum thickness portion, such as, for example, the thin portion including the second layer 144b may be smaller than a thickness of the first intermediate layer 136a. In some example embodiments, in the second intermediate layer 142a, a minimum thickness portion, such as, for example, a thickness of the thin portion including the second layer 144b may be greater than a thickness of the first intermediate layer 136a.

The grid structure 160 may be disposed on the second region 132B of the insulating structure 132a. The grid structure 160 may be in contact with the second region 132B of the insulating structure 132a and may be spaced apart from the first region 132A of the insulating structure 132a. Accordingly, the lower surface of the grid structure 160 may be disposed on a constant level when viewed with respect to the second surface 106s2 of the second substrate 106. That is, the lower surface of the grid structure 160 may be flat (e.g., may at least partially define and/or be coplanar with a plane that is parallel to the first surface 106s1 and/or second surface 106s2 of the second substrate 106.

The second region 132B of the insulating structure 132a may be in contact with the second and third color filters 170b and 170c, and may be in contact with an edge portion of each of the first color filters 170a. A central portion of each of the first color filters 170a may be in contact with the first region 132A of the insulating structure 132a. In each of the first color filters 170a, the edge portion may have a shape surrounding the center portion.

The second region 132B of the insulating structure 132a may vertically overlap an edge portion of each of the first color filters 170a, the second and third color filters 170b and 170c, and the grid structure 160, and the first region 132A of the insulating structure 132a may vertically overlap a central portion of each of the first color filters 170a.

In the insulating structure 132a, a region in which the thickness changes, that is, a boundary region 132br between the first region 132A and the second region 132B, may vertically overlap the first color filters 170a, may be spaced apart from side surfaces of the first color filters 170a, and may be spaced apart from the grid structure 160. In the insulating structure 132a, the boundary region 132br between the first region 132A and the second region 132B may vertically overlap (e.g., overlap in the Z direction perpendicular to the first surface 106s1 and/or second surface 106s2 of the second substrate 106 at least a portion of the first color filter 170a, and may be misaligned with the vertical central axis of the grid structure 160 (e.g., horizontally offset, for example in the X direction and/or Y direction parallel to the first surface 106s1 and/or second surface 106s2 of the second substrate 106 from a vertical central axis 160c of the grid structure 160 which extends vertically (e.g., in the Z direction), for example through a center of an opening 160o defined by opposing surfaces 160s of the grid structure 160.

In the diagram viewed from above, the boundary region 132br between the first region 132A and the second region 132B may be described as a boundary region between a center portion and an edge portion in each of the first color filters 170a.

In each of the first color filters 170a, a lower surface of the center portion may be disposed on a level lower than a level of a lower surface of the edge portion. A lower surface of the edge portion of each of the first color filters 170a, lower surfaces of the second color filters 170b, lower surfaces of the third color filters 170c, and lower surfaces of the grid structure 160 may be disposed on substantially the same level.

The image sensor 1a including the above-described insulating structure 132a may improve or optimize transmittance of light transmitting the first color filters, that is, the blue color filter 170a and the second color filters, that is, the green color filter 170b. Accordingly, in the image sensor 1a including the above-described insulating structure 132a, by improving transmittance of light transmitting the insulating structure 132a through the first color filters, that is, the blue color filter 170a and the second color filters, that is, the green color filter 170b, sensitivity of the image sensor 1a may improve.

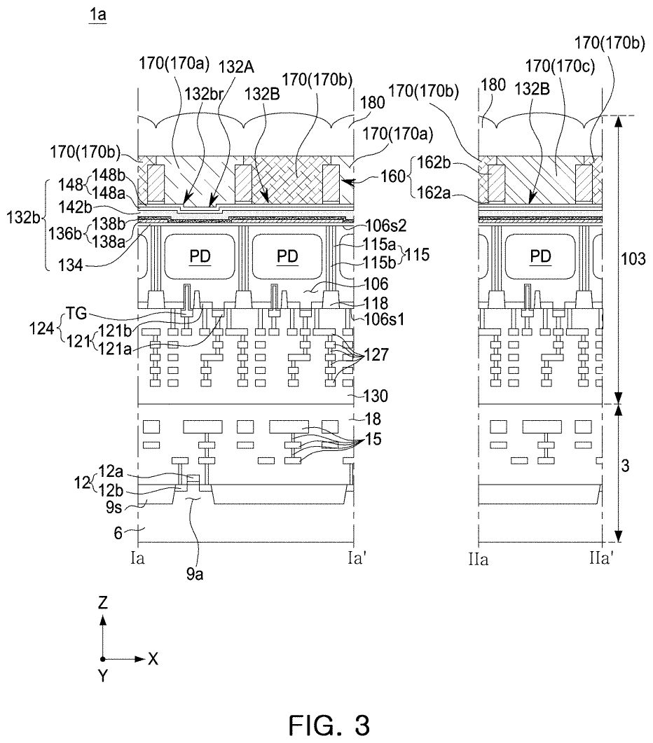

In the description below, a modified example of the insulating structure 132a will be described with reference to FIG. 3. Hereinafter, a modified example of the insulating structure 132a will be mainly described with respect to a modified component or a replaced component.

FIG. 3 is a cross-sectional diagram illustrating regions taken along lines Ia-Ia′ and IIa-IIa′ in FIG. 1, illustrating a modified example of an image sensor according to some example embodiments.

Referring to FIGS. 1 and 3, the insulating structure 132b as illustrated in FIG. 3, which may replace the insulating structure 132a in FIG. 2, may include a lower layer 134, intermediate layers 136b and 142b, and an upper layer 148 stacked in sequence. The lower layer 134 and the upper layer 148 may be substantially the same as the examples described with reference to FIG. 2. The intermediate layers 136b and 142b may include a first intermediate layer 136b and a second intermediate layer 142b stacked in sequence. The first intermediate layer 136b may include substantially the same material as that of the first intermediate layer 136a in FIG. 2, such as, for example, a high-κ material such as hafnium oxide, and the second intermediate layer 142b may include silicon oxide.

The insulating structure 132b may include the first region 132A having a first thickness and the second region 132B having a second thickness greater than the first thickness, as described with reference to FIG. 2.

In the second region 132B of the insulating structure 132b, the first intermediate layer 136b may include a first layer 138a and a second layer 138b stacked in sequence, and in the first region 132A of the insulating structure 132b, the first intermediate layer 136b may include the second layer 138b.

In some example embodiments, the first layer 138a and the second layer 138b of the first intermediate layer 136b may include the same material, such as, for example, hafnium oxide. In some example embodiments, the first layer 138a and the second layer 138b of the first intermediate layer 136b may be formed of different materials.

The first intermediate layer 136b may include a relatively thick portion including the first and second layers 138a and 138b and a relatively thin portion including the second layer 138b. According to the thickness difference depending on the position of the first intermediate layer 136b, there may be a difference in thickness between the first and second regions 132A and 132B of the insulating structure 132b.

In some example embodiments, the image sensor 1a may include the insulating structure 132a in which the thicknesses of the first and second regions 132A and 132B change according to a change in the thickness of the second intermediate layer 142a as described with reference to FIG. 2, or the insulating structure 132b in which the thicknesses of the first and second regions 132A and 132B changes according to a change in the thickness of the first intermediate layer 136b as described with reference to FIG. 3. Accordingly, the image sensor 1a may include the insulating structure (132a in FIG. 2 or 132b in FIG. 3) having a thickness optimized according to wavelengths of the first and second color filters 170a and 170b. Accordingly, by improving transmittance of light passing through the insulating structure (132a in FIG. 2 or 132b in FIG. 3) through the first and second color filters 170a and 170b, sensitivity of the image sensor 1a may improve.

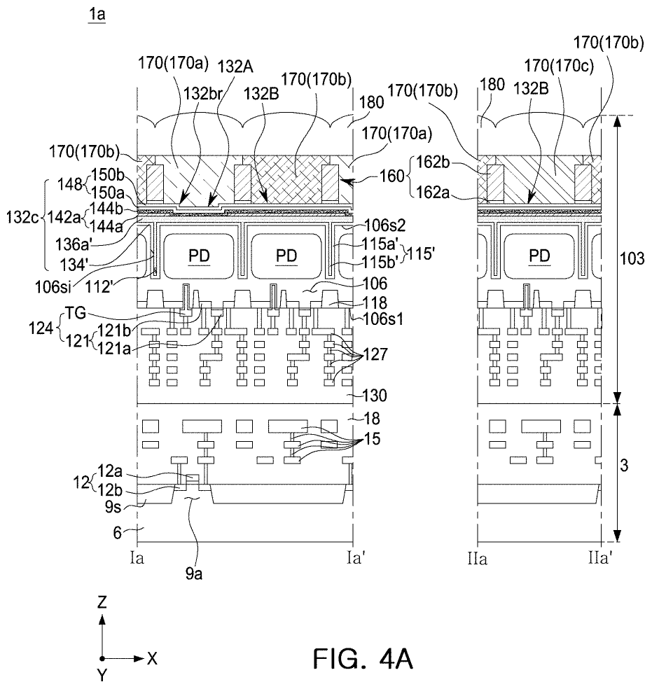

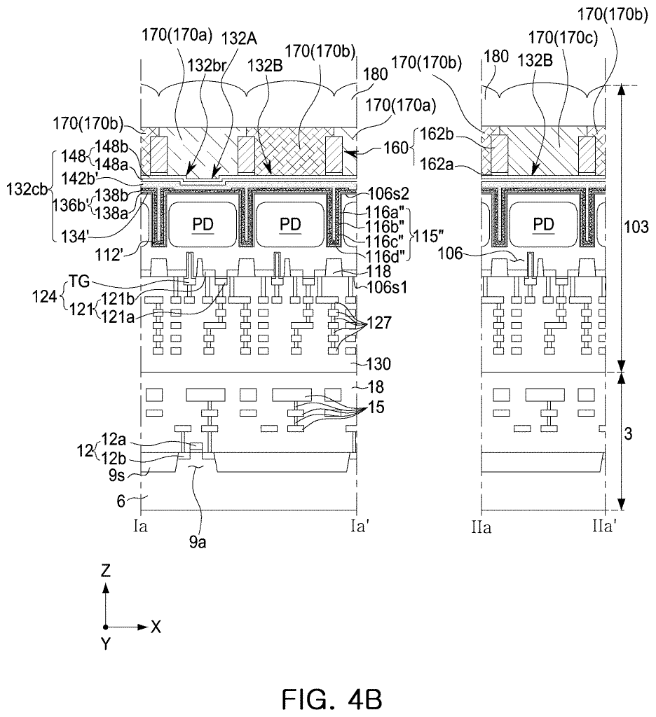

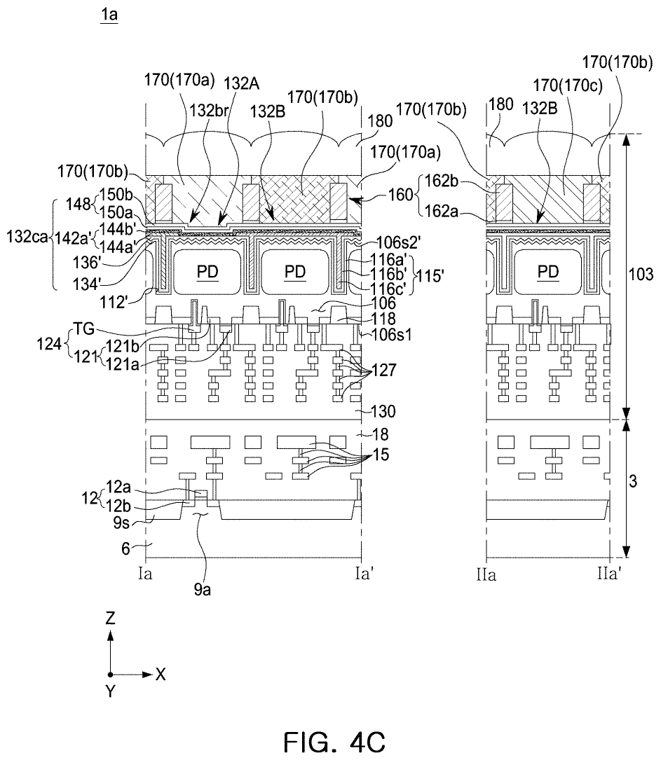

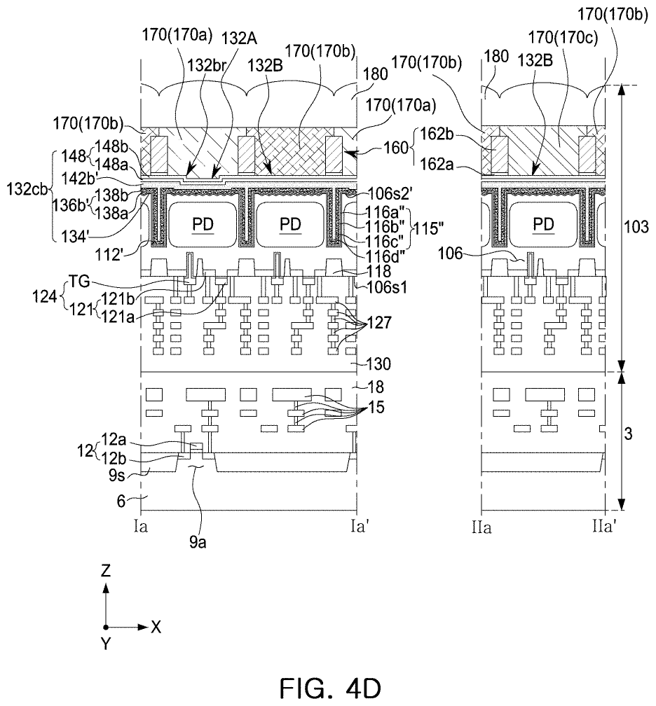

The separation structure 115 described with reference to FIGS. 2 and 3 may be disposed in an opening 112 that is at least partially defined by one or more inner sidewall surfaces 106si of the second substrate 106 such that the opening 112 is penetrating through in a direction from the first surface 106s1 to the second surface 106s2 of the second substrate 106, but some example embodiments thereof is not limited thereto. Also, the insulating structure (132a in FIG. 2 or 132b in FIG. 3) described with reference to FIGS. 2 and 3 may be modified to extend into the second substrate 106. Hereinafter, various modified examples of the separation structure 115 and the insulating structure (132a in FIGS. 2 and 132b in FIG. 3) will be described with reference to FIGS. 4A to 4D.

FIGS. 4A to 4D are cross-sectional diagrams illustrating regions taken along lines Ia-Ia′ and IIa-IIa′ in FIG. 1, illustrating various modified examples of the image sensor according to some example embodiments.

Referring to FIGS. 1 and 4A, the separation structure 115 (in FIG. 2) in FIG. 2 may be modified to form the separation structure 115′ in FIG. 4A. The separation structure 115′ may be disposed in an opening 112′ that is at least partially defined by one or more inner sidewall surfaces 106si of the second substrate 106 such that the opening 112′ is extending in a direction from the second surface 106s2 to the first surface 106s1 of the second substrate 106.

The separation structure 115′ may be spaced apart from the device isolation layer 118. The separation structure 115′ may extend in a direction from the second surface 106s2 of the second substrate 106 toward the first surface 106s1, and an end of the separation structure 115′ may be disposed in the second substrate 106.

The insulating structure 132a (in FIG. 2) including the first and second regions 132A and 132B having different thicknesses described with reference to FIG. 2 may be modified to be an insulating structure 132ca including has at least one material layer extending into the opening 112′. For example, at least a portion of the insulating structure 132a in FIG. 2 described with reference to FIG. 2 may extend into the opening 112′ and may form the separation structure 115′. For example, the separation structure 115′ may include a first layer 116a′ and a second layer 116b′ covering an internal wall of the opening 112′ in sequence, and a third layer 116c′ filling the opening 112′ on the second layer 116b′, and the first to third layers 116a′, 116b′, and 116c′ may extend from at least a portion of the insulating structure 132ca.

In some example embodiments, the insulating structure 132ca may include a lower layer 134′, intermediate layers 136a′ and 142a′, and an upper layer 148 stacked in sequence. The intermediate layers 136a′ and 142a′ may include a first intermediate layer 136a′ and a second intermediate layer 142a′ stacked in sequence. The second intermediate layer 142a′ may include a first layer 144a′ and a second layer 144b′ stacked in sequence.

The lower layer 134′, the intermediate layers 136a′ and 142a′ and the upper layer 148 of the insulating structure 132ca may correspond to the lower layer 134, the intermediate layers 136a and 142a, and the upper layer 148 of the insulating structure 132a, respectively, described with reference to FIG. 2, and may be formed of the same material as those of the lower layer 134, the intermediate layers 136a and 142a, and the upper layer 148 of the insulating structure 132a.

The lower layer 134′ may extend into the opening 112′ and may be included in the first layer 116a′ of the separation structure 115′, a portion of the intermediate layers 136a′ and 142a′, such as, for example, the first intermediate layer 136a′, may extend into the opening 112′ and may be included in the second layer 116b′ of the separation structure 115′, and the first layer 144a′ of the second intermediate layer 142a′ may be included in the third layer 116c′ of the separation structure 115′.

The insulating structure 132ca may include the first and second regions 132A and 132B having different thicknesses as described with reference to FIG. 2 on the second surface 106s2 of the second substrate 106.

Thereafter, referring to FIGS. 1 and 4B, the separation structure 115 (in FIG. 3) may be modified to form a separation structure 115″ as in FIG. 4B. The separation structure 115″ may be disposed in the opening 112′ extending in a direction from the second surface 106s2 of the second substrate 106 toward the first surface 106s1, described with reference to FIG. 4A.

The insulating structure 132b (in FIG. 3) described with reference to FIG. 3 may be modified to form an insulating structure 132cb including at least one material layer extending into the opening 112′. For example, at least a portion of the insulating structure 132b (in FIG. 3) described with reference to FIG. 3 may extend into the opening 112′ and may form the separation structure 115″. For example, the separation structure 115″ may include a first layer 116a″, a second layer 116b″, a third layer 116c″, and a fourth layer 116d″ covering the internal wall of the opening 112′ in sequence, and the first to fourth layers 116a″, 116b″, 116c″, and 116d″ may extend from at least a portion of the insulating structure 132cb.

In some example embodiments, the insulating structure 132cb may include a lower layer 134′, intermediate layers 136b′ and 142b′, and an upper layer 148 stacked in sequence. The intermediate layers 136b′ and 142b′ may include a first intermediate layer 136b′ and a second intermediate layer 142b′ stacked in sequence. The first intermediate layer 136b′ may include a first layer 138a′ and a second layer 138b′ stacked in sequence.

The lower layer 134′, the intermediate layers 136b′ and 142b′ and the upper layer 148 of the insulating structure 132cb may correspond to the lower layer 134, the intermediate layers 136b and 142b, and the upper layer 148 of the insulating structure 132b, respectively, described with reference to FIG. 3, and may be formed of the same material as those of the lower layer 134, the intermediate layers 136a and 142a, and the upper layer 148 of the insulating structure 132a.

The lower layer 134′ may extend into the opening 112′ and may be included in the first layer 116a″ of the separation structure 115″, and in the intermediate layers 136b′ and 142b′, the first layer 138a′ and the second layer 138b′ of the first intermediate layer 136b′ may extend into the opening 112′ and may be included in the second layer 116b″ and the third layer 116c″ of the separation structure 115″, and the second intermediate layer 142b′ may extend into the opening 112′ and may be included in the fourth layer 116d″ of the separation structure 115″.

The insulating structure 132cb may include the first and second regions 132A and 132B having different thicknesses as described with reference to FIG. 3 on the second surface 106s2 of the second substrate 106.

In FIGS. 2, 3, 4A and 4B, the second surface 106s2 of the second substrate 106 may be substantially planar, but some example embodiments thereof is not limited thereto. For example, in FIGS. 2, 3, 4A, and 4B, the second surface 106s2 of the second substrate 106 may be modified to form a second surface having an uneven structure. Hereinafter, an example in which the second surface 106s2 of the second substrate 106 in FIGS. 4A and 4B is modified to form a second surface having an uneven structure will be described with reference to FIGS. 4C and 4D. FIGS. 4C and 4D are cross-sectional diagrams illustrating regions taken along lines Ia-Ia′ and IIa-IIa′ in FIG. 1, illustrating a modified example of an image sensor according to some example embodiments.

Referring to FIGS. 1 and 4C, the second surface 106s2 of the second substrate 106 in FIG. 4A may be modified to form a second surface 106s2′ having an uneven structure as in FIG. 4C. FIG. 4C illustrates an example in which the second surface 106s2 (in FIG. 4A) of the second substrate 106 in FIG. 4A is modified to form the second surface 106s2′ having an uneven structure, but the second surface 106s2 of the second substrate 106 in FIG. 2 may be modified to form the second surface 106s2′ having an uneven structure as in FIG. 4C. By forming the second surface 106s2′ in an uneven structure, light transmittance may improve. Accordingly, sensitivity of the image sensor 1a may improve.

Referring to FIGS. 1 and 4D, as described with reference to FIG. 4C, to improve sensitivity of the image sensor 1a, the second surface 106s2 of the second substrate 106 in FIG. 4B may be modified to form the second surface 106s2′ having an uneven structure as in FIG. 4D. Similarly, the second surface 106s2 of the second substrate 106 in FIG. 3 may also be modified to form the second surface 106s2′ having an uneven structure as in FIG. 4D.

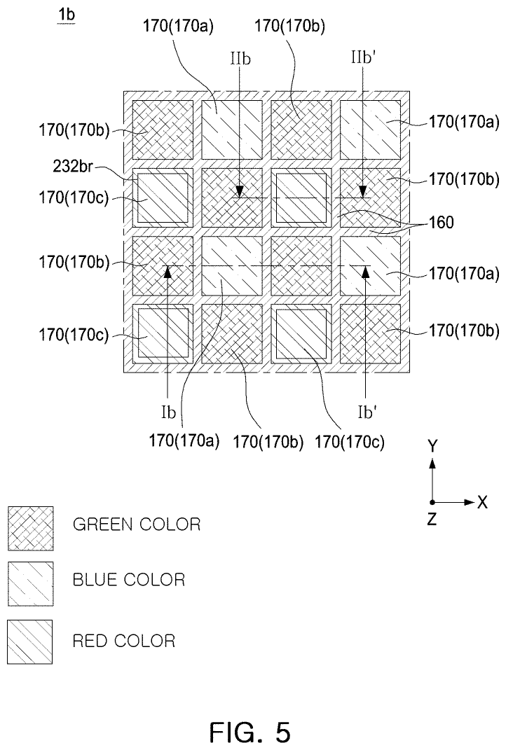

In the description below, various modified examples of the above-described image sensor 1a will be described with reference to FIGS. 5 to 45. The various modified examples of the image sensor 1a will be mainly described with respect to modified components or replaced components. Also, various components in the image sensor 1a, which may be modified or replaced, may be combined with each other and may be included in an image sensor of a modified example.

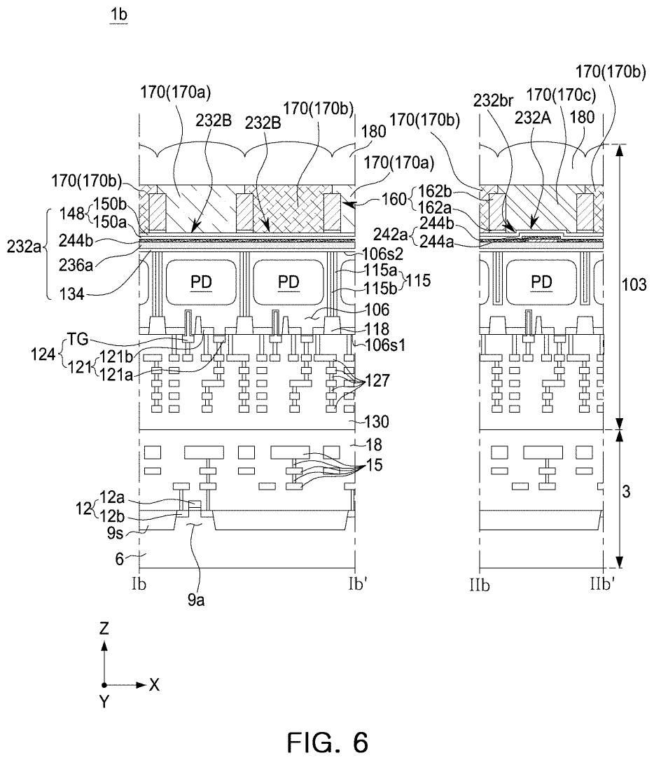

An example of an image sensor will be described with reference to FIGS. 5 and 6 according to some example embodiments.

FIG. 5 is a diagram illustrating an image sensor according to some example embodiments, viewed from above, and FIG. 6 is a cross-sectional diagram illustrating regions taken along lines Ib-Ib′ and IIb-IIb′ in FIG. 5, illustrating an example of the image sensor according to some example embodiments.

Referring to FIGS. 5 and 6, an image sensor 1b in the modified example may include an insulating structure 232a which may replace the insulating structure 132a (in FIG. 2) described with reference to FIG. 2.

The insulating structure 232a may include a lower layer 134, intermediate layers 236a and 242a, and an upper layer 148 stacked in sequence. The lower layer 134 and the upper layer 148 may be substantially the same as the examples described with reference to FIG. 2. The intermediate layers 236a and 242a may include a first intermediate layer 236a and a second intermediate layer 242a stacked in sequence. The first intermediate layer 236a may include substantially the same material as that of the first intermediate layer 136a in FIG. 2, such as, for example, a high-κ material such as hafnium oxide, and the second intermediate layer 242a may include silicon oxide.

The insulating structure 232a may include a first region 232A and a second region 232B having a thickness lower than that of the first region 232A.

In the first region 232A of the insulating structure 232a, the second intermediate layer 242a may include a first layer 244a and a second layer 244b stacked in sequence, and in the second region 232B of the insulating structure 232a, the second intermediate layer 242a may include the second layer 244b. The first layer 244a and the second layer 244b of the second intermediate layer 242a may include the same material, such as, for example, silicon oxide.

The second intermediate layer 242a may include a relatively thick portion including the first and second layers 244a and 244b and a relatively thin portion including the second layer 244b. According to the thickness difference depending on the position of the second intermediate layer 242a, there may be a difference in thickness between the first and second regions 232A and 232B of the insulating structure 232a.

An edge portion of each of the third color filters 170c, the first and second color filters 170a and 170b, and the grid structure 160 may be disposed on the second region 232B of the insulating structure 232a, and a center portion of each of the third color filters 170c may be disposed on the first region 232A of the insulating structure 232a.

In the insulating structure 232a, a region in which the thickness changes, that is, a boundary region 232br between the first region 232A and the second region 232B, may vertically overlap the third color filters 170c, may be spaced apart from side surfaces of the third color filters 170c, and may be spaced apart from the grid structure 160.

In the diagram viewed from above, the boundary region 232br between the first region 232A and the second region 232B may also be described as a boundary region between a center portion and an edge portion of each of the third color filters 170c.

In each of the third color filters 170c, a lower surface of the center portion may be disposed on a level higher than a level of a lower surface of the edge portion. Lower surfaces of the first color filters 170a, lower surfaces of the second color filters 170b, lower surfaces of the edge portion of each of the third color filters 170c, and lower surfaces of the grid structure 160 may be disposed on substantially the same level.

As described with reference to FIGS. 5 and 6, the image sensor 1b may include the insulating structure 232a in which the thicknesses of the first and second regions 232A and 232B changes according to a change in the thickness of the second intermediate layer 242a. Accordingly, since the image sensor 1b may include the insulating structure 232a having a thickness optimized according to wavelengths of the second and third color filters 170b and 170c, by improving transmittance of light passing through the insulating structure 232a through the second and third color filters 170b and 170c, that is, the green color filter 170b and the red color filter 170c, sensitivity of the image sensor 1b may improve.

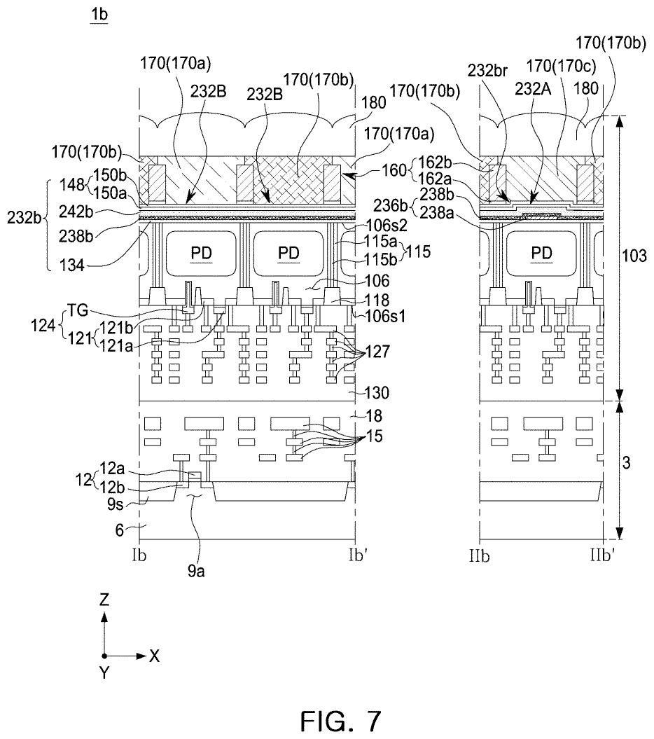

In the description below, a modified example of the insulating structure 232a (in FIG. 6) will be described with reference to FIG. 7.

FIG. 7 is a cross-sectional diagram illustrating regions taken along lines Ib-Ib′ and IIb-IIb′ in FIG. 5, illustrating a modified example of an image sensor according to some example embodiments.

Referring to FIGS. 5 and 7, an insulating structure 232b as in FIG. 7 which may replace the insulating structure 232a in FIG. 6 may include a lower layer 134, intermediate layers 236b and 242b, and an upper layer 148. The lower layer 134 and the upper layer 148 may be substantially the same as the examples described with reference to FIG. 2.

The intermediate layers 236b and 242b may include a first intermediate layer 236b and a second intermediate layer 242b stacked in sequence. The first intermediate layer 236b may include substantially the same material as that of the first intermediate layer 136a in FIG. 2, such as, for example, a high-κ material such as hafnium oxide, and the second intermediate layer 242b may include silicon oxide.

The insulating structure 332b may include the first region 232A and the second region 232B having a thickness lower than the thickness of the first region 232A, as described with reference to FIG. 6.

In the first region 232A of the insulating structure 232b, the first intermediate layer 236b may include a first layer 238a and a second layer 238b stacked in sequence, and in the second region 232B of the insulating structure 232b, the first intermediate layer 236b may include the second layer 238b.

In some example embodiments, the first layer 238a and the second layer 238b of the first intermediate layer 236b may include the same material, such as, for example, hafnium oxide. In some example embodiments, the first layer 238a and the second layer 238b of the first intermediate layer 236b may be formed of different materials.

The first intermediate layer 236b may include a relatively thick portion including the first and second layers 238a and 238b and a relatively thin portion including the second layer 238b. According to the thickness difference depending on the position of the first intermediate layer 236b, there may be a difference in thickness between the first and second regions 232A and 232B of the insulating structure 232b, substantially the same as in the insulating structure 232a in FIG. 6.

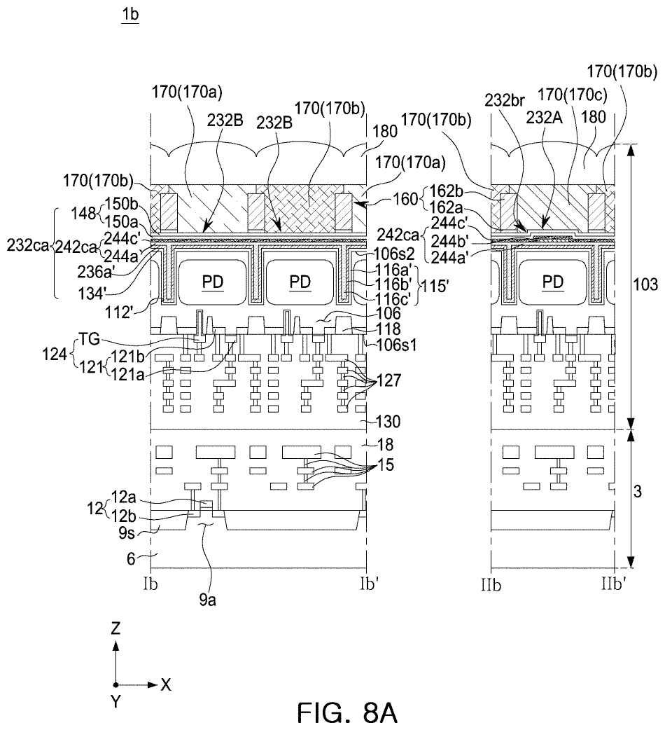

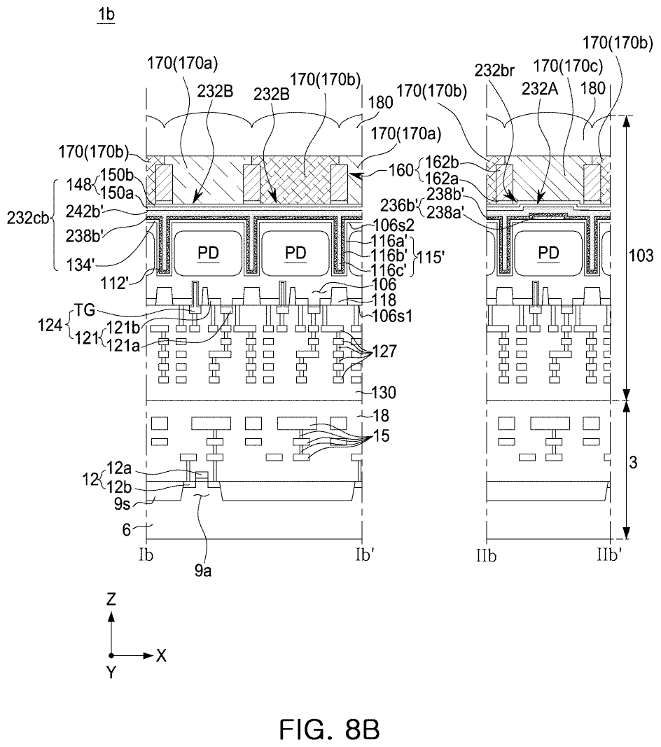

In the description below, a modified example of the separation structure 115 of the image sensor 1b in FIGS. 6 and 7 will be described with reference to FIGS. 8A and 8B.

FIGS. 8A and 8B are cross-sectional diagrams illustrating regions taken along lines Ib-Ib′ and IIb-IIb′ in FIG. 5, illustrating a modified example of an image sensor according to some example embodiments.

Referring to FIG. 8A, the separation structure 115 in FIG. 6 may be modified to form a separation structure 115′ in FIG. 8A. The separation structure 115′ may be disposed in the opening 112′ as described with reference to FIG. 4A. The insulating structure 232a (in FIG. 6) including the first region 232A and the second region 232B having different thicknesses as illustrated in FIG. 6 may be modified to form an insulating structure 232ca including a portion extending into the opening 112′.

In some example embodiments, the insulating structure 232ca may include a lower layer 134′, intermediate layers 236a′ and 242ca and an upper layer 148 stacked in sequence. The intermediate layers 236a′ and 242ca may include a first intermediate layer 236a′ and a second intermediate layer 242ca stacked in sequence. The second intermediate layer 242ca may include a first layer 244a′, a second layer 244b′, and a third layer 244c′.

The lower layer 134′ may extend into the opening 112′ and may be included in the first layer 116a′ of the separation structure 115′, a portion of the intermediate layers 236a′ and 242ca, such as, for example, the first intermediate layer 236a′, may extend into the opening 112′ and may be included in a second layer 116b′ of the separation structure 115′, and the first layer 244a′ of the second intermediate layer 242ca may extend into the opening 112′ and may be included in the third layer 116c′ of the separation structure 115′.

In some example embodiments, the second layer 244b′ and the third layer 244c′ of the second intermediate layer 242ca may correspond to the first layer 244a and the second layer 244b of the second intermediate layer 242a described with reference to FIG. 6, and may be formed of the same material as that of the first layer 244a and the second layer 244b of the second intermediate layer 242a described with reference to FIG. 6. In the second intermediate layer 242ca, the first layer 244a′ may include the same material as that of the second layer 244b′ and the third layer 244c′, such as, for example, silicon oxide.

In some example embodiments, the first layer 244a′ of the second intermediate layer 242ca may not be provided, and the third layer 244c′ of the second intermediate layer 242ca may extend into the opening 112′ and may be included in the third layer 116c′ of the separation structure 115′.

In the description below, referring to FIGS. 7 and 8B, the separation structure 115 (in FIG. 7) in FIG. 7 may be modified to form the separation structure 115′ as in FIG. 8B. The separation structure 115′ may be disposed in the opening 112′ as described with reference to FIG. 4A.

The insulating structure 232b (in FIG. 7) described with reference to FIG. 7 may be modified to form an insulating structure 232cb including at least one material layer extending into the opening 112′. For example, at least a portion of the insulating structure 232b (in FIG. 7) described with reference to FIG. 7 may extend into the opening 112′ and may form the separation structure 115′. For example, the separation structure 115′ may include a first layer 116a′, a second layer 116b′, and a third layer 116c′ covering the internal wall of the opening 112′ in sequence, and the first to third layers 116a′, 116b′, and 116c′ may extend from at least a portion of the insulating structure 232cb.

In some example embodiments, the insulating structure 232cb may include a lower layer 134′, intermediate layers 236b′ and 242b′, and an upper layer 148 stacked in sequence. The intermediate layers 236b′ and 242b′ may include a first intermediate layer 236b′ and a second intermediate layer 242b′ stacked in sequence. The first intermediate layer 236b′ may include a first layer 238a′ and a second layer 238b′ stacked in sequence.

The lower layer 134′, the intermediate layers 236b′ and 242b′ and the upper layer 148 of the insulating structure 232cb may correspond to the lower layer 134, the intermediate layers 236b and 242b, and the upper layer 148 of the insulating structure 232b described with reference to FIG. 7, respectively, and may be formed of the same material as those of the lower layer 134, the intermediate layers 236b and 242b, and the upper layer 148 of the insulating structure 232b.

The lower layer 134′ may extend into the opening 112′ and may be included in the first layer 116a′ of the separation structure 115′, in the intermediate layers 236b′ and 242b′, the second layer 238b′ of the first intermediate layer 236b′ may extend into the opening 112′ and may be included in the second layer 116b′ of the separation structure 115′, and the second intermediate layer 242b′ may extend into the opening 112′ and may be included in the third layer 116c′ of the separation structure 115′.

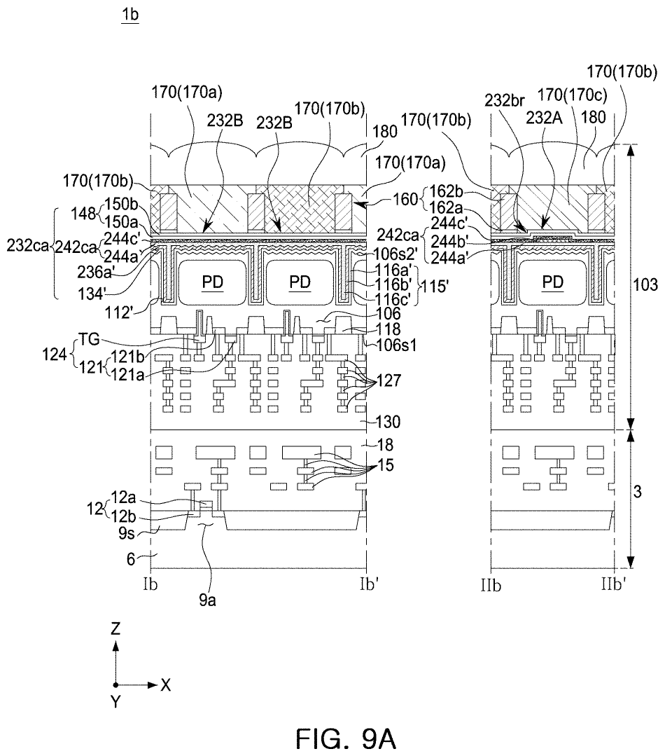

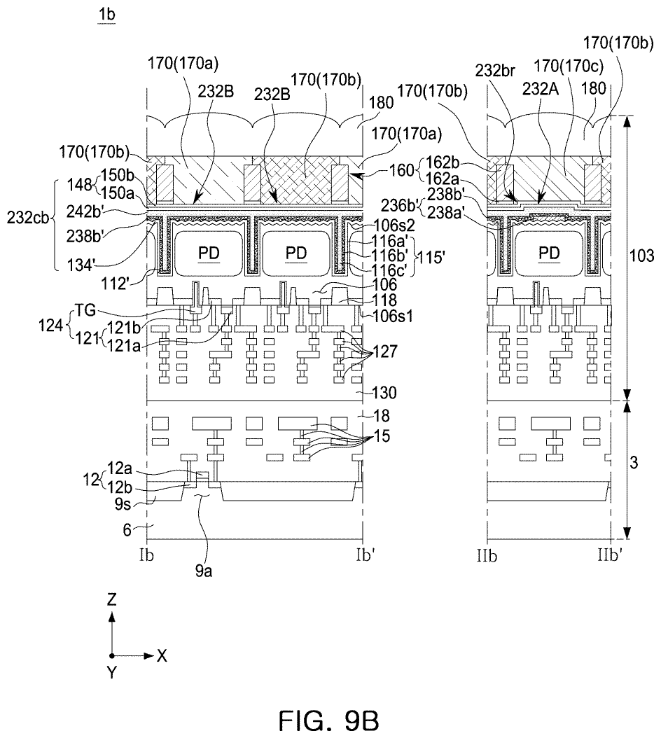

In FIGS. 6, 7, 8A, and 8B, the second surface 106s2 of the second substrate 106 may be substantially planar, but some example embodiments thereof is not limited thereto. For example, in FIGS. 6, 7, 8A, and 8B, the second surface 106s2 of the second substrate 106 may be modified to form a second surface having an uneven structure. Hereinafter, a modified example of the second surface 106s2 of the second substrate 106 in FIGS. 8A and 8B will be described with reference to FIGS. 9A and 9B.

FIGS. 9A and 9B are cross-sectional diagrams illustrating regions taken along lines Ib-Ib′ and IIb-IIb′ in FIG. 5, illustrating a modified example of an image sensor according to some example embodiments.

Referring to FIGS. 5 and 9A, in some example embodiments, including the example embodiments shown in FIG. 8A, the second surface 106s2 of the second substrate 106 may be substantially planar, but as described with reference to FIGS. 4C and 4D, the second surface 106s2 may be modified to form a second surface 106s2′ having an uneven structure. Similarly, the second surface 106s2 of the second substrate 106 in FIG. 8A may be modified to form a second surface 106s2′ having an uneven structure.

Referring to FIGS. 5 and 9B, in some example embodiments, including the example embodiments shown in FIG. 8B, the second surface 106s2 of the second substrate 106 may be substantially planar, but as described with reference to FIGS. 4C and 4D, the second surface 106s2 may be modified to form the second surface 106s2′ having an uneven structure. Similarly, the second surface 106s2 of the second substrate 106 in FIG. 8B may be modified to form a second surface 106s2′ having an uneven structure.

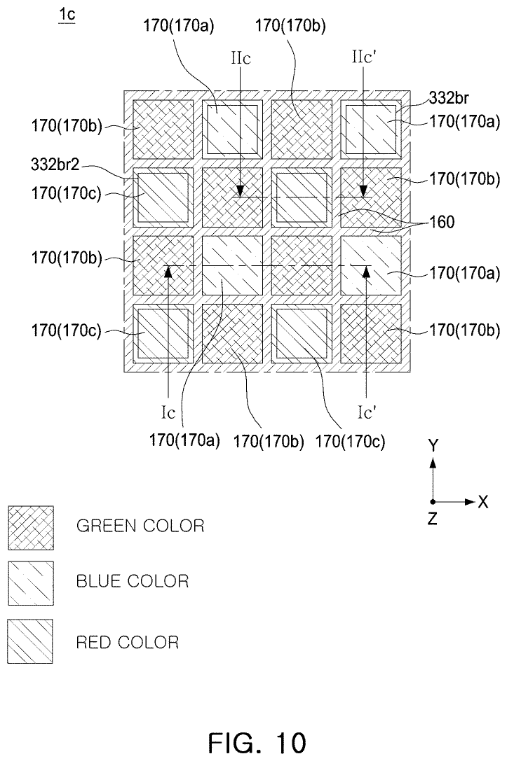

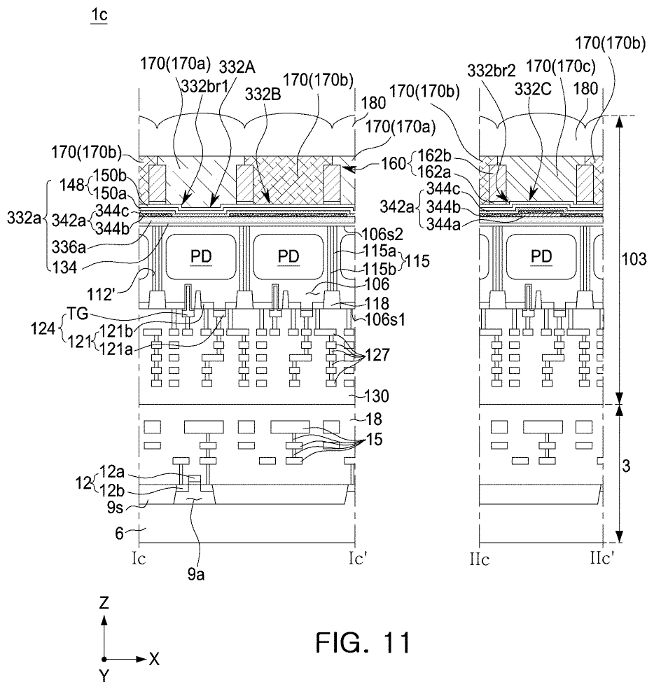

In the description below, an example of an image sensor according to some example embodiments will be described with reference to FIGS. 10 and 11.

FIG. 10 is a diagram illustrating an image sensor according to some example embodiments, viewed from above, and FIG. 11 is a cross-sectional diagram illustrating regions taken along lines Ic-Ic′ and IIc-IIc′ in FIG. 10.

Referring to FIGS. 10 and 11, an image sensor 1c in the modified example may include an insulating structure 332a which may replace the insulating structure 132a (in FIG. 2) described with reference to FIG. 2.

The insulating structure 332a may include a lower layer 134, intermediate layers 336a and 342a, and an upper layer 148 stacked in sequence. The lower layer 134 and the upper layer 148 may be substantially the same as the examples described with reference to FIG. 2. The intermediate layers 336a and 342a may include a first intermediate layer 336a and a second intermediate layer 342a stacked in sequence. The first intermediate layer 336a may include substantially the same material as that of the first intermediate layer 136a in FIG. 2, such as, for example, a high-κ material such as hafnium oxide, and the second intermediate layer 342a may include silicon oxide.

The insulating structure 332a may include a first region 332A, a second region 332B having a thickness greater than that of the first region 332A, and a third region 332C having a thickness greater than a thickness of the second region 332B.

In the third region 332C of the insulating structure 332a, the second intermediate layer 342a may include a first layer 344a, a second layer 344b and a third layer 344c stacked in sequence, in the second region 332B of the insulating structure 332a, the second intermediate layer 342a may include the second layer 344b and the third layer 344c stacked in sequence, and in the first region 332A of the insulating structure 332a, the second intermediate layer 342a may include the third layer 344c.

In some example embodiments, the first layer 344a, the second layer 344b, and the third layer 344c of the second intermediate layer 342a may include the same material, such as, for example, silicon oxide. In some example embodiments, at least two of the first layer 344a, the second layer 344b, and the third layer 344c of the second intermediate layer 342a may be formed of different materials.

The second intermediate layer 342a may include a maximum thickness portion including the first to third layers 344a, 344b, 344c, an intermediate thickness portion including the second and third layers 344b and 344c, and a minimum thickness portion including the third layer 344c. According to the thickness difference depending on the position of the second intermediate layer 342a, there may be a difference in thickness between the first to third regions 332A, 332B, and 332C of the insulating structure 332a.

The second color filters 170b, an edge portion of each the third color filters 170c, an edge portion of each of the first color filters 170a, and the grid structure 160 may be disposed on the second region 332B of the insulating structure 332a, a center portion of each of the third color filters 170c may be disposed on the third region 332C of the insulating structure 332a, and a central portion of each of the first color filters 170a may be disposed on the first region 332A of the insulating structure 332a.

In the insulating structure 332a, a region in which the thickness changes, that is, a first boundary region 332br1 between the first region 332A and the second region 332B, may vertically overlap the first color filters 170a and may be spaced apart from the grid structure 160. A second boundary region 332br2 between the second region 332B and the third region 332C may vertically overlap the third color filters 170c and may be spaced apart from the grid structure 160.

In the diagram viewed from above, the first boundary region 332br1 between the first region 332A and the second region 332B may be described as a boundary region between a center portion and an edge portion in each of the first color filters 170a, and the second boundary region 332br2 between the second region 332B and the third region 332C may be described as a boundary region between a central portion and an edge portion in the third color filters 170c.

As described with reference to FIGS. 10 and 11, the image sensor 1c may include the insulating structures 332a in which the thicknesses of the first to third regions 332A, 332B, and 323C change according to a change in the thickness of the second intermediate layer 342a. Accordingly, since the image sensor 1c may include the insulating structure 332a having a thickness optimized according to wavelengths of the first, second and third color filters 170a, 170b, and 170c, by improving transmittance of light passing through the insulating structure 332a through the first, second, and third color filters 170a, 170b, and 170c, that is, the blue color filter 170a, the green color filter 170b, and the red color filter 170c, sensitivity of the image sensor 1c may improve.

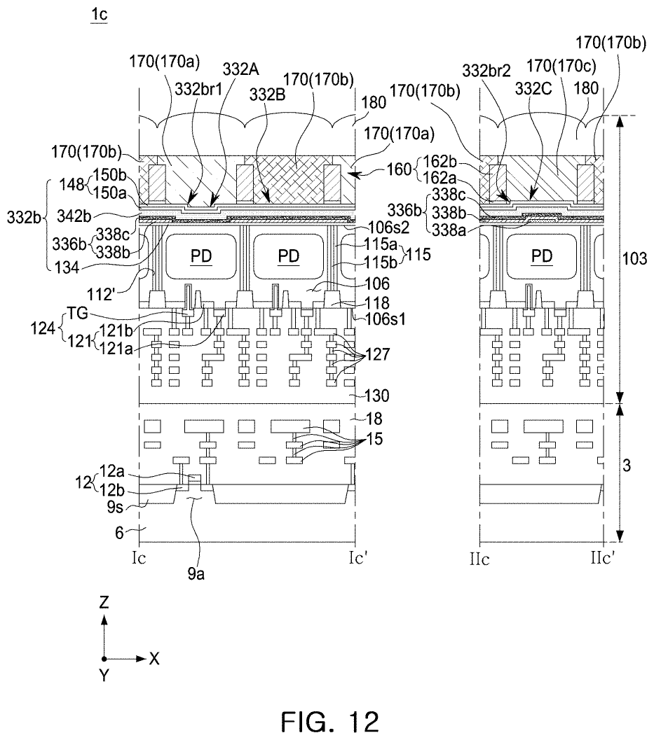

In the description below, a modified example of the insulating structure 332a (in FIG. 11) will be described with reference to FIG. 12.

FIG. 12 is a cross-sectional diagram illustrating regions taken along lines Ic-Ic′ and IIc-IIc′ in FIG. 10, illustrating a modified example of an image sensor according to some example embodiments.

Referring to FIGS. 10 and 12, an insulating structure 332b in FIG. 12 which may replace the insulating structure 332a in FIG. 11 may include a lower layer 134, an intermediate layer 336b and 342b, and an upper layer 148 stacked in sequence. The lower layer 134 and the upper layer 148 may be substantially the same as the examples described with reference to FIG. 2.

The intermediate layers 336b and 342b may include a first intermediate layer 336b and a second intermediate layer 342b stacked in sequence. The first intermediate layer 336b may include substantially the same material as that of the first intermediate layer 136a in FIG. 2, such as, for example, a high-κ material such as hafnium oxide, and the second intermediate layer 342b may include silicon oxide.

The insulating structure 332b may include the first region 332A, the second region 332B having a thickness greater than the thickness of the first region 332A, and the third region 332C having a thickness greater than the thickness of the second region 332B.

In the third region 332C of the insulating structure 332b, the first intermediate layer 336b may include a first layer 338a, a second layer 338b and a third layer 338c stacked in sequence, in the second region 332B of the insulating structure 332b, the first intermediate layer 336b may include the second layer 338b and the third layer 338c stacked in sequence, and in the first region 332A of the insulating structure 332b, the first intermediate layer 336b may include the third layer 338c.

In some example embodiments, the first layer 338a, the second layer 338b, and the third layer 338c of the first intermediate layer 336b may include the same material, such as, for example, hafnium oxide. In some example embodiments, at least two of the first layer 338a, the second layer 338b, and the third layer 338c of the first intermediate layer 336b may be formed of different materials.

The first intermediate layer 336b may include a maximum thickness portion including the first to third layers 338a, 338b, and 338c, an intermediate thickness portion including the second and third layers 338b and 338c, and a minimum thickness portion including the third layer 338c. According to the thickness difference depending on the position of the first intermediate layer 336b, there may be a difference in thickness between the first to third regions 332A, 332B, and 332C of the insulating structure 332b.

The second color filters 170b, an edge portion of each of the third color filters 170c, an edge portion of each of the first color filters 170a, and the grid structure 160 may be disposed on the second region 332B of the insulating structure 332b, a center portion of each of the third color filters 170c may be disposed on the third region 332C of the insulating structure 332b, and a central portion of each of the first color filters 170a may be disposed on the first region 332A of the insulating structure 332b.

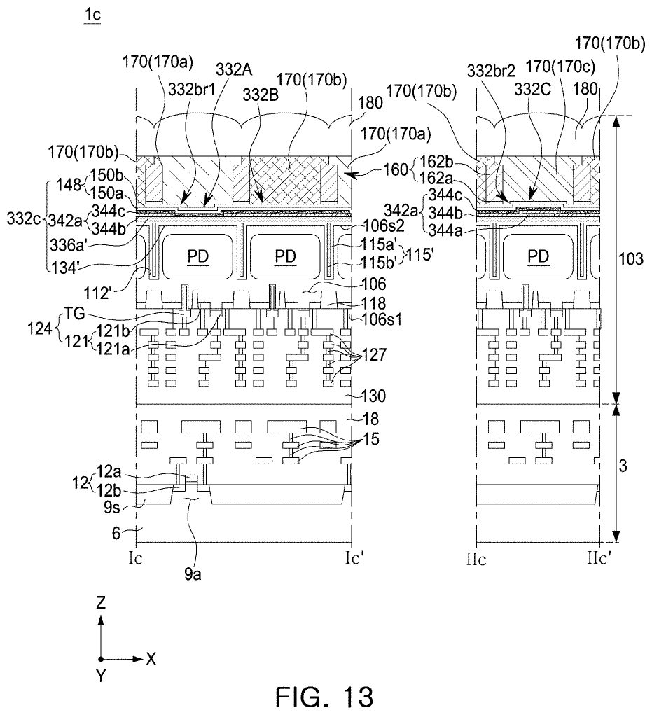

In the description below, a modified example of the separation structure 115 of the image sensor 1c in FIGS. 11 and 12 will be described with reference to FIG. 13.

FIG. 13 is a cross-sectional diagram illustrating regions taken along lines Ib-Ib′ and IIb-IIb′ in FIG. 10, illustrating a modified example of an image sensor according to some example embodiments.

Referring to FIG. 13, the separation structure 115 in FIGS. 11 and 12 may be modified to form a separation structure 115′ disposed in the opening 112′ as described with reference to FIG. 4A. The separation structure 115′ may include at least two layers, such as, for example, a first layer 115a′ and a second layer 115b′ on the first layer 115a′. The insulating structure (332a in FIG. 11 or 332b in FIG. 12) including the first region 332A, the second region 332B, and the third region 332C having different thicknesses as in FIGS. 11 and 12 may be modified to form an insulating structure 332c including a portion extending into the opening 112′ extending in a direction from the second side 106s2 of the second substrate 106 toward the first side 106s1.

In some example embodiments, the insulating structure 332c may include a lower layer 134′, intermediate layers 336a′ and 342a, and an upper layer 148 stacked in sequence. The intermediate layers 336a′ and 342a may include a first intermediate layer 336a′ and a second intermediate layer 342a stacked in sequence.

The lower layer 134′ may extend into the opening 112′ and may be included in a first layer 115a′ of the separation structure 115′, and a portion of the intermediate layers 336a′ and 342a, such as, for example, the first intermediate layer 336a′, may extend into the opening 112′ and may be included in the second layer 115b′ of the separation structure 115′.

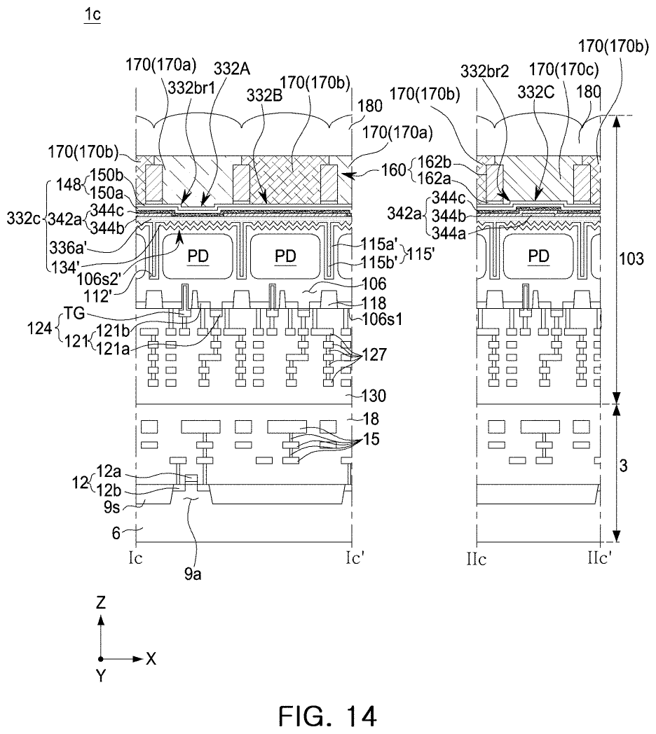

In the description below, a modified example of the second surface 106s2 of the second substrate 106 in FIGS. 11, 12 and 13 will be described with reference to FIG. 14.

FIG. 14 is a cross-sectional diagram illustrating regions taken along lines Ib-Ib′ and IIb-IIb′ in FIG. 10, illustrating a modified example of an image sensor according to some example embodiments.

Referring to FIGS. 10 and 14, in FIGS. 11, 12, and 13 described above, the second surface 106s2 of the second substrate 106 may be substantially planar, but as described with reference to FIGS. 4C and 4D, the second surface 106s2 may be modified to form a second surface 106s2′ having an uneven structure.

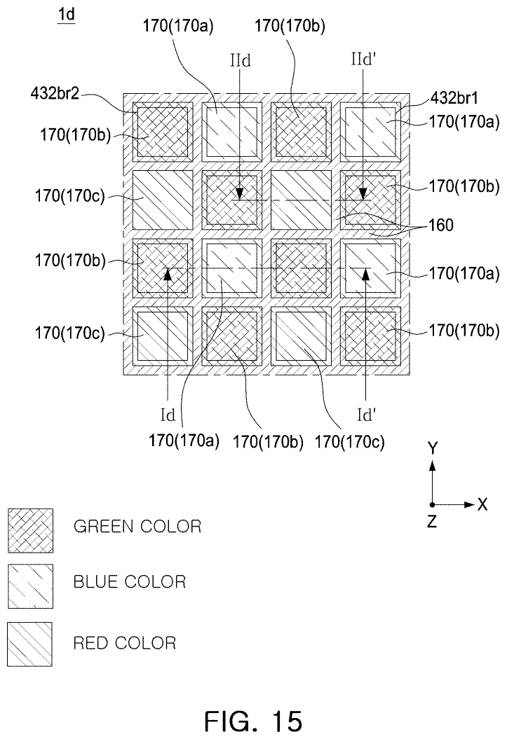

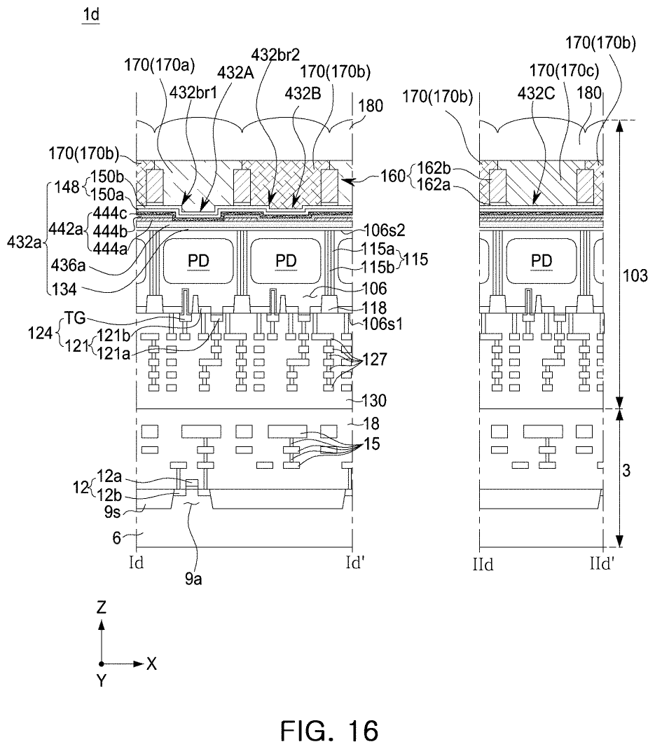

In the description below, an example of an image sensor will be described with reference to FIGS. 15 and 16 according to some example embodiments.

FIG. 15 is a diagram illustrating an image sensor according to some example embodiments of, viewed from above, and FIG. 16 is a cross-sectional diagram illustrating regions taken along lines Id-Id′ and IId-IId′.

Referring to FIGS. 15 and 16, an image sensor 1d in the modified example may include an insulating structure 432a which may replace the insulating structure 132a (in FIG. 2) described with reference to FIG. 2

The insulating structure 432a may include a lower layer 134, intermediate layers 436a and 442a, and an upper layer 148 stacked in sequence. The lower layer 134 and the upper layer 148 may be substantially the same as the examples described with reference to FIG. 2. The intermediate layers 436a and 442a may include a first intermediate layer 436a and a second intermediate layer 442a stacked in sequence. The first intermediate layer 436a may include substantially the same material as that of the first intermediate layer 136a in FIG. 2, such as, for example, a high-κ material such as hafnium oxide, and the second intermediate layer 442a may include silicon oxide.

The insulating structure 432a may include a first region 432A, a second region 432B having a thickness greater than a thickness of the first region 432A, and a third region 432C having a thickness greater than a thickness of the second region 432B.

In the third region 432C of the insulating structure 432a, the second intermediate layer 442a may include a first layer 444a, a second layer 444b, and a third layer 444c stacked in sequence, in the second region 432B of the insulating structure 432a, the second intermediate layer 442a may include the second layer 444b and the third layer 444c stacked in sequence, and in the first region 432A of the insulating structure 432a, the second intermediate layer 442a may include the third layer 444c.

In some example embodiments, the first layer 444a, the second layer 444b, and the third layer 444c of the second intermediate layer 442a may include the same material, such as, for example, silicon oxide. In some example embodiments, at least two of the first layer 444a, the second layer 444b, and the third layer 444c of the second intermediate layer 442a may be formed of different materials.

The second intermediate layer 442a may include a maximum thickness portion including the first to third layers 444a, 444b, and 444c, an intermediate thickness portion including the second and third layers 444b and 444c, and a minimum thickness portion including the third layer 444c. According to the thickness difference depending on the position of the second intermediate layer 442a, there may be a difference in thickness between the first to third regions 432A, 432B, and 432C of the insulating structure 432a.

The third color filters 170c, an edge portion of each of the second color filters 170b, an edge portion of each of the first color filters 170a, and the grid structure 160 may be disposed on the third region 432C of the insulating structure 432a, a center portion of each of the second color filters 170b may be disposed on the second region 432B of the insulating structure 432a, and a central portion of each of the first color filters 170a may be disposed on the first region 432A of the insulating structure 432a.

In the insulating structure 432a, a region in which the thickness changes, that is, a first boundary region 432br1 between the first region 432A and the second region 432B, may vertically overlap the first color filters 170a and may be spaced apart from the grid structure 160, and a second boundary region 432br2 between the second region 432B and the third region 432C may vertically overlap the second color filters 170b and may be spaced apart from the grid structure 160.

In the diagram viewed from above, the first boundary region 432br1 between the first region 432A and the second region 432B may be described as a boundary region between a center portion and an edge portion in each of the first color filters 170a, and the second boundary region 432br2 between the second region 432B and the third region 432C may also be described as a boundary region between a center portion and an edge portion in the second color filters 170b.

In each of the first color filters 170a, a lower surface of the center portion may be disposed on a level lower than a level of a lower surface of the edge portion, and in each of the second color filters 170b, a lower surface of the intermediate portion may be disposed on a level lower than a level of a lower surface of the edge portion. A lower surface of the center portion of each of the second color filters 170b may be disposed on a level higher than a level of a lower surface of the center portion of each of the first color filters 170a. A lower surface of the edge portion of each of the first color filters 170a, a lower surface of the edge portion of each of the second color filters 170b, lower surfaces of the third color filters 170c, and the lower surface of the grid structure 160 may be disposed on substantially the same level.

The image sensor 1d described with reference to FIGS. 15 and 16 may include the insulating structures 432a in which thicknesses of the first to third regions 432A, 432B, and 423C change according to the change in the thickness of the second intermediate layer 442a. Accordingly, since the image sensor 1d may include the insulating structure 432a having a thickness optimized according to wavelengths of the first, second and third color filters 170a, 170b, and 170c, by improving transmittance of light passing through the insulating structure 432a through the first, second, and third color filters 170a, 170b, and 170c, that is, the blue color filter 170a, the green color filter 170b, and the red color filter 170c, sensitivity of the image sensor 1d may improve.

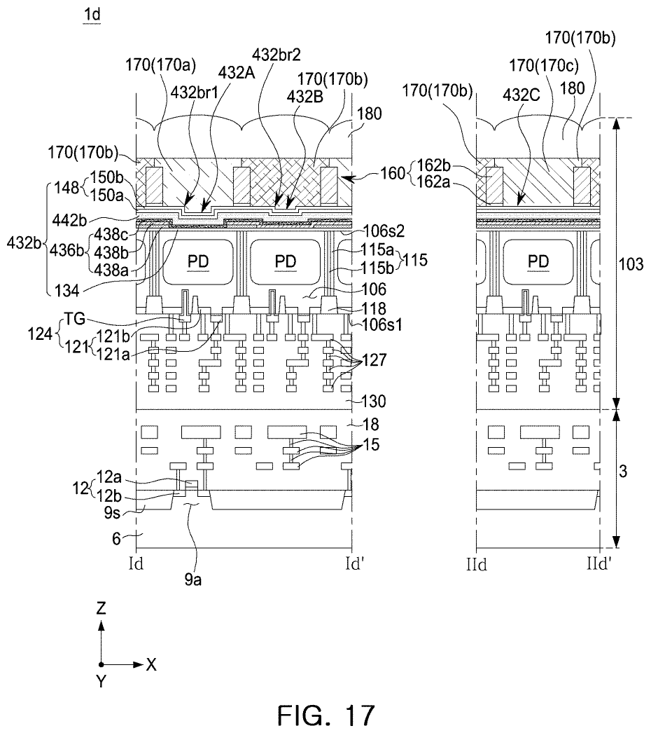

In the description below, a modified example of the insulating structure 432a (in FIG. 16) will be described with reference to FIG. 17.

FIG. 17 is a cross-sectional diagram illustrating regions taken along lines Id-Id′ and IId-IId′ in FIG. 15, illustrating a modified example of an image sensor according to some example embodiments.

Referring to FIGS. 15 and 17, an insulating structure 432b as in FIG. 17 which may replace the insulating structure 432a in FIG. 16 may include a lower layer 134, intermediate layers 436b and 442b, and an upper layer 148 stacked in sequence. The lower layer 134 and the upper layer 148 may be substantially the same as the examples described with reference to FIG. 2.

The intermediate layers 436b and 442b may include a first intermediate layer 436b and a second intermediate layer 442b stacked in sequence. The first intermediate layer 436b may include substantially the same material as the first intermediate layer 136a in FIG. 2, such as, for example, a high-κ material such as hafnium oxide, and the second intermediate layer 442b may include silicon oxide.

The insulating structure 432b may include the first region 432A, the second region 432B having a thickness greater than the thickness of the first region 432A, and the third region 432C having a thickness greater than that of the second region 432B, described with reference to FIG. 16.

In the third region 432C of the insulating structure 432b, the first intermediate layer 436b may include a first layer 438a, a second layer 438b and a third layer 438c stacked in sequence, in the second region 432B of the insulating structure 432b, the first intermediate layer 436b may include the second layer 438b and the third layer 438c stacked in sequence, and in the first region 432A of the insulating structure 432b, the first intermediate layer 436b may include the third layer 438c.

In some example embodiments, the first layer 438a, the second layer 438b, and the third layer 438c of the first intermediate layer 436b may include the same material, such as, for example, hafnium oxide. In some example embodiments, at least two of the first layer 438a, the second layer 438b, and the third layer 438c of the first intermediate layer 436b may be formed of different materials.

The first intermediate layer 436b may include a maximum thickness portion including the first to third layers 438a, 438b, and 438c, and an intermediate thickness portion including the second and third layers 438b and 438c, and a minimum thickness portion including the third layer 438c. According to the thickness difference depending on the position of the first intermediate layer 436b, there may be a difference in thicknesses between the first to third regions 432A, 432B, and 432C of the insulating structure 432b as described with reference to FIG. 17.

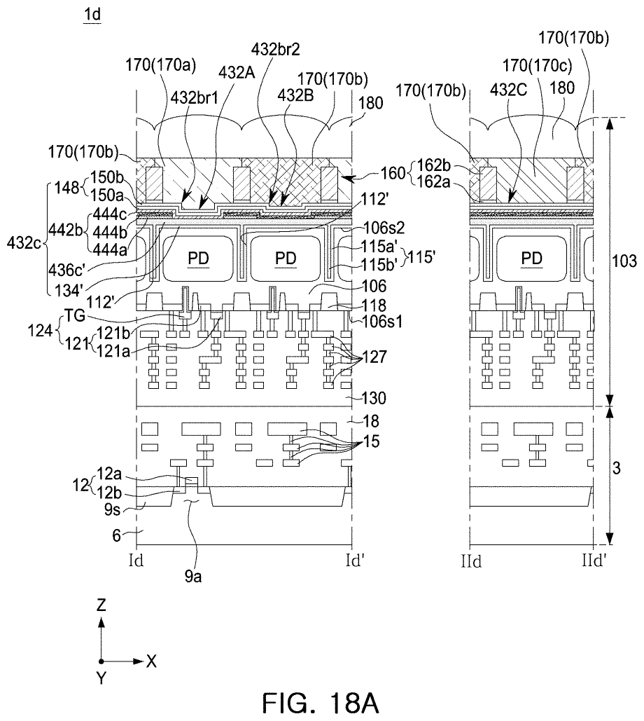

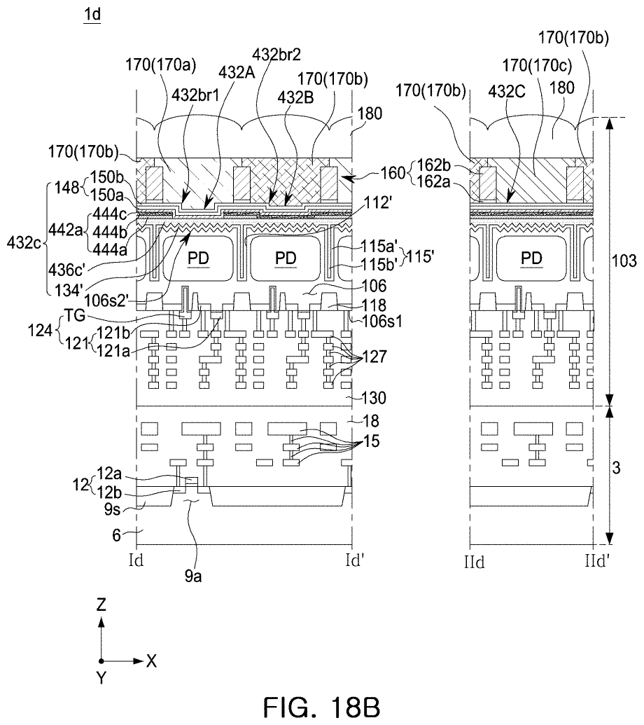

In the description below, a modified example of the separation structure 115 of the image sensor 1d in FIGS. 16 and 17 will be described with reference to FIG. 18A.

FIG. 18A is a cross-sectional diagram illustrating regions taken along lines Id-Id′ and IId-IId′ in FIG. 15, illustrating a modified example of an image sensor according to some example embodiments.

Referring to FIG. 18A, the separation structure 115 in FIGS. 16 and 17 may be modified to form a separation structure 115′ disposed in the opening 112′ as described with reference to FIG. 4A. The separation structure 115′ may include at least two layers, such as, for example, a first layer 115a′ and a second layer 115b′ on the first layer 115a′. The insulating structure (432a in FIG. 16 or 432b in FIG. 17) including the first region 432A, the second region 432B, and the third region 432C having different thicknesses as in FIG. 17 may be modified to form an insulating structure 432c including a portion extending into the opening 112′.

In some example embodiments, the insulating structure 432c may include a lower layer 134′, intermediate layers 436c′ and 442b, and an upper layer 148 stacked in sequence. The intermediate layers 436c′ and 442b may include a first intermediate layer 436c′ and a second intermediate layer 442b stacked in sequence. The lower layer 134′ may extend into the opening 112′ and may be included in a first layer 115a′ of the separation structure 115′, and a portion of the intermediate layer 436c′ and 442b, such as, for example, the first intermediate layer 436c′, may extend into the opening 112′ and may be included in the second layer 115b′ of the separation structure 115′.

In the description below, a modified example of the second surface 106s2 of the second substrate 106 in FIGS. 16, 17 and 18A will be described with reference to FIG. 18B.

FIG. 18B is a cross-sectional diagram illustrating regions taken along lines Id-Id′ and IId-IId′ in FIG. 15, illustrating a modified example of an image sensor according to some example embodiments.

Referring to FIGS. 15 and 18B, in FIGS. 16, 17, and 18A described above, the second surface 106s2 of the second substrate 106 may be substantially planar, but may be modified to form the second surface 106s2′ having an uneven structure described in FIGS. 4C and 4D.

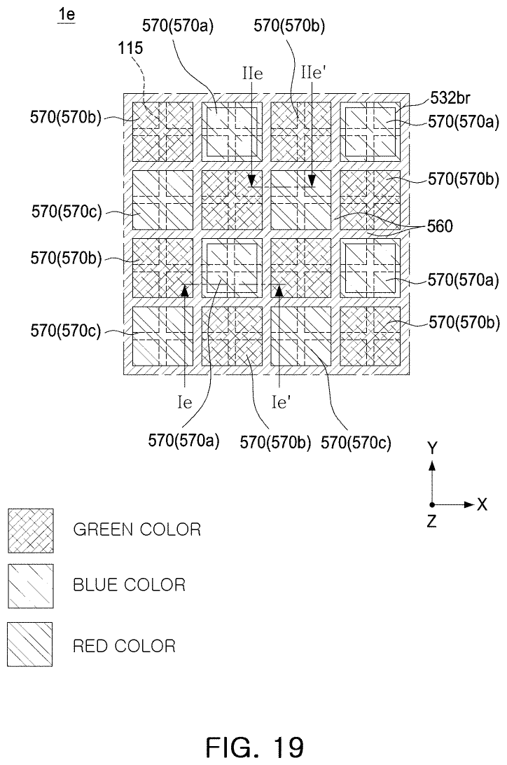

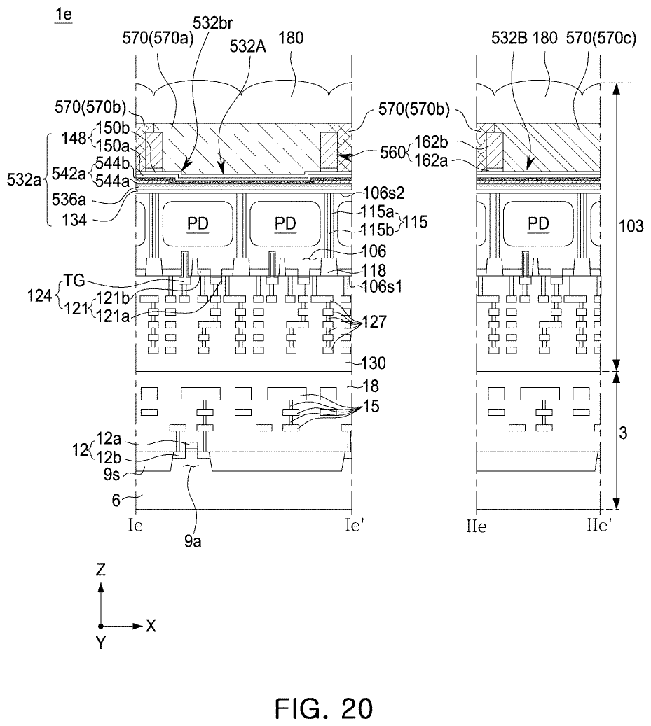

In the description below, an example of an image sensor in some example embodiments will be described with reference to FIGS. 19 and 20.

FIG. 19 is a diagram illustrating an image sensor according to some example embodiments, viewed from above, and FIG. 20 is a cross-sectional diagram illustrating regions taken along the lines Ie-Ie′ and IIe-IIe′.

Referring to FIGS. 19 and 20, an image sensor 1e in the modified example may include an insulating structure 532a which may replace the insulating structure 132a (in FIG. 2) described in FIG. 2, color filters 570 which may replace the color filters 170 described with reference to FIG. 2, and a grid structure 560 which may replace the grid structure 160 described with reference to FIG. 2.

The insulating structure 532a may include a lower layer 134, intermediate layers 536a and 542a, and an upper layer 148 stacked in sequence. The lower layer 134 and the upper layer 148 may be substantially the same as the examples described with reference to FIG. 2. The intermediate layers 536a and 542a may include a first intermediate layer 536a and a second intermediate layer 542a stacked in sequence. The first intermediate layer 536a may include substantially the same material as that of the first intermediate layer 136a (in FIG. 2), such as, for example, a high-κ material such as hafnium oxide, and the second intermediate layer 542a may include silicon oxide.

The insulating structure 532a may include a first region 532A and a second region 532B having a thickness greater than that of the first region 532A.

In the second region 532B of the insulating structure 532a, the second intermediate layer 542a may include a first layer 544a and a second layer 544b stacked in sequence, and in the first region 532A of the insulating structure 532a, the second intermediate layer 542a may include the second layer 544b.

In some example embodiments, the first layer 544a and the second layer 544b of the second intermediate layer 542a may include the same material, such as, for example, silicon oxide. In some example embodiments, the first layer 544a and the second layer 544b of the second intermediate layer 542a may be formed of different materials.

The second intermediate layer 542a may include a maximum thickness portion including the first and second layers 544a and 544b and a minimum thickness portion including the second layer 544b. According to the thickness difference depending on the position of the second intermediate layer 542a, there may be a difference in thickness between the first and second regions 532A and 532B of the insulating structure 532a.

The color filters 570 may include first color filters 570a, second color filters 570b, and third color filters 570c. For example, the first color filters 570a may be configured as blue color filters, the second color filters 570b may be configured as green color filters, and the third color filters 570c may be configured as red color filters.

Each of the color filters 570 may vertically overlap the plurality of photoelectric conversion devices, such as, for example, photodiodes PD. For example, one of the color filters 570, such as, for example, one first color filter 570a may vertically overlap the plurality of photoelectric conversion devices PD. One of the color filters 570, such as, for example, a first color filter 570a, may vertically overlap a portion of the separation structure 115.

The grid structure 560 may be disposed between color filters of different colors among the color filters 570. The grid structure 560 may include a first layer 162a and a second layer 162b stacked in sequence as described with reference to FIG. 2.

The third color filters 570c, the second color filters 570b, an edge portion of each of the first color filters 570a, and the grid structure 560 may be disposed on the second region 532B of the insulating structure 532a, and a center portion of each of the first color filters 570a may be disposed on the first region 532A of the insulating structure 532a.

In the insulating structure 532a, a region in which the thickness changes, that is, a boundary region 532br between the first region 532A and the second region 532B may vertically overlap the first color filters 570a and may be spaced apart from the grid structure 560.

In the diagram viewed from above, the boundary region 532br between the first region 532A and the second region 532B may also be described as a boundary region between a center portion and an edge portion in each of the first color filters 570a.

The image sensor 1e may include the insulating structure 532a in which the thicknesses of the first and second regions 532A and 532B change according to the change in the thickness of the second intermediate layer 542a. Accordingly, since the image sensor 1e may include the insulating structure 532a having a thickness optimized according to wavelengths of the first and second color filters 570a and 570b, by improving transmittance of light passing through the insulating structure 532a through the first and second color filters 570a and 570b, that is, the blue color filter 570a and the green color filter 570b, sensitivity of the image sensor 1e may improve.

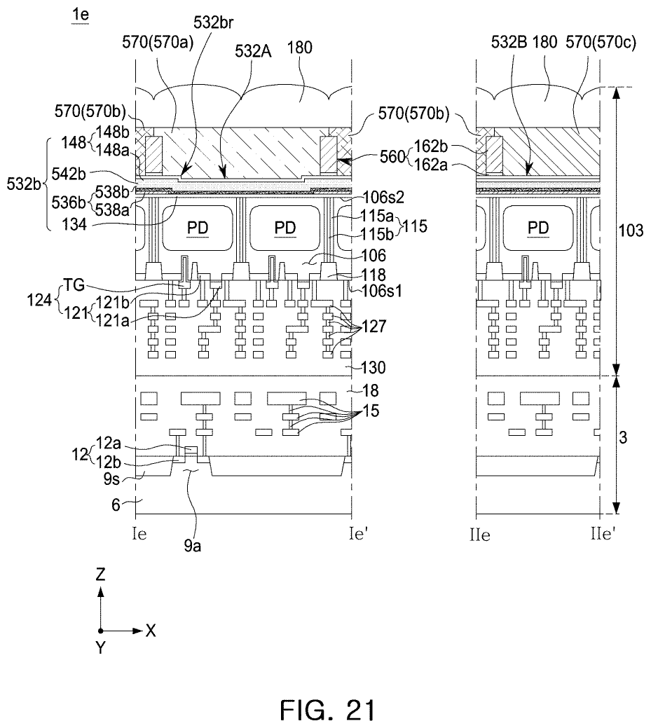

In the description below, a modified example of the insulating structure 532a will be described with reference to FIG. 21.

FIG. 21 is a cross-sectional diagram illustrating regions taken along lines Ie-Ie′ and IIe-IIe′ in FIG. 19, illustrating a modified example of the image sensor in some example embodiments.

Referring to FIGS. 19 and 21, the insulating structure 532b as in FIG. 21 which may replace the insulating structure 532a in FIG. 20 may include a lower layer 134, intermediate layers 536b and 542b, and an upper layer 148 stacked in sequence. The lower layer 134 and the upper layer 148 may be substantially the same as the examples described with reference to FIG. 2. The intermediate layers 536b and 542b may include a first intermediate layer 536b and a second intermediate layer 542b stacked in sequence. The first intermediate layer 536b may include substantially the same material as that of the first intermediate layer 136a in FIG. 2, such as, for example, a high-κ material such as hafnium oxide, and the second intermediate layer 542b may include silicon oxide.

The insulating structure 532b may include the first region 532A having a first thickness and the second region 532B having a second thickness greater than the first thickness, as described with reference to FIG. 20.

In the second region 532B of the insulating structure 532b, the first intermediate layer 536b may include a first layer 538a and a second layer 538b stacked in sequence, and, in the first region 532A of the insulating structure 532b, the first intermediate layer 536b may include the second layer 538b.

In some example embodiments, the first layer 538a and the second layer 538b of the first intermediate layer 536b may include the same material, such as, for example, hafnium oxide. In some example embodiments, the first layer 538a and the second layer 538b of the first intermediate layer 536b may be formed of different materials.

The first intermediate layer 536b may include a relatively thick portion including the first and second layers 538a and 538b and a relatively thin portion including the second layer 538b. According to the thickness difference depending on the position of the first intermediate layer 536b, there may be a difference in thickness between the first and second regions 532A and 532B of the insulating structure 532b as described with reference to FIG. 20.

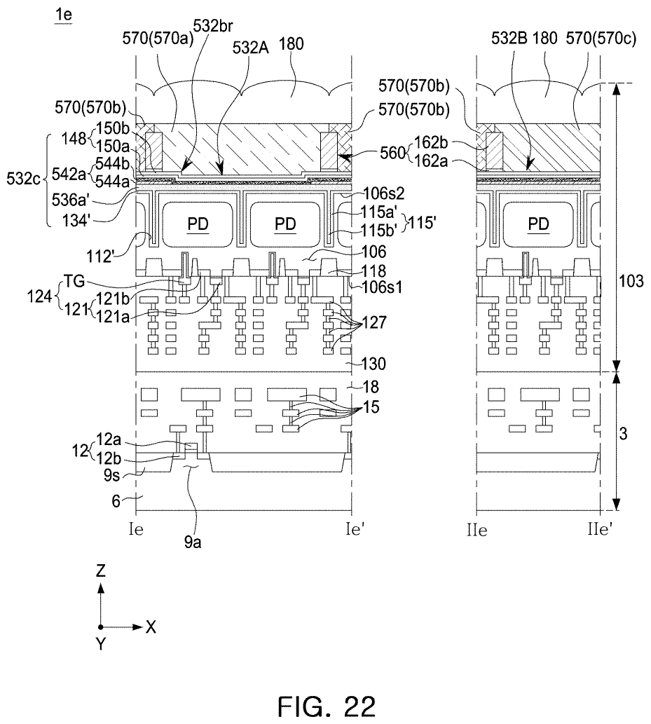

In the description below, a modified example of the separation structure 115 of the image sensor 1e in FIGS. 20 and 21 will be described with reference to FIG. 22.

FIG. 22 is a cross-sectional diagram illustrating regions taken along lines Ie-Ie′ and IIe-IIe′ in FIG. 19, illustrating a modified example of an image sensor according to some example embodiments.

Referring to FIG. 22, the separation structure 115 in FIGS. 20 and 21 may be modified to form a separation structure 115′ disposed in the opening 112′ as described with reference to FIG. 4A. The separation structure 115′ may include at least two layers, such as, for example, a first layer 115a′ and a second layer 115b′ on the first layer 115a′. As illustrated in FIGS. 20 and 21, the insulating structure (532a in FIG. 20 or 532b in FIG. 21) including the first region 532A and the second region 532B having different thicknesses may be modified to form an insulating structure 532c including a portion extending into the opening 112′.

In some example embodiments, the insulating structure 532c may include a lower layer 134′, intermediate layers 536a′ and 542a, and an upper layer 148 stacked in sequence. The intermediate layers 536a′ and 542a may include a first intermediate layer 536a′ and a second intermediate layer 542a stacked in sequence. The lower layer 134′ may extend into the opening 112′ and may be included in a first layer 115a′ of the separation structure 115′, and a portion of the intermediate layer 536a′ and 542a, such as, for example, the first intermediate layer 536a′, may extend into the opening 112′ and may be included in the second layer 115b′ of the separation structure 115′.

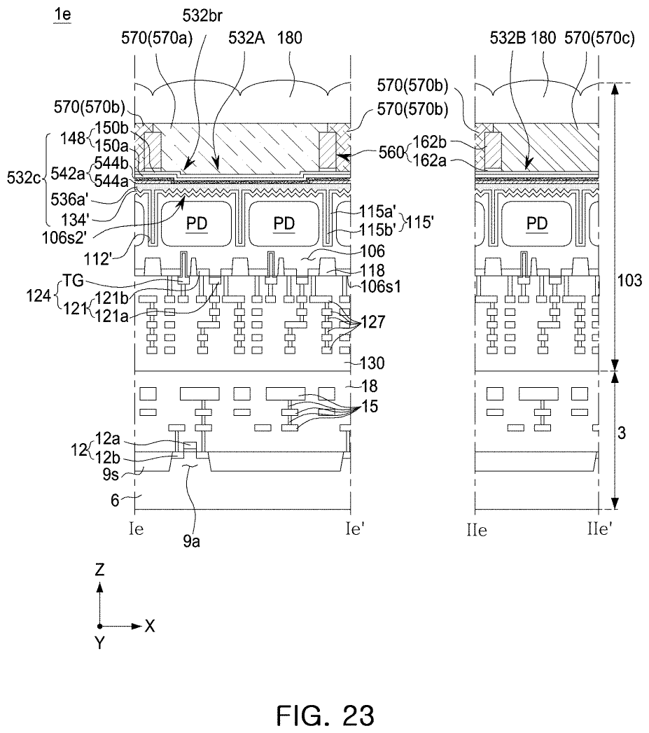

In the description below, a modified example of the second surface 106s2 of the second substrate 106 in FIGS. 20, 21 and 22 will be described with reference to FIG. 23.

FIG. 23 is a cross-sectional diagram illustrating regions taken along lines Ie-Ie′ and IIe-IIe′ in FIG. 19, illustrating a modified example of an image sensor according to some example embodiments.

Referring to FIGS. 20 and 23, in FIGS. 20, 21 and 22, the second surface 106s2 of the second substrate 106 may be substantially planar, but may be modified to the second surface 106s2′ having an uneven structure described with reference to FIGS. 4C and 4D.

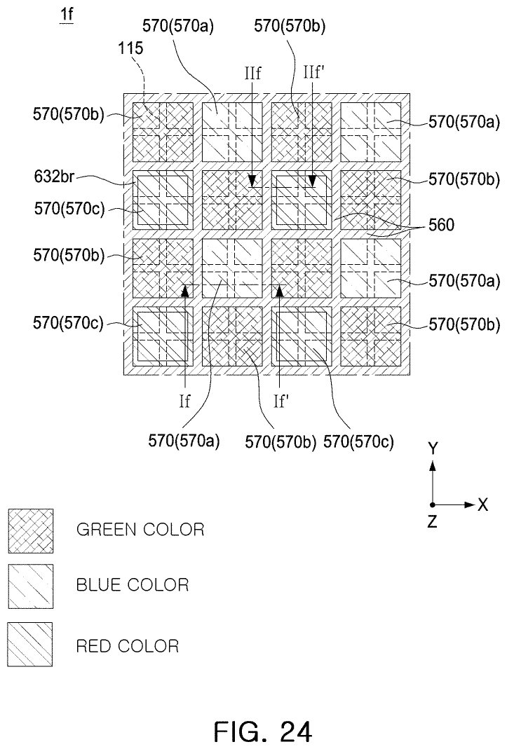

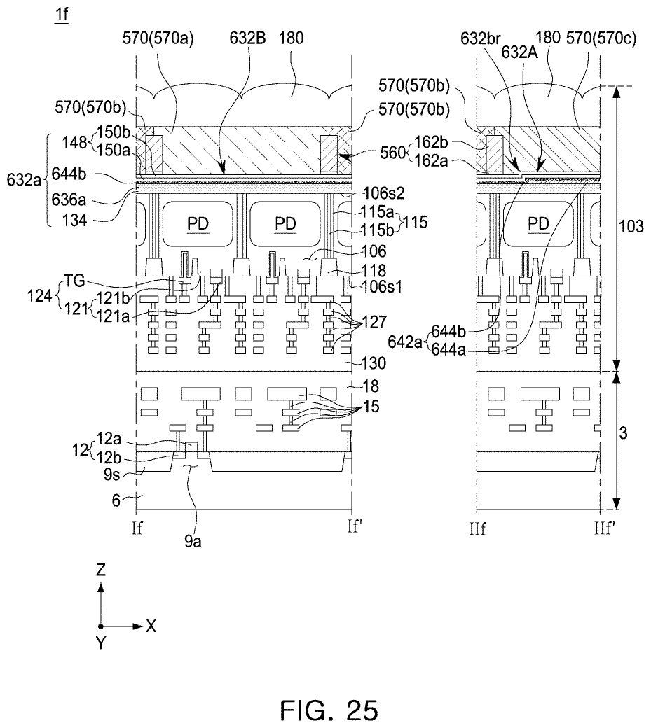

In the description below, an example of an image sensor in some example embodiments will be described with reference to FIGS. 24 and 25.

FIG. 24 is a diagram illustrating an image sensor according to some example embodiments, viewed from above, and FIG. 25 is a cross-sectional diagram illustrating regions taken along the lines If-If′ and IIf-IIf′.

Referring FIGS. 24 and 25, an image sensor if in the modified example may include an insulating structure 632a which may replace the insulating structure 532a (in FIG. 20) in the image sensor 1e in FIG. 20. Accordingly, the image sensor if may include the same color filters 570 and the grid structure 560 as the image sensor 1e in FIG. 20.

The insulating structure 632a may include a lower layer 134, intermediate layers 636a and 642a, and an upper layer 148 stacked in sequence. The lower layer 134 and the upper layer 148 may be substantially the same as the examples described with reference to FIG. 2. The intermediate layers 636a and 642a may include a first intermediate layer 636a and a second intermediate layer 642a stacked in sequence. The first intermediate layer 636a may include substantially the same material as that of the first intermediate layer 136a in FIG. 2, such as, for example, a high-κ material such as hafnium oxide, and the second intermediate layer 642a may include silicon oxide.

The insulating structure 632a may include a first region 632A and a second region 632B having a thickness lower than a thickness of the first region 632A.

In the first region 632A of the insulating structure 632a, the second intermediate layer 642a may include a first layer 644a and a second layer 644b stacked in sequence, and, in the second region 632B of the insulating structure 632a, the second intermediate layer 642a may include the second layer 644b.

In some example embodiments, the first layer 644a and the second layer 644b of the second intermediate layer 642a may include the same material, such as, for example, silicon oxide. In some example embodiments, the first layer 644a and the second layer 644b of the second intermediate layer 642a may be formed of different materials.

The second intermediate layer 642a may include a maximum thickness portion including the first and second layers 644a and 644b and a minimum thickness portion including the second layer 644b. According to the thickness difference depending on the position of the second intermediate layer 642a, there may be a difference in thickness between the first and second regions 632A and 632B of the insulating structure 632a.

In the insulating structure 632a, a region in which the thickness changes, that is, a boundary region 632br between the first region 632A and the second region 632B may vertically overlap the third color filters 570c and may be spaced apart from the grid structure 560.

In the diagram viewed from above, the boundary region 632br between the first region 632A and the second region 632B may also be described as a boundary region between a center portion and an edge portion in each of the third color filters 570c.

The image sensor if may include the insulating structure 632a in which thicknesses of the first and second regions 632A and 632B change according to a change in the thickness of the second intermediate layer 642a. Accordingly, since the image sensor if may include the insulating structure 632a having a thickness optimized according to wavelengths of the second and third color filters 570b and 570c, by improving transmittance of light passing through the insulating structure 632a through the second and third color filters 570b and 570c, that is, the green color filter 570b and the red color filter 570c, sensitivity of the image sensor 1f may improve.

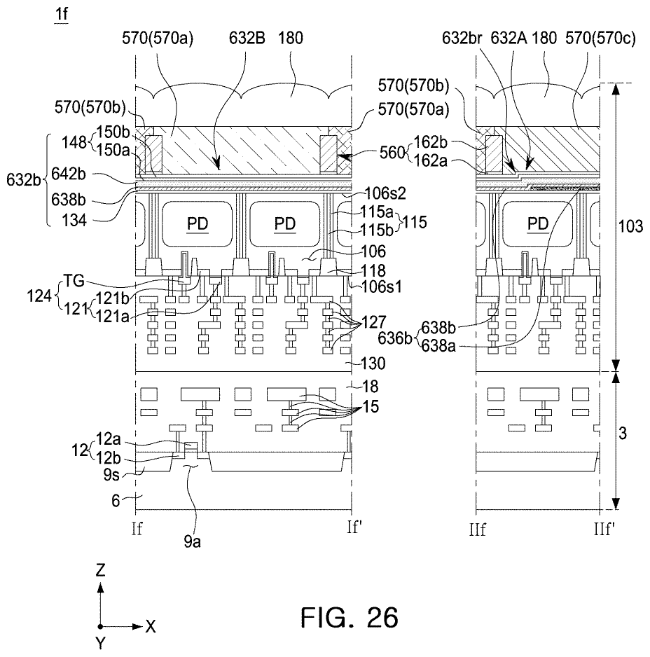

In the description below, a modified example of the insulating structure 632a will be described with reference to FIG. 26.

FIG. 26 is a cross-sectional diagram illustrating regions taken along the If-If′ and IIf-IIf′ lines in FIG. 24, illustrating a modified example of the image sensor some example embodiments.

Referring to FIGS. 24 and 26, an insulating structure 632b as illustrated in FIG. 26 which may replace the insulating structure 632a in FIG. 25 may include a lower layer 134, an intermediate layer 636b and 642b, and an upper layer 148 stacked in sequence. The lower layer 134 and the upper layer 148 may be substantially the same as the examples described with reference to FIG. 2. The intermediate layers 636b and 642b may include a first intermediate layer 636b and a second intermediate layer 642b stacked in sequence. The first intermediate layer 636b may include substantially the same material as that of the first intermediate layer 136a in FIG. 2, such as, for example, a high-κ material such as hafnium oxide, and the second intermediate layer 642b may include silicon oxide.

The insulating structure 632b may include the first region 632A having a first thickness and the second region 632B having a second thickness greater than the first thickness, as described with reference to FIG. 25.

In the first region 632A of the insulating structure 632b, the first intermediate layer 636b may include a first layer 638a and a second layer 638b stacked in sequence, and, in the second region 632B of the insulating structure 632b, the first intermediate layer 636b may include the second layer 638b.

In some example embodiments, the first layer 638a and the second layer 638b of the first intermediate layer 636b may include the same material, such as, for example, hafnium oxide. In some example embodiments, the first layer 638a and the second layer 638b of the first intermediate layer 636b may be formed of different materials.

The first intermediate layer 636b may include a relatively thick portion including the first and second layers 638a and 638b and a relatively thin portion including the second layer 638b. According to the thickness difference depending on the position of the first intermediate layer 636b, there may be a difference in thickness between the first and second regions 632A and 632B of the insulating structure 632b as described with reference to FIG. 25.

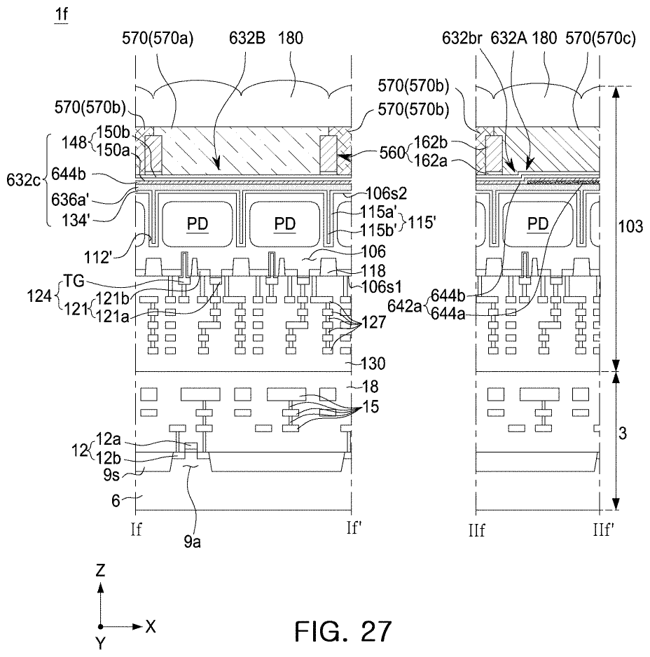

In the description below, a modified example of the separation structure 115 of the image sensor if in FIGS. 25 and 26 will be described with reference to FIG. 27.

FIG. 27 is a cross-sectional diagram illustrating regions taken along the If-If′ and IIf-IIf′ lines in FIG. 24, illustrating a modified example of the image sensor in some example embodiments.

Referring to FIG. 27, the separation structure 115 in FIGS. 25 and 26 may be modified to form a separation structure 115′ disposed in the opening 112′ as described with reference to FIG. 4A. The separation structure 115′ may include at least two layers, such as, for example, a first layer 115a′ and a second layer 115b′ on the first layer 115a′. As in FIGS. 25 and 26, the insulating structure (632a in FIG. 25 or 632b in FIG. 26) including the first region 632A and the second region 632B having different thicknesses may be modified to form an insulating structure 632c extending into the opening 112′.

In some example embodiments, the insulating structure 632c may include a lower layer 134′, intermediate layers 636a′ and 642a, and an upper layer 148 stacked in sequence. The intermediate layers 636a′ and 642a may include a first intermediate layer 636a′ and a second intermediate layer 642a stacked in sequence. The lower layer 134′ may extend into the opening 112′ and may be included in a first layer 115a′ of the separation structure 115′, and a portion of the intermediate layer 636a′ and 642a, such as, for example, the first intermediate layer 636a′ may extend into the opening 112′ and may be included in the second layer 115b′ of the separation structure 115′.

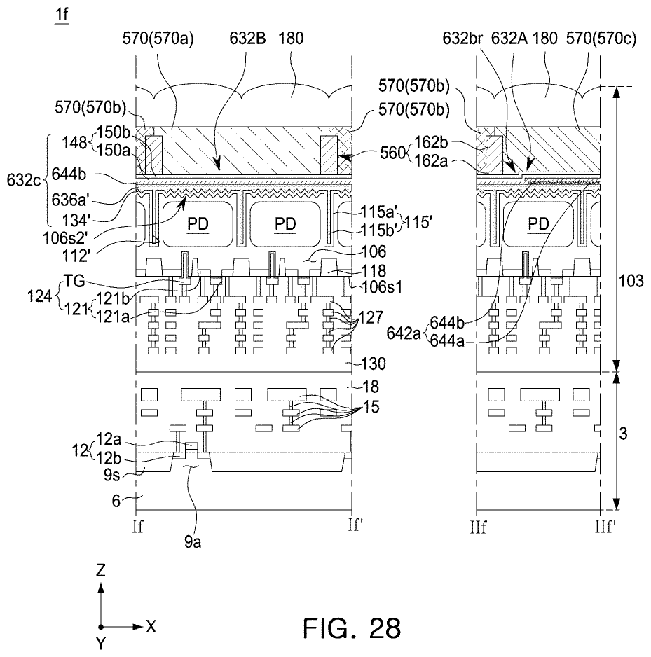

In the description below, a modified example of the second surface 106s2 of the second substrate 106 in FIGS. 25, 26 and 27 will be described with reference to FIG. 28.

FIG. 28 is a cross-sectional diagram illustrating regions taken along the If-If′ and IIf-IIf′ lines in FIG. 24, illustrating a modified example of the image sensor in some example embodiments.

Referring to FIGS. 24 and 28, in FIGS. 25, 26 and 27 described above, the second surface 106s2 of the second substrate 106 may be substantially planar, but may be modified to form the second surface 106s2′ having an uneven structure as described with reference to FIGS. 4C and 4D.

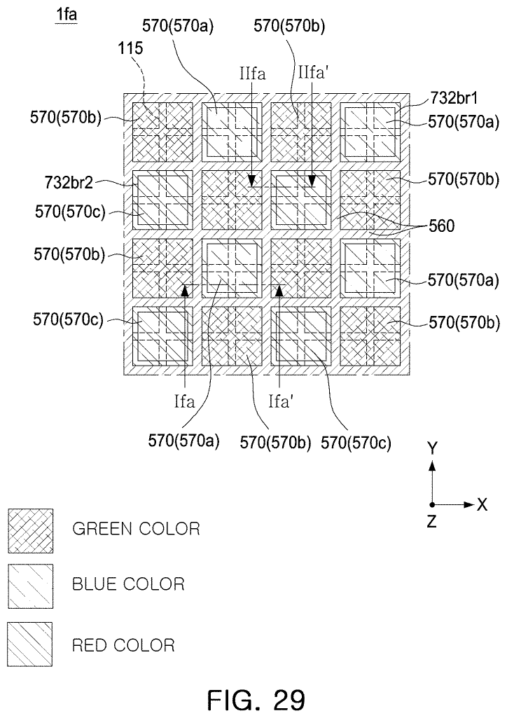

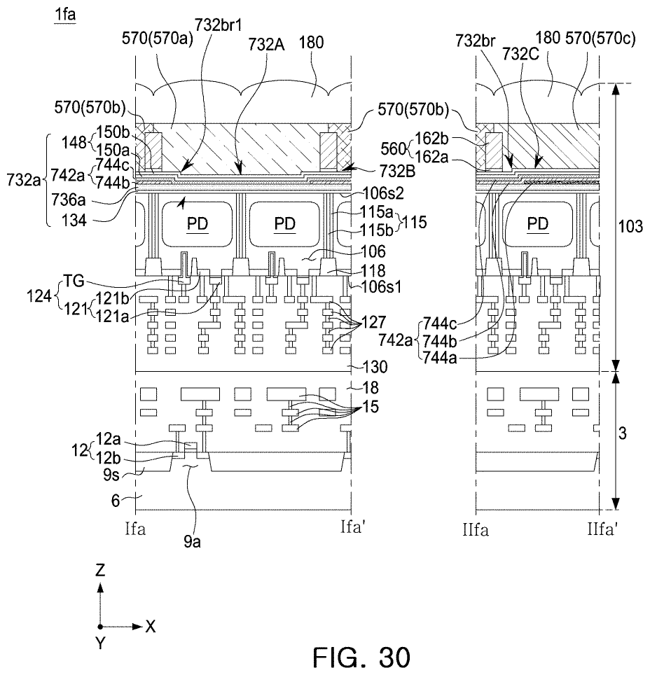

In the description below, an example of an image sensor in some example embodiments will be described with reference to FIGS. 29 and 30.

FIG. 29 is a diagram illustrating an image sensor according to some example embodiments, viewed from above, and FIG. 30 is a cross-sectional diagram illustrating regions taken along the lines Ifa-Ifa′ and IIfa-IIfa′.

Referring to FIGS. 29 and 30, an image sensor 1fa in the modified example may include an insulating structure 732a which may replace the insulating structure 532a in the image sensor 1e in FIG. 20. Accordingly, the image sensor 1fa may include the same color filters 570 and the grid structure 560 as the image sensor 1e in FIG. 20.

The insulating structure 732a may include a lower layer 134, intermediate layers 736a and 742a, and an upper layer 148 stacked in sequence. The lower layer 134 and the upper layer 148 may be substantially the same as the examples described with reference to FIG. 2. The intermediate layers 736a and 742a may include a first intermediate layer 736a and a second intermediate layer 742a stacked in sequence. The first intermediate layer 736a may include substantially the same material as that of the first intermediate layer 136a in FIG. 2, such as, for example, a high-κ material such as hafnium oxide, and the second intermediate layer 742a may include silicon oxide.

The insulating structure 732a may include a first region 732A, a second region 732B having a thickness greater than a thickness of the first region 732A, and a third region 732C having a thickness greater than a thickness of the second region 732B.

In the third region 732C of the insulating structure 732a, the second intermediate layer 742a may include a first layer 744a, a second layer 744b and a third layer 744c stacked in sequence, in the second region 732B of the insulating structure 732a, the second intermediate layer 742a may include the second layer 744b and the third layer 744c stacked in sequence, and in the first region 732A of the insulating structure 732a, the second intermediate layer 742a may include the third layer 744c.

In some example embodiments, the first layer 744a, the second layer 744b, and the third layer 744c of the second intermediate layer 742a may include the same material, such as, for example, silicon oxide. In some example embodiments, at least two of the first layer 744a, the second layer 744b, and the third layer 744c of the second intermediate layer 742a may be formed of different materials.

The second intermediate layer 742a may include a maximum thickness portion including the first to third layers 744a, 744b, and 744c, an intermediate portion including the second and third layers 744b and 744c, and a minimum thickness portion including the third layer 744c. According to the thickness difference depending on the position of the second intermediate layer 742a, there may be a difference in thickness between the first to third regions 732A, 732B, and 732C of the insulating structure 732a.

The second color filters 570b, an edge portion each of the third color filters 570c, an edge portion of each of the first color filters 570a, the grid structure 560 may be disposed on the second region 732B of the insulating structure 732a, and a center portion of each of the third color filters 570c may be disposed on the third region 732C of the insulating structure 732a, and a central portion of each of the first color filters 570a may be disposed on the first region 732A of the insulating structure 732a.

In the insulating structure 732a, a region in which the thickness changes, that is, a first boundary region 732br1 between the first region 732A and the second region 732B may vertically overlap the first color filters 570a and may be spaced apart from the grid structure 560, and a second boundary region 732br2 between the second region 732B and the third region 732C may vertically overlap the third color filters 570c and may be spaced apart from the grid structure 560.

In the diagram viewed from above, the first boundary region 732br1 between the first region 732A and the second region 732B may be described as a boundary region between a center portion and an edge portion in each of the first color filters 570a, and the second boundary region 732br2 between the second region 732B and the third region 732C may be described as a boundary region between a central portion and an edge portion in each of the third color filters 570c.

The image sensor 1fa may include the insulating structure 732a in which the thickness of the first to third regions 732A, 732B, and 723C changes according to a change in the thickness of the second intermediate layer 742a. Accordingly, since the image sensor 1fa may include the insulating structure 732a having a thickness optimized according to wavelengths of the first, second and third color filters 570a, 570b, and 570c, by improving transmittance of light passing through the insulating structure 732a through the first, second, and third color filters 570a, 570b, and 570c, that is, the blue color filter 570a, the green color filter 570b, and the red color filter 570c, sensitivity of the image sensor 1fa may improve.

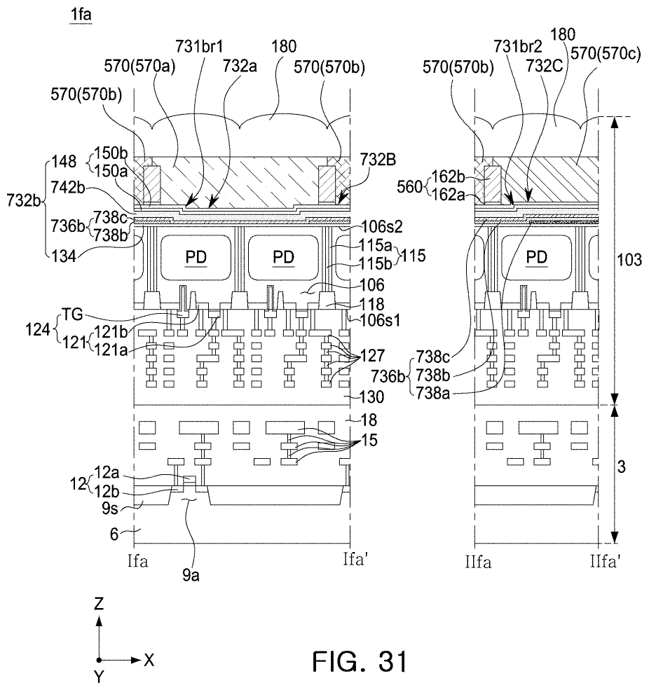

In the description below, a modified example of the insulating structure 732a will be described with reference to FIG. 31.

FIG. 31 is a cross-sectional diagram illustrating regions taken along lines Ifa-Ifa′ and IIfa-IIfa′ in FIG. 29, illustrating a modified example of the image sensor in some example embodiments.

Referring to FIGS. 29 and 31, an insulating structure 732b as illustrated in FIG. 31 which may replace the insulating structure 732a in FIG. 30 may include a lower layer 134, intermediate layers 736b and 742b, and an upper layer 148 stacked in sequence. The lower layer 134 and the upper layer 148 may be substantially the same as the examples described with reference to FIG. 2. The intermediate layers 736b and 742b may include a first intermediate layer 736b and a second intermediate layer 742b stacked in sequence. The first intermediate layer 736b may include substantially the same material as that of the first intermediate layer 136a in FIG. 2, such as, for example, a high-κ material such as hafnium oxide, and the second intermediate layer 742b may include silicon oxide.

As described with reference to FIG. 31, the insulating structure 732b may include the first region 732A, the second region 732B having a thickness greater than the thickness of the first region 732A, and the third region 732C having a thickness greater than that of the second region 732B.

In the third region 732C of the insulating structure 732b, the first intermediate layer 736b may include a first layer 738a, a second layer 738b and a third layer 738c stacked in sequence, and in the second region 732B of the insulating structure 732b, the first intermediate layer 736b may include the second layer 738b and the third layer 738c stacked in sequence, and in the first region 732A of the insulating structure 732b, the first intermediate layer 736b may include the third layer 738c.

In some example embodiments, the first layer 738a, the second layer 738b, and the third layer 738c of the first intermediate layer 736b may include the same material, such as, for example, hafnium oxide. In some example embodiments, at least two of the first layer 738a, the second layer 738b, and the third layer 738c of the first intermediate layer 736b may be formed of different materials.

The first intermediate layer 736b may include a maximum thickness portion including the first to third layers 738a, 738b, and 738c, an intermediate thickness portion including the second and third layers 738b and 738c, a minimum thickness portion including the third layer 738c. According to the thickness difference depending on the position of the first intermediate layer 736b, the thickness difference between the first to third regions 732A, 732B, and 732C of the insulating structure 732b as illustrated in FIG. 30.

In some example embodiments, the separation structure 115 in FIGS. 30 and 31 may be modified to form the a separation structure 115′ including a first layer 116a′, a second layer 116b′, and a third layer 116c as in FIG. 4a, and the insulating structure (732a in FIG. 30 or 732b in FIG. 31) including the first region 732A, the second region 732B, and the third region 732C having different thicknesses as in FIGS. 30 and 31 may be modified to form an insulating structure including a portion extending into the opening 112′ (FIG. 4a) extending in a direction from the second surface 106s2 of the second substrate 106 toward the first surface 106s1 as in FIG. 4A.

In some example embodiments, in FIGS. 30 and 31, the second surface 106s2 of the second substrate 106 may be substantially planar, but as described with reference to FIGS. 4C and 4D, the second surface 106s2 may be modified to form the second surface 106s2′ having an uneven structure as described with reference to FIGS. 4C and 4D.

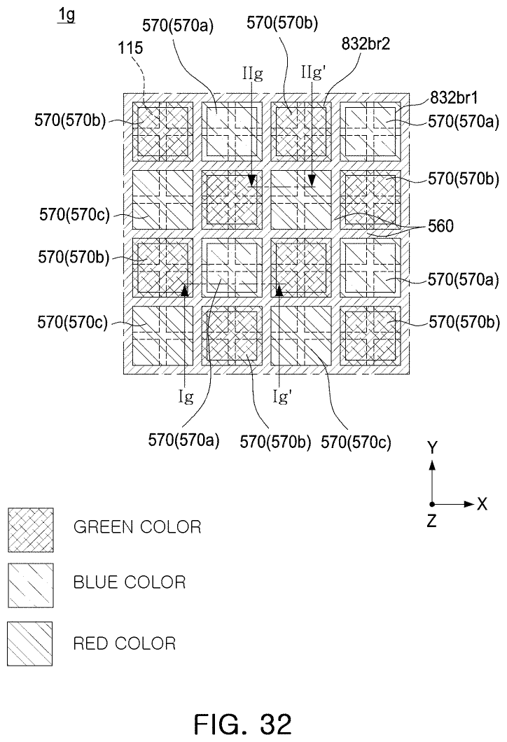

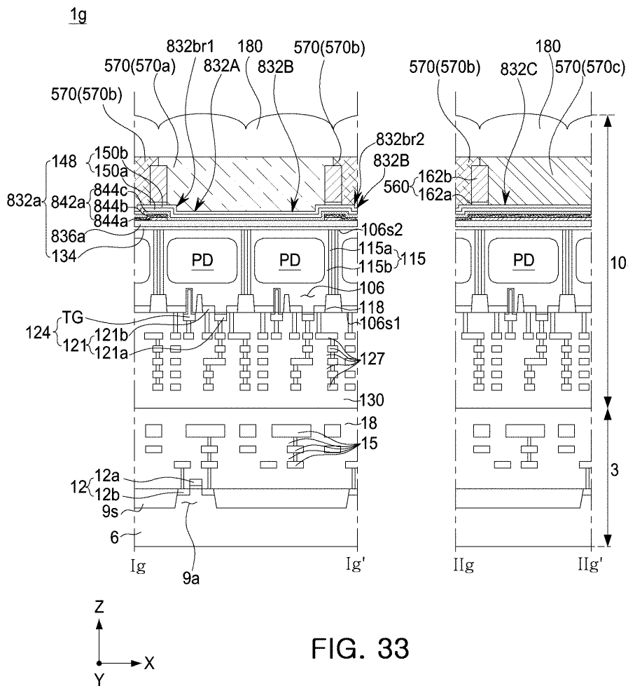

In the description below, an example of an image sensor in some example embodiments will be described with reference to FIGS. 32 and 33.

FIG. 32 is a diagram illustrating an image sensor according to some example embodiments, viewed from above, and FIG. 33 is a cross-sectional diagram illustrating regions taken along the line Ig-Ig′ and IIg-IIg′.

Referring to FIGS. 32 and 33, an image sensor 1g in the modified example may include an insulating structure 832a which may replace the insulating structure 532a (in FIG. 20) in the image sensor 1e in FIG. 20.

The insulating structure 832a may include a lower layer 134, intermediate layers 836a and 842a, and an upper layer 148 stacked in sequence. The lower layer 134 and the upper layer 148 may be substantially the same as the examples described with reference to FIG. 2. The intermediate layers 836a and 842a may include a first intermediate layer 836a and a second intermediate layer 842a stacked in sequence. The first intermediate layer 836a may include substantially the same material as that of the first intermediate layer 136a in FIG. 2, such as, for example, a high-κ material such as hafnium oxide, and the second intermediate layer 842a may include silicon oxide.

The insulating structure 832a may include a first region 832A, a second region 832B having a thickness greater than a thickness of the first region 832A, and a third region 832C having a thickness greater than a thickness of the second region 832B.

In the third region 832C of the insulating structure 832a, the second intermediate layer 842a may include a first layer 844a, a second layer 844b and a third layer 844c stacked in sequence, in the second region 832B of the insulating structure 832a, the second intermediate layer 842a may include the second layer 844b and the third layer 844c, and in the first region 832A of the insulating structure 832a, the second intermediate layer 842a may include the third layer 844c.

In some example embodiments, the first layer 844a, the second layer 844b, and the third layer 844c of the second intermediate layer 842a may include the same material, such as, for example, silicon oxide. In some example embodiments, at least two of the first layer 844a, the second layer 844b, and the third layer 844c of the second intermediate layer 842a may be formed of different materials.

The second intermediate layer 842a may include a maximum thickness portion including the first to third layers 844a, 844b, and 844c, an intermediate thickness portion including the second and third layers 844b and 844c, and a minimum thickness portion including the third layer 844c. According to the thickness difference depending on the position of the second intermediate layer 842a, there may be a difference in thickness between the first to third regions 832A, 832B, and 832C of the insulating structure 832a.

A center portion of each of the first color filters 570a may be disposed on the first region 832A of the insulating structure 832a, a center portion of each of the second color filters 570b may be disposed on the second region 832B of the insulating structure 832a, and the third color filters 570c, an edge portion of each of the first color filters 570a, an edge portion of each of the second color filters 570b, and the grid structure 560 may be disposed on the second region 832B of the insulating structure 832a.

In the insulating structure 832a, a region in which the thickness changes, that is, a first boundary region 832br1 between the first region 832A and the second region 832B may vertically overlap the first color filters 570a and may be spaced apart from the grid structure 560, and a second boundary region 832br2 between the second region 832B and the third region 832C vertically overlap the second color filters 570b and may be spaced apart from the grid structure 560.

In the diagram viewed from above, the first boundary region 832br1 between the first region 832A and the second region 832B may be described as a boundary region between a center portion and an edge portion in each of the first color filters 570a, and the second boundary region 832br2 between the second region 832B and the third region 832C may be described as a boundary region between a boundary region between a central portion and an edge portion in each of the second color filters 570b.

The image sensor 1g may include the insulating structure 832a in which the thickness of the first to third regions 832A, 832B, and 833C changes according to a change in the thickness of the second intermediate layer 842a. Accordingly, since the image sensor 1g may include the insulating structure 832a having a thickness optimized according to wavelengths of the first, second and third color filters 570a, 570b, and 570c, by improving transmittance of light passing through the insulating structure 832a through the first, second, and third color filters 570a, 570b, and 570c, that is, the blue color filter 570a, the green color filter 570b, and the red color filter 570c, sensitivity of the image sensor 1g may improve.

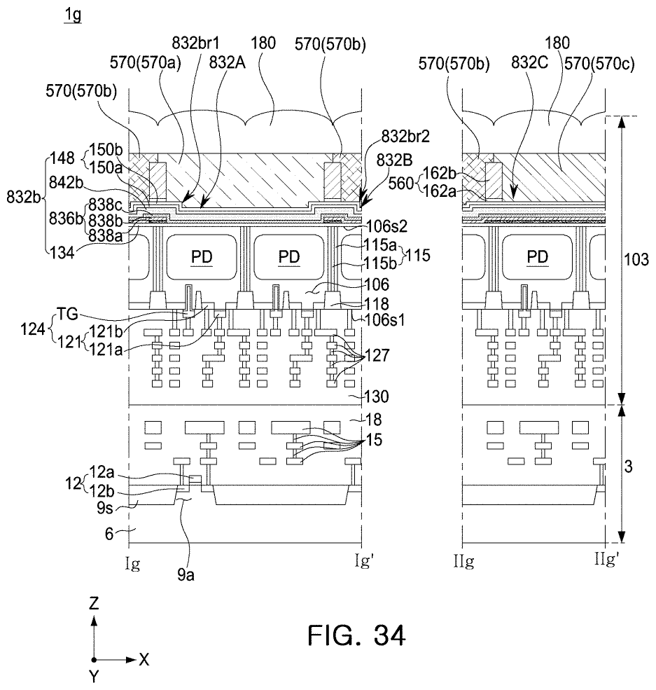

In the description below, a modified example of the insulating structure 832a will be described with reference to FIG. 34.

FIG. 34 is a cross-sectional diagram illustrating regions taken along lines Ig-Ig′ and IIg-IIg′ in FIG. 32, illustrating a modified example of the image sensor in some example embodiments.

Referring to FIGS. 32 and 34, an insulating structure 832b as illustrated in FIG. 34 which may replace the insulating structure 732a in FIG. 30 may include a lower layer 134, intermediate layers 836b and 842b, and an upper layer 148 stacked in sequence. The lower layer 134 and the upper layer 148 may be substantially the same as the examples described with reference to FIG. 2. The intermediate layers 836b and 842b may include a first intermediate layer 836b and a second intermediate layer 842b stacked in sequence. The first intermediate layer 836b may include substantially the same material as that of the first intermediate layer 136a in FIG. 2, such as, for example, a high-κ material such as hafnium oxide, and the second intermediate layer 842b may include silicon oxide.

As described with reference to FIG. 34, the insulating structure 832b may include the first region 832A, the second region 832B having a thickness greater than the thickness of the first region 832A, and a third region 832C having a thickness greater than the thickness of the second region 832B.

In the third region 832C of the insulating structure 832b, the first intermediate layer 836b may include a first layer 838a, a second layer 838b and a third layer 838c stacked in sequence, in the second region 832B of the insulating structure 832b, the first intermediate layer 836b may include the second layer 838b and the third layer 838c stacked in sequence, and in the first region 832A of the insulating structure 832b, the first intermediate layer 836b may include the third layer 838c.

In some example embodiments, the first layer 838a, the second layer 838b, and the third layer 838c of the first intermediate layer 836b may include the same material, such as, for example, hafnium oxide. In some example embodiments, at least two of the first layer 838a, the second layer 838b, and the third layer 838c of the first intermediate layer 836b may be formed of different materials.

The first intermediate layer 836b may include a maximum thickness portion including the first to third layers 838a, 838b, and 838c, an intermediate thickness portion including the second and third layers 838b and 838c, and a minimum thickness portion including the third layer 838c. According to the thickness difference depending on the position of the first intermediate layer 836b, there may be a difference in thickness between the first to third regions 832A, 832B, and 832C of the insulating structure 832b as in FIG. 33.

In some example embodiments, the separation structure 115 in FIGS. 33 and 34 may be modified to form a separation structure 115′ including a first layer 116a′, a second layer 116b′ and a third layer 116c′ as in FIG. 4A, and the insulating structure (832a in FIG. 33 or 832b in FIG. 34) including the first region 832A, the second region 832B, and the third region 832C having different thicknesses as in FIGS. 33 and 34 may be modified to form an insulating structure including a portion extending into the opening 112′ (in FIG. 4A) extending in a direction from the second surface 106s2 of the second substrate 106 toward the first surface 106s1 as in FIG. 4A.

In some example embodiments, in FIGS. 33 and 34, the second surface 106s2 of the second substrate 106 may be substantially planar, but as described with reference to FIGS. 4C and 4D, the second surface 106s2 may be modified to form the second surface 106s2′ having an uneven structure as described with reference to FIGS. 4C and 4D.

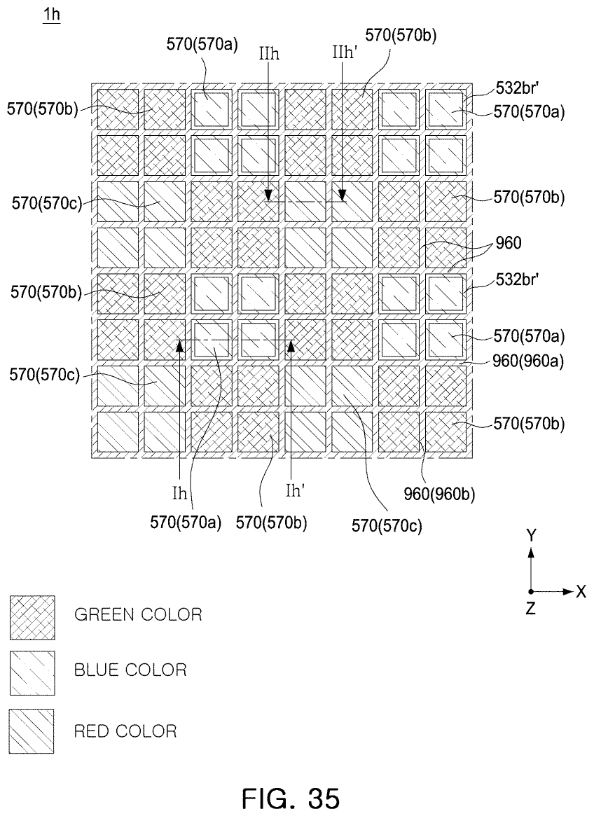

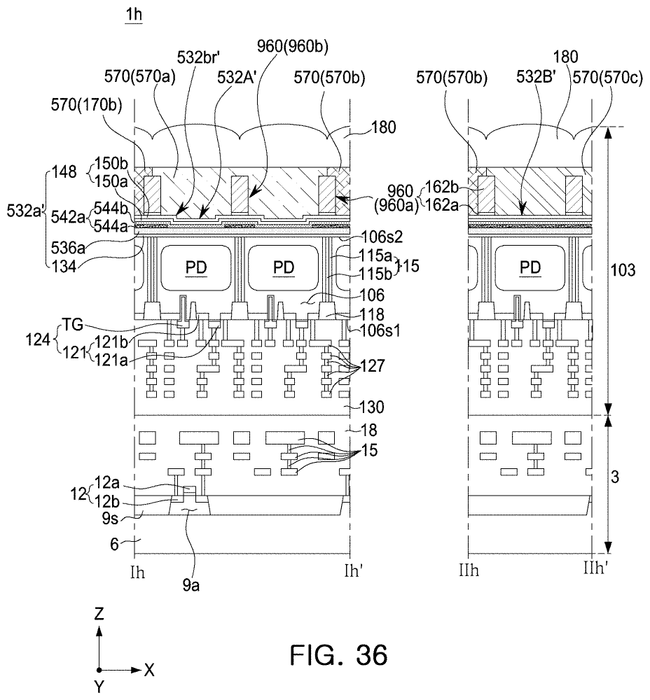

In the description below, a modified example of the image sensor 1e described with reference to FIGS. 19 to 23 will be described with reference to FIGS. 35 and 36.

FIG. 35 is a diagram illustrating an image sensor according to some example embodiments, viewed from above, and FIG. 36 is a cross-sectional diagram illustrating regions taken along lines Ih-Ih′ and IIh-IIh′.

Referring to FIGS. 35 and 36, an image sensor 1h in a modified example may include a grid structure 960 which may replace the grid structure 560 (in FIGS. 19 and 20) described above, and an insulating structure 532a′ which may replace the insulating structure 532a (in FIGS. 19 and 20) described above.

In the diagram viewed from above, the grid structure 560 described with reference to FIGS. 19 and 20 may be replace with a grid structure 960 further including a portion crossing each of the color filters 570 in the X direction and the Y direction. For example, the grid structure 960 may include a first portion 960a crossing a region between the color filters 570 and a second portion 960b crossing each of the color filters 570 in the X and Y directions. The second portion 960b of the grid structure 960 may cross one of the first color filters 570a in the X direction.

The insulating structure 532a′ may include a first region 532A′ and a second region 532B′ having a thickness greater than that of the first region 532A′ as described with reference to FIG. 20.

The third color filters 570c, the second color filters 570b, portions adjacent to the grid structure 960 in the first color filters 570a, and the grid structure 960 may be disposed on the second region 532B′ of the insulating structure 532a′, and the central portion of each of the first color filters 570a surrounded by the grid structure 960 in the diagram viewed from above may be disposed on the first region 532A′ of the insulating structure 532a′.

In the insulating structure 532a′, a region where the thickness changes, that is, a boundary region 532br′ between the first region 532A′ and the second region 532B′ may vertically overlap the first color filters 570a and may be spaced apart from the grid structure 960.

In some example embodiments, the thickness of the insulating structure 532a′ may change according to a change in the thickness of the second intermediate layer 542a as in FIG. 20.

In some example embodiments, the thickness of the insulating structure 532a′ may change according to a change in the thickness of the first intermediate layer 536b as in FIG. 21.

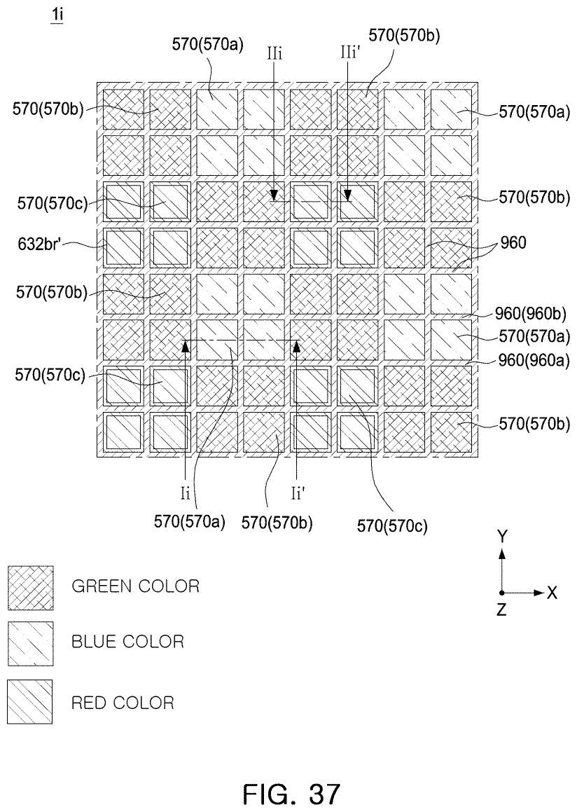

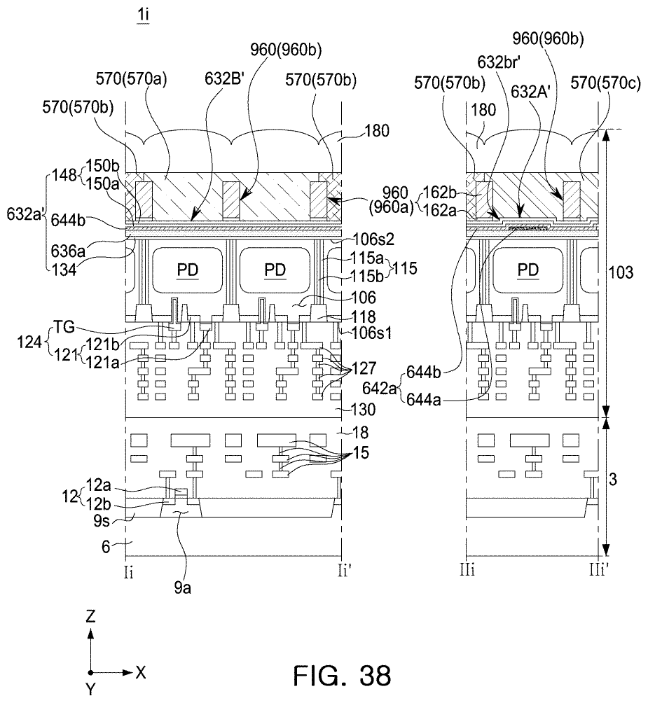

In the description below, a modified example of an image sensor if described with reference to FIGS. 24 to 28 will be described with reference to FIGS. 37 and 38.

FIG. 37 is a diagram illustrating an image sensor according to some example embodiments, viewed from above, and FIG. 38 is a cross-sectional diagram illustrating regions taken along lines Ii-Ii′ and IIi-IIi′.

Referring to FIGS. 37 and 38, the image sensor 1i in the modified example may include a grid structure 960 which may replace the grid structure 560 (in FIGS. 24 and 25) described above, and an insulating structure 632a′ which may replace the insulating structure 632a (in FIGS. 24 and 25) described above.

In the diagram viewed from above, the grid structure 560 described with reference to FIGS. 24 and 25 may be replaced with the grid structure 960 described with reference to FIGS. 35 and 36.

The insulating structure 632a′ may include a first region 632A′ and a second region 632B′ having a thickness smaller than that of the first region 632A′.

The first color filters 570a, the second color filters 570b, portions adjacent to the grid structure 960 in the third color filters 570c, and the grid structure 960 may be disposed on the second region 632B′ of the insulating structure 632a′, and a central portion of each of the third color filters 570c surrounded by the grid structure 960 in the diagram viewed from above may be disposed on the first region 632A′ of the insulating structure 632a′.

In the insulating structure 632a′, a region in which the thickness changes, that is, a boundary region 632br′ between the first region 632A′ and the second region 632B′ may vertically overlap the third color filters 570c and may be spaced apart from the grid structure 960.

In some example embodiments, the thickness of the insulating structure 632a′ may change according to a change in the thickness of the second intermediate layer 642a as in FIG. 25.

In some example embodiments, the thickness of the insulating structure 632a′ may change according to a change in the thickness of the first intermediate layer 636b as in FIG. 26.

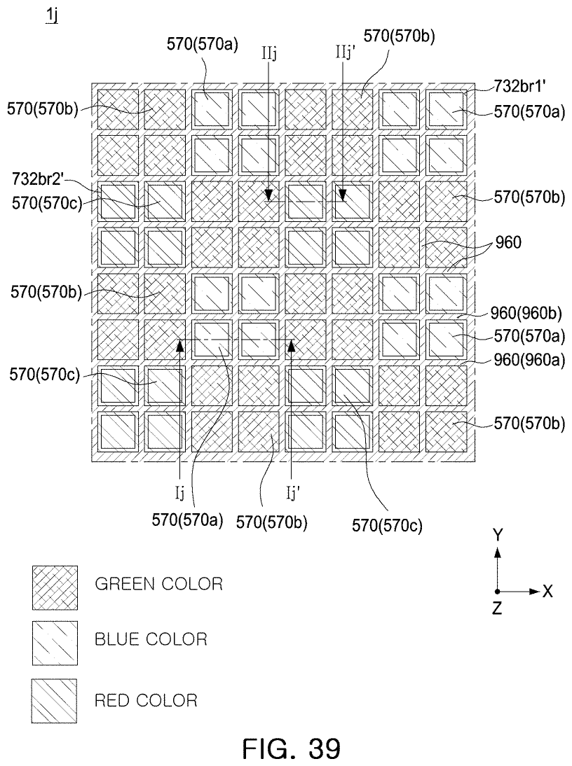

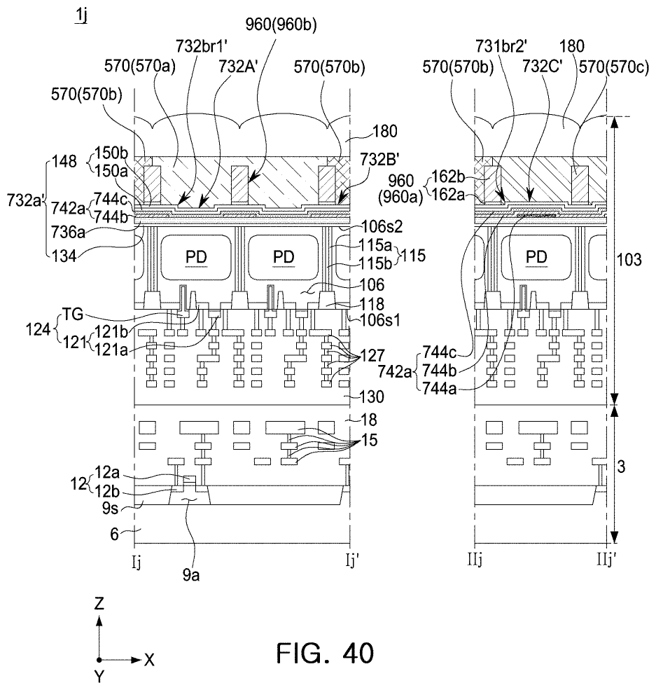

In the description below, a modified example of the image sensor 1fa described with reference to FIGS. 29 to 31 will be described with reference to FIGS. 39 and 40.

FIG. 39 is a diagram illustrating an image sensor according to some example embodiments, viewed from above, and FIG. 40 is a cross-sectional diagram illustrating regions taken along lines Ij-Ij′ and IIj-IIj′.

Referring to FIGS. 39 and 40, an image sensor 1j in the modified example may include a grid structure 960 which may replace the grid structure 560 (in FIGS. 29 and 30) described above, and an insulating structure 732a′ which may replace the insulating structure 732a (in FIGS. 29 and 30) described above.

In the diagram viewed from above, the grid structure 560 described with reference to FIGS. 24 and 25 may be replaced with the grid structure 960 described with reference to FIGS. 35 and 36.

The insulating structure 732a′ may include a first region 732A′ and a second region 732B′ having thickness greater than that of the first region 732A′ described with reference to FIG. 30.

The second color filters 570b, portions of the third color filters 570c adjacent to the grid structure 960, portions of the first color filters 570a adjacent to the grid structure 960, and the grid structure 960 may be disposed on the second region 732B′ of the insulating structure 732a′, a central portion of each of the third color filters 570c surrounded by the grid structure 960 in the diagram viewed from above may be disposed on the third region 732C′ of the insulating structure 732a′, and a central portion of each of the first color filters 570a surrounded by the grid structure 960 may be disposed on the first region 732A′ of the insulating structure 732a′.

In the insulating structure 732a′, a region in which the thickness changes, that is, a first boundary region 732br1′ between the first region 732A′ and the second region 732B′, may vertically overlap the first color filters 570a may be spaced apart from the grid structure 960, and a second boundary region 732br2′ between the second region 732B′ and the third region 732C′ may vertically overlap the third color filters 570c and may be spaced apart from the grid structure 960.

In some example embodiments, the thickness of the insulating structure 732a′ may change according to a change in the thickness of the second intermediate layer 742a as in FIG. 30.

In some example embodiments, the thickness of the insulating structure 732a′ may change according to a change in the thickness of the first intermediate layer 736b as in FIG. 31.

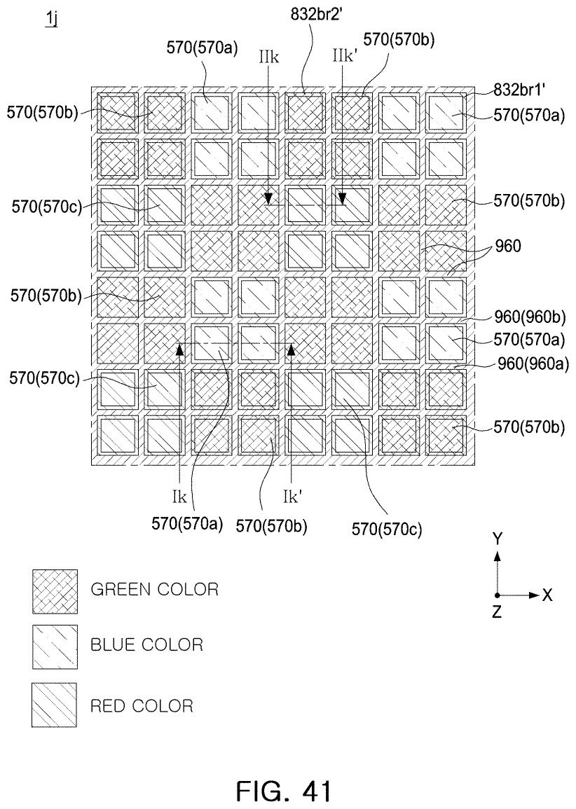

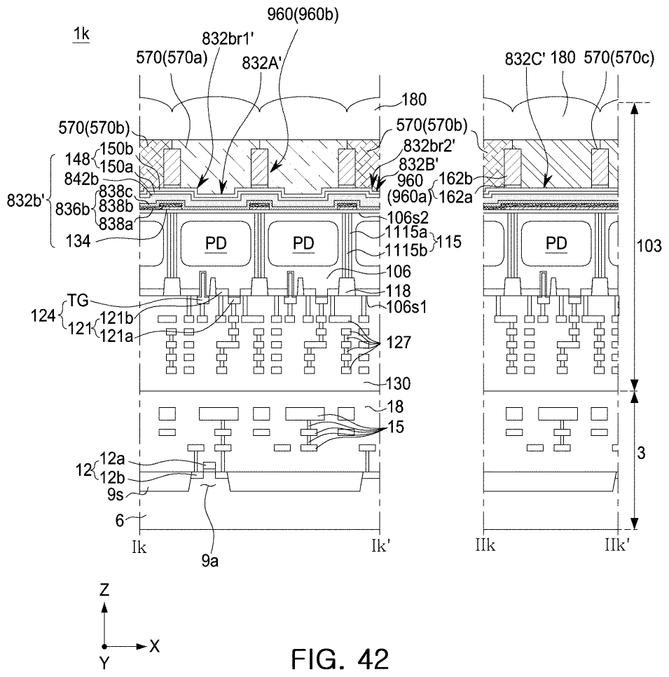

In the description below, a modified example of an image sensor 1g described with reference to FIGS. 32 to 34 will be described with reference to FIGS. 41 and 42.

FIG. 41 is a diagram illustrating an image sensor according to some example embodiments, viewed from above, and FIG. 42 is a cross-sectional diagram illustrating regions taken along lines Ik-Ik′ and Ilk-Ilk′.

Referring to FIGS. 41 and 42, the image sensor 1k in the modified example may include a grid structure 960 which may replace the grid structure 560 (in FIGS. 32 and 33) described above, and an insulating structure 832a′ which may replace the insulating structure 832a (in FIGS. 32 and 33) described above.

In the diagram viewed from above, the grid structure 560 described with reference to FIGS. 32 and 33 may be replaced with the grid structure 960 described with reference to FIGS. 35 and 36.

The insulating structure 832a′ may include a first region 832A′, a second region 832B′ having a thickness greater than that of the first region 832A′, and a third region 832C′ having a thickness greater than a thickness of the second region 832B′ as described with reference to FIG. 33.

The third color filters 570c, portions of the second color filters 570b adjacent to the grid structure 960, portions of the first color filters 570a adjacent to the grid structure 960, and the grid structure 960 may be disposed on the third region 832C′ of the insulating structure 832a′, a central portion of each of the second color filters 570b surrounded by the grid structure 960 in the diagram viewed from above may be disposed on the second region 832B′ of the insulating structure 832a′, and a central portion of each of the first color filters 570a surrounded by the grid structure 960 in the diagram viewed from above may be disposed on the first region 832A′ of the insulating structure 832a′.

In the insulating structure 832a′, the region in which the thickness changes, that is, the first boundary region 832br1′ between the first region 832A′ and the second region 832B′, may vertically overlap the first color filters 570a and may be spaced apart from the grid structure 960, and a second boundary region 832br2′ between the second region 832B′ and the third region 832C′ may vertically overlap the second color filters 570b and may be spaced apart from the grid structure 960.

In some example embodiments, the thickness of the insulating structure 832a′ may change according to a change in the thickness of the second intermediate layer 842a as in FIG. 33.

In some example embodiments, the thickness of the insulating structure 832a′ may change according to a change in the thickness of the first intermediate layer 836b as in FIG. 34.

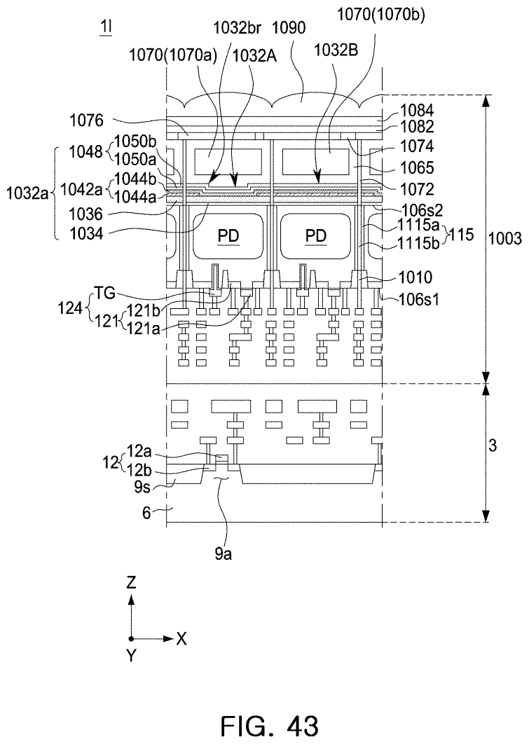

In the description below, with reference to FIG. 43, an image sensor in some example embodiments will be described.

FIG. 43 is a diagram illustrating an image sensor according to some example embodiments, viewed from above.

Referring to FIG. 43, the image sensor 11 may include the first chip structure 3 substantially the same as the example described with reference to FIG. 2.

The image sensor 11 may further include a second chip structure 1003 on the first chip structure 3. The second chip structure 1003 may be configured as an image sensor chip.

The second chip structure 1003 may include a second substrate 106 having a first surface 106s1 and a second surface 106s2 opposing each other, a device isolation layer 118 disposed on the first surface 106s1 of the second substrate 106 and defining an active region, a second circuit device 124 and a second wiring structure 127 disposed between the first surface 106s1 of the second substrate 106 and the first chip structure 3, and a second insulating layer 130 covering the second circuit device 124 and the second wiring structure 127 between the first surface 106s1 of the second substrate 106 and the first chip structure 3. The first surface 106s1 of the second substrate 106 may oppose the first chip structure 3. The second substrate 106 may be configured as a semiconductor substrate. For example, the second substrate 106 may be configured as a substrate formed of a semiconductor material, such as, for example, a single crystal silicon substrate.

The image sensor 11 may further include photoelectric conversion devices PD described with reference to FIG. 2.

The second chip structure 1003 may further include through-electrode structures 1115. The through-electrode structures 1115 may include a conductive pattern 1115b and an insulating spacer 1115a on a side surface of the conductive pattern 1115b. The through-electrode structures 1115 may be disposed between the photoelectric conversion devices PD and may penetrate the second substrate 106.

The second chip structure 1003 may further include an insulating structure 1032a having regions of different thickness from each other.

The second chip structure 1003 may further include an insulating layer 1065 disposed on the insulating structure 1032a and color filters 1070 embedded in the insulating layer 1065. The color filters 1070 may include a blue color filter 1070a allowing light of a blue wavelength to pass and to reach the photoelectric conversion device PD, and a red color filter 1070b allowing light of red wavelength to pass and to reach the photoelectric conversion device PD.

The second chip structure 1003 may include first electrodes 1076 disposed on the insulating layer 1065, an insulating layer 1074 surrounding side surfaces of the first electrodes 1076, and rear contact plugs 1072 electrically connecting the first electrodes 1076 to the conductive patterns 1115b. The first electrodes 1076 may include portions overlapping the color filters 1070.

The first electrodes 1076 may be configured as transparent electrodes. For example, the first electrodes 1076 may be formed of a transparent conductive material such as ITO, IZO, ZnO, SnO2, antimony-doped tin oxide (ATO), Al-doped zinc oxide (AZO), gallium-doped zinc oxide (GZO), TiO₂, or fluorine-doped tin oxide (FTO).

The second chip structure 1003 may include a photoelectric layer 1082 disposed on the first electrodes 1076, a second electrode 1084 disposed on the photoelectric layer 1082, and microlenses 1090 disposed on the second electrode 1084.

In some example embodiments, the photoelectric layer 1082 may be configured as an organic photoelectric layer. For example, the photoelectric layer 1082 may be configured as an organic photoelectric layer formed of an organic material causing photoelectric change only in light of a specific wavelength. For example, the photoelectric layer 1082 may include a p-type layer in which main carriers are holes and an n-type layer in which main carriers are electrons. The photoelectric layer 1082 may generate electric charges in response to light of a specific wavelength band, and in some example embodiments, the photoelectric layer 1082 may generate electric charges in response to light of a green. In this case, light of colors other than green (e.g., blue and red) may be transmitted to the photoelectric conversion devices PD through the color filters 1070.

The second electrode 1084 may be formed of a transparent electrode. For example, the second electrode 1084 may be formed of a transparent conductive material such as ITO, IZO, ZnO, SnO2, antimony-doped tin oxide (ATO), Al-doped zinc oxide (AZO), gallium-doped zinc oxide (GZO), TiO₂, or fluorine-doped tin oxide (FTO).

In some example embodiments, the photoelectric layer 1082 and the first and second electrodes 1076 and 1084 may be included in an organic photoelectric device or an organic photoelectric conversion device. Charges generated in response to light of a green in the photoelectric layer 1082 may be accumulated in storage node regions through the first electrodes 1076, the rear contact plugs 1072, the conductive patterns 1115b in the through-electrode structures 1115, and the front contact plugs 1010.

The insulating structure 1032a may include a plurality of layers stacked in sequence. The insulating structure 1032a may include an anti-reflective layer providing incident light to travel to the photoelectric conversion devices PD with high transmittance by adjusting a refractive index. For example, the insulating structure 1032a may include at least three layers. Accordingly, the insulating structure 1032a may be referred to as an anti-reflective structure.

The insulating structure 1032a may include a lower layer 1034, an intermediate layer 1036a and 1042a on the lower layer 1034, and an upper layer 1048 on the intermediate layer 1036a and 1042a.

The lower layer 1034 and the upper layer 1048 may be substantially the same as the lower layer 134 and the upper layer 148 described with reference to FIG. 2. For example, the upper layer 1048 may include a first layer 1050a and a second layer 1050b stacked in sequence.

The intermediate layers 1036a and 1042a may include a first intermediate layer 1036a and a second intermediate layer 1042a stacked in sequence.

The first intermediate layer 1036a may be substantially the same as the first intermediate layer 136a described with reference to FIG. 2.

The second intermediate layer 1042a may be substantially the same as the second intermediate layer 142a described with reference to FIG. 2. For example, the second intermediate layer 1042a may include a first layer 1044a and a second layer 1044b stacked in sequence.

The insulating structure 1032a may include a first region 1032A having a first thickness and a second region 1032B having a second thickness greater than the first thickness.

In the second region 1032B of the insulating structure 1032a, the second intermediate layer 1042a may include a first layer 1044a and a second layer 1044b stacked in sequence, and in the first region 1032A of the insulating structure 1032a, the second intermediate layer 1042a may include the second layer 1044b. Accordingly, the second intermediate layer 1042a may include a relatively thick portion including the first and second layers 1044a and 1044b and a relatively thin portion including the second layer 1044b. According to the thickness difference depending on the position of the second intermediate layer 1042a, there may be a difference in thickness between the first and second regions 1032A and 1032B of the insulating structure 1032a.

In the insulating structure 1032a, the first region 1032A may be disposed below the blue color filter 1070a, and the second region 1032B may be disposed below the red color filter 1070b.

In the insulating structure 1032a, a boundary region 1032br between the first region 1032A and the second region 1032B in which the thickness of the insulating structure 1032a changes may be disposed below an edge portion of the blue color filter 1070a.

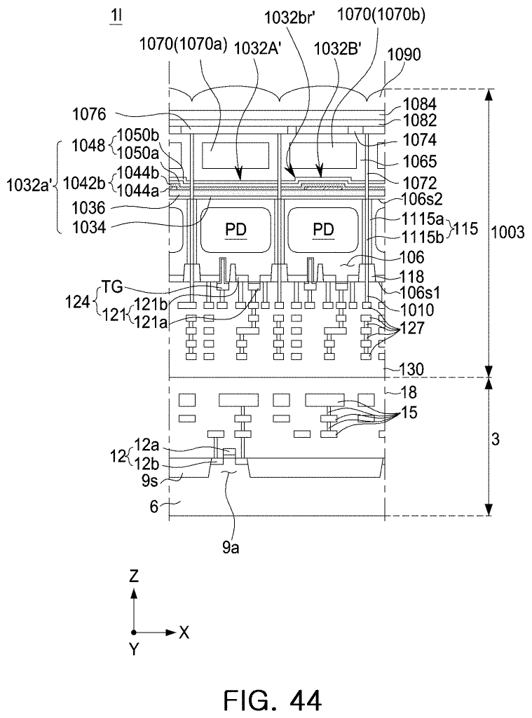

In the description below, an image sensor in some example embodiments will be described with reference to FIG. 44.

FIG. 44 is a diagram illustrating an image sensor according to some example embodiments, viewed from above.

Referring to FIG. 44, the boundary region 1032br between the first region 1032A and the second region 1032B in which the thickness of the insulating structure 1032a described with reference to FIG. 43 changes may be modified to form a boundary region 1032br′ disposed below the edge portion of the red color filter 1070b.

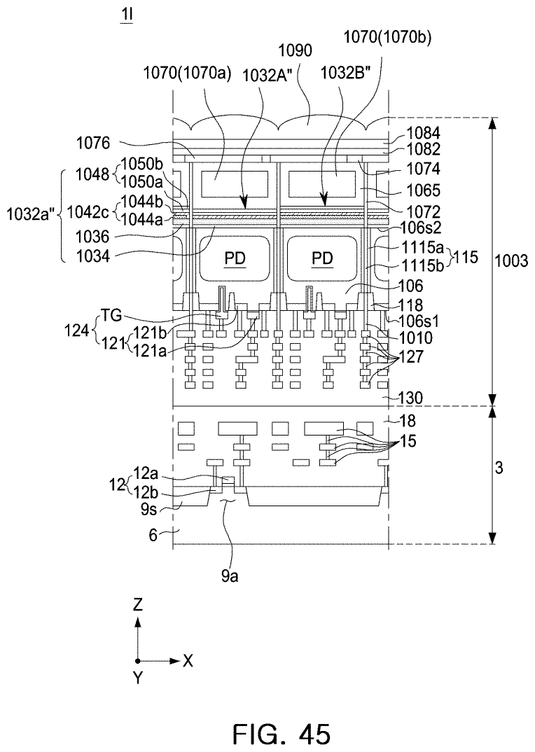

In the description below, with reference to FIG. 45, an image sensor in some example embodiments will be described.

FIG. 45 is a diagram illustrating an image sensor according to some example embodiments, viewed from above.

Referring to FIG. 45, the boundary region 1032br between the first region 1032A and the second region 1032B, in which the thickness of the insulating structure 1032a described with reference to FIG. 43 changes may be modified to not vertically overlap the color filters 1070. For example, the rear contact plugs 1072 may penetrate through the boundary region between the first region 1032A and the second region 1032B in which the thickness of the insulating structure 1032a changes.

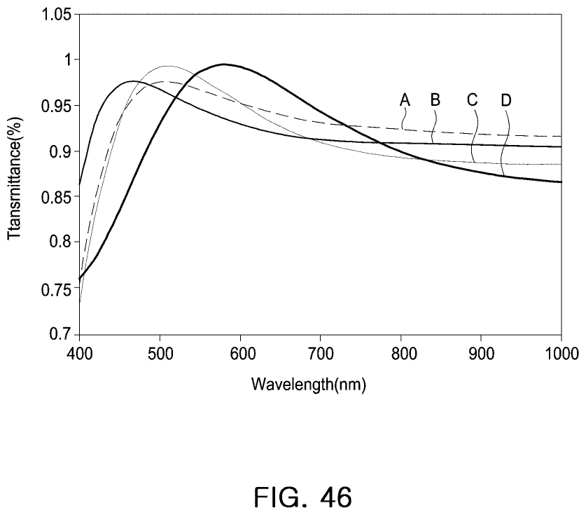

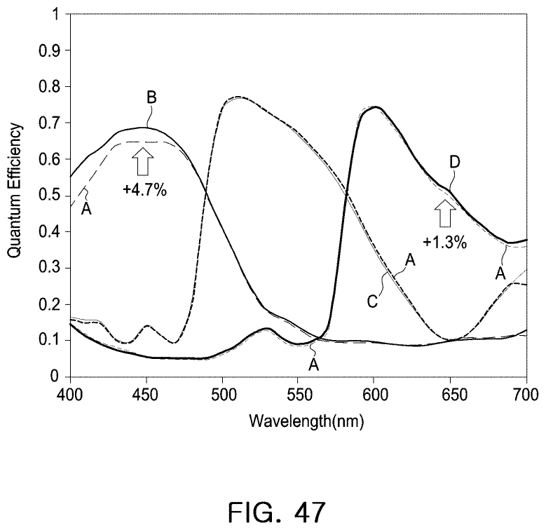

An image sensor in some example embodiments will be described with reference to FIGS. 46 and 47.

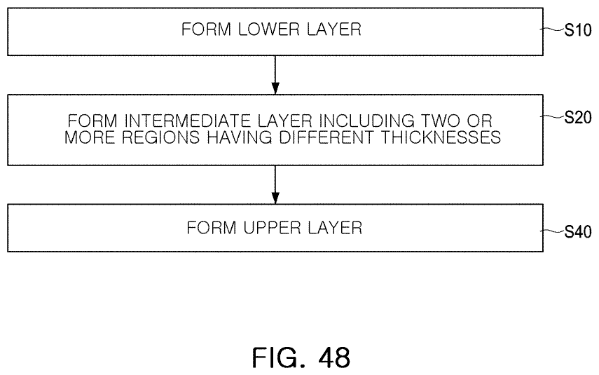

FIGS. 46 and 47 are graphs illustrating properties of an image sensor according to some example embodiments. FIG. 48 is a flowchart illustrating a method of manufacturing an image sensor according to some example embodiments.

Referring to FIGS. 46 and 47, the line A in FIG. 46 may indicate transmittance of light in the image sensor in which the thickness of the insulating structure, which may be configured as an anti-reflective layer, is constant, and the line A in FIG. 47 may indicate the amount of light absorbed by the photodiode, light which passes through an insulating structure having a constant thickness.

The line B in FIG. 46 may indicate transmittance of light passing through the first region 332A of the insulating structure 332a having a first thickness below the blue color filter 170a of the image sensor 1c described with reference to FIGS. 10 and 11, and the line B in FIG. 47 may indicate the amount of light absorbed by the photodiode PD, light which passes through the first region 332A of the insulating structure 332a having a first thickness below the blue color filter 170a of the image sensor 1c.

The line C in FIG. 46 may indicate transmittance of light passing through the second region 332B of the insulating structure 332a having a second thickness below the green color filter 170b of the image sensor 1c, and the line C in FIG. 47 may indicate the amount of light absorbed by the photodiode PD, light which passes through the second region 332B of the insulating structure 332a below the green color filter 170b of the image sensor 1c.

The line D in FIG. 46 may indicate transmittance of light passing through the third region 332C of the insulating structure 332a having a third thickness below the red color filter 170c of the image sensor 1c, and the line D in FIG. 47 may indicate the amount of light absorbed by the photodiode PD, light which passes through the third region 332C of the insulating structure 332a below the red color filter 170c of the image sensor 1c.

As in FIGS. 46 and 47, by varying the thickness of the intermediate layers 336a and 342a of the insulating structure 332a depending on positions, transmittance of light passing through the insulating structure 332a may be optimized depending on the color type of the color filters 170, and accordingly, the amount of light absorbed by the photodiode PD below the blue color filter 170a may improve by about 4.7%, and the amount of light absorbed by the photodiode PD below the red color filter 170c may improve by about 1.3%.

Accordingly, sensitivity of the image sensors in some example embodiments may improve.

Hereinafter, an example method of forming the insulating structures described with reference to FIGS. 1 to 45 will be described.

In the description below, a method of manufacturing an image sensor according to some example embodiments will be described with reference to FIG. 48.

FIG. 48 is a flowchart illustrating processes of a method of manufacturing an image sensor according to some example embodiments.

Referring to FIG. 48, in the image sensor, forming an insulating structure which may be configured as an anti-reflective layer may include forming a lower layer (S10), forming an intermediate layer including two or more regions having different thicknesses (S20), and forming an upper layer (S40).

In the description below, examples of a method of forming the insulating structures described above with reference to FIGS. 1 to 45, such as, for example, the insulating structure 132a in FIG. 2 and the insulating structure 132b in FIG. 3, will be described.

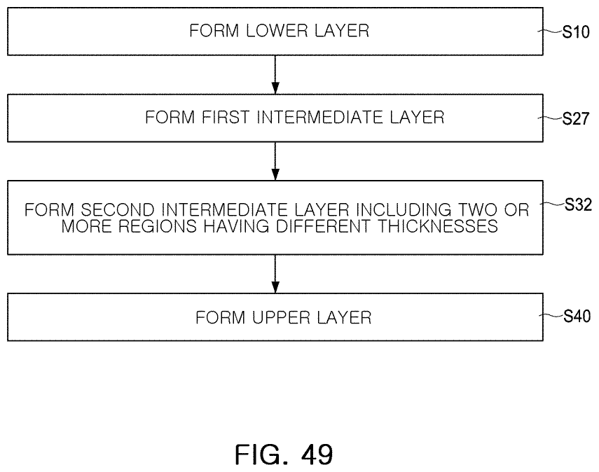

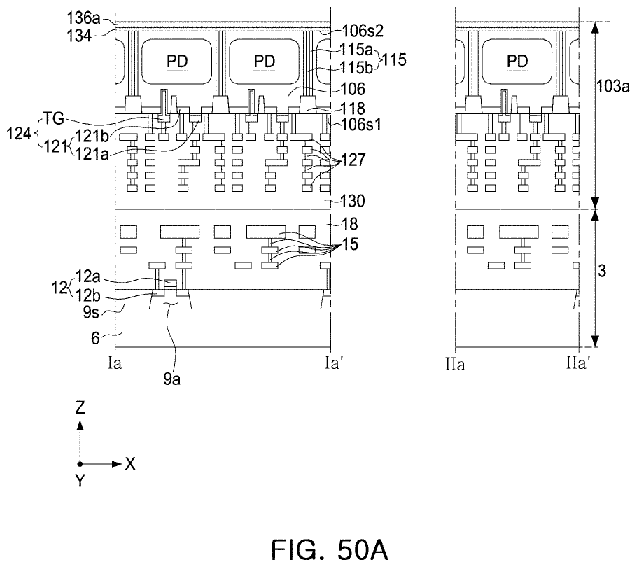

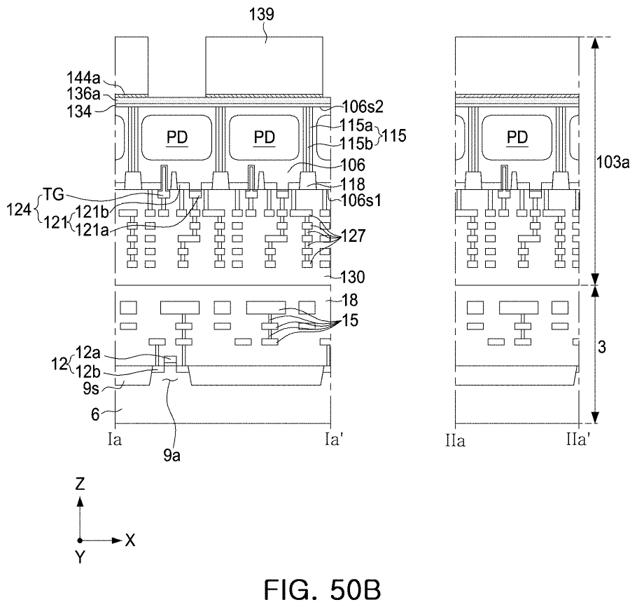

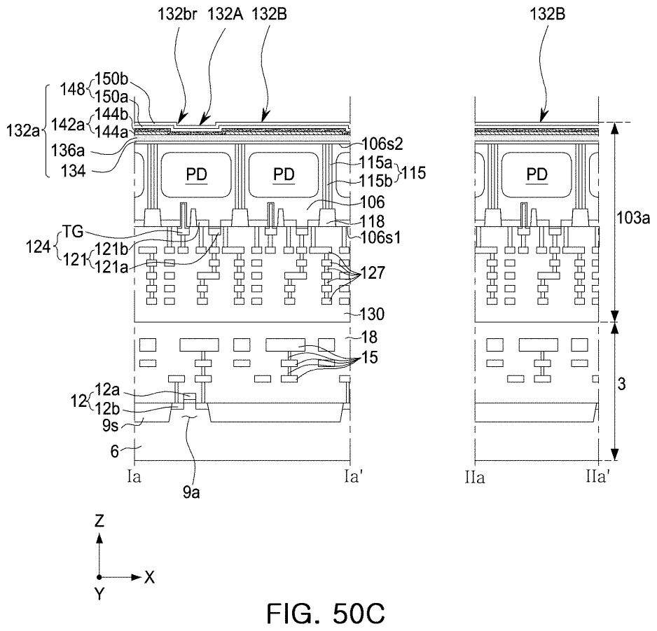

An example of a method of forming the insulating structure 132a described with reference to FIG. 2 will be described with reference to FIGS. 49 and 50A to 50C.

FIG. 49 is a flowchart illustrating an example of a method of manufacturing an image sensor according to some example embodiments, and FIGS. 50A to 50C are cross-sectional diagrams illustrating regions taken along lines Ia-Ia′ and IIa-IIa′ in FIG. 1.

Referring to FIGS. 49 and 50A, a lower layer 134 may be formed (S10). The lower layer 134 may be formed on the second surface 106s2 of the second substrate 106 (in FIG. 2).

A first intermediate layer 136a may be formed (S27). The first intermediate layer 136a may be formed on the lower layer 134.

Referring to FIGS. 49 and 50B, a first layer 144a may be formed on the first intermediate layer 136a, a mask pattern 139 having an opening may be formed on the first layer 144a, and the first layer 144a may be etched using the mask pattern 139 as an etch mask. Accordingly, the first layer 144a described with reference to FIG. 2 may be formed.

Referring to FIGS. 49 and 50C, a second layer 144b covering the first layer 144a may be formed on the first intermediate layer 136a. The first and second layers 144a and 144b may be included in the second intermediate layer 142a described with reference to FIG. 2. Accordingly, the second intermediate layer 142a including two or more regions having different thicknesses may be formed (S32).

An upper layer 148 may be formed (S40). The upper layer 148 may include a first upper layer 150a and a second upper layer 150b stacked in sequence on the second intermediate layer 142a. Accordingly, the insulating structure 132a as illustrated in FIG. 2 may be formed.

In the description below, examples of a method of forming the insulating structures described above with reference to FIGS. 1 to 45, such as, for example, the insulating structure 132a in FIG. 2 and the insulating structure 132b in FIG. 3, will be described.

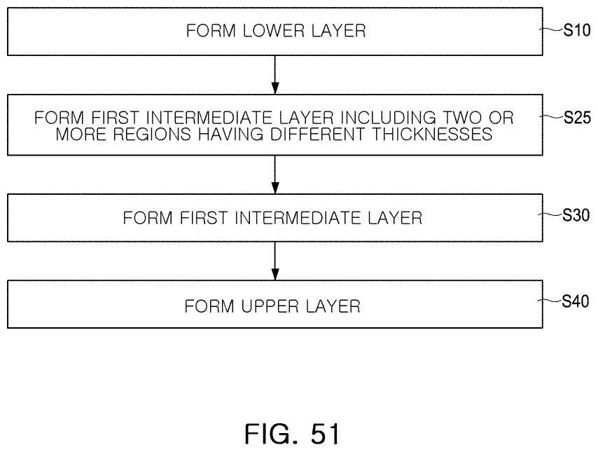

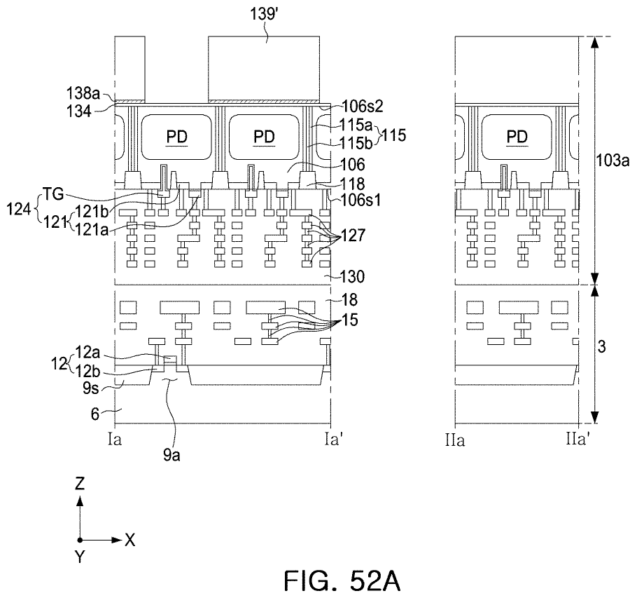

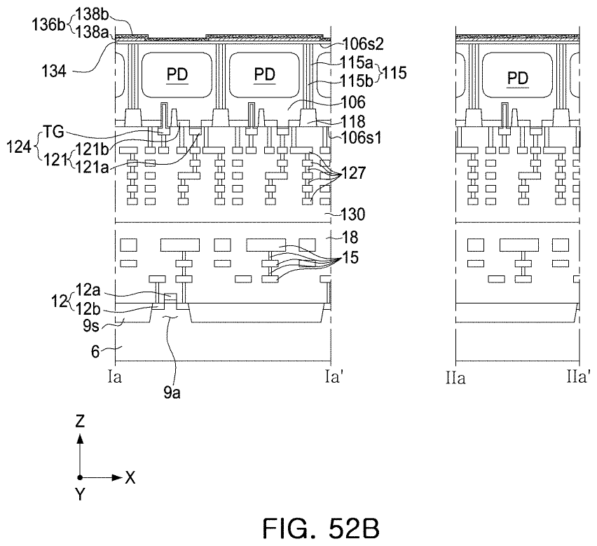

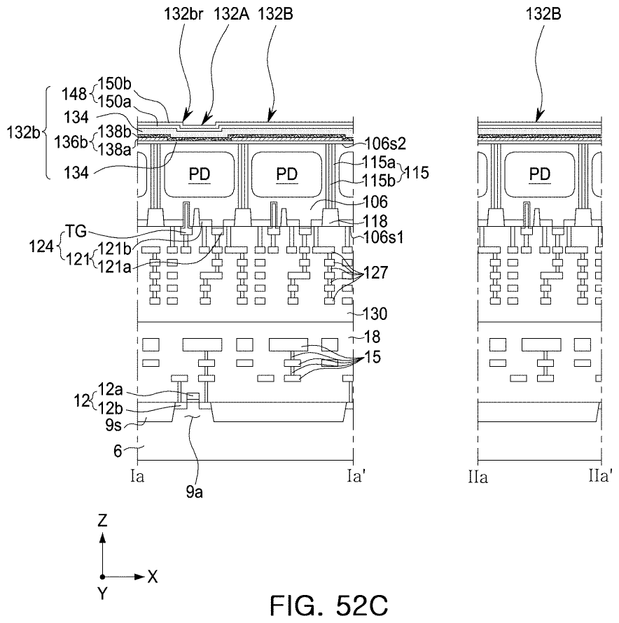

In the description below, an example of a method of forming the insulating structure 132b described with reference to FIG. 3 will be described with reference to FIGS. 51 and 52A to 52C.

FIG. 51 is a flowchart illustrating an example of a method of manufacturing an image sensor according to some example embodiments, and FIGS. 52A to 52C are cross-sectional diagrams illustrating regions taken along lines Ia-Ia′ and IIa-IIa′ in FIG. 1.

Referring to FIGS. 51 and 52A, the lower layer 134 may be formed (S10). The lower layer 134 may be formed on the second surface 106s2 of the second substrate 106 (in FIG. 2).

A first layer 138a may be formed on the lower layer 134, a mask pattern 139′ having an opening may be formed on the first layer 138a, and the first layer 138a may be etched using the mask pattern 139′ as an etch mask. Accordingly, the first layer 138a described with reference to FIG. 3 may be formed.

Referring to FIGS. 51 and 52B, a second layer 138b covering the first layer 138a may be formed on the lower layer 134. The first and second layers 138a and 138b may be included in the first intermediate layer 136b described with reference to FIG. 3. Accordingly, the first intermediate layer 136b including two or more regions having different thicknesses may be formed (S25).

Referring to FIGS. 51 and 52C, a second intermediate layer 142b may be formed on the first intermediate layer 136b (S30). An upper layer 148 may be formed (S40). The upper layer 148 may include a first upper layer 150a and a second upper layer 150b stacked in sequence on the second intermediate layer 142b. Accordingly, the insulating structure 132b as illustrated in FIG. 3 may be formed.

According to the aforementioned example embodiments, the insulating structure including the anti-reflective layer may include a plurality of layers, and an intermediate layer of the plurality of layers may include two or more regions having different thicknesses from each other. As described above, the insulating structure including the intermediate layer including two or more regions having different thicknesses may improve transmittance of light passing through the insulating structure through color filters, thereby improving sensitivity of the image sensor.

While some example embodiments have been illustrated and described above, it will be configured as apparent to those skilled in the art that modified examples and variations could be made without departing from the scope of the present inventive concepts as defined by the appended claims.

What is claimed is:

1. An image sensor, comprising:
a substrate having a first surface and a second surface opposing each other;
photodiodes in the substrate;
circuit and wiring structures below the first surface of the substrate;
an insulating structure on the second surface of the substrate;
a plurality of color filters on the insulating structure; and
a grid structure on the insulating structure,
wherein at least a portion of the grid structure is between adjacent color filters of the plurality of color filters,
wherein the plurality of color filters include a first color filter and a second color filter configured to selectively transmit light of different wavelength spectra associated with different colors,
wherein the insulating structure includes
a first region having a first thickness,
a second region having a second thickness different from the first thickness, and
a boundary region between the first region and the second region, the boundary region vertically overlapping with the first color filter and is horizontally offset from a vertical central axis of the grid structure.

2. The image sensor of claim 1, wherein, in the insulating structure, the boundary region between the first region and the second region does not vertically overlap the grid structure.

3. The image sensor of claim 1,
wherein the first thickness is smaller than the second thickness,
wherein, in the insulating structure, the first region vertically overlaps the first color filter and does not vertically overlap the second color filter,
wherein the first color filter is a blue color filter configured to selectively transmit blue light, and
wherein the second color filter is a green color filter configured to selectively transmit green light.

4. The image sensor of claim 1,
wherein the plurality of color filters further include a third color filter configured to selectively transmit a wavelength spectrum of light that is different from wavelength spectra of light selectively transmitted by either of the first color filter or the second color filter,
wherein the first color filter is a blue color filter configured to selectively transmit blue light,
wherein the second color filter is a green color filter configured to selectively transmit green light,
wherein the third color filter is a red color filter configured to selectively transmit red light, and
wherein, in the insulating structure, the first region vertically overlaps the first color filter, and the second region vertically overlaps each of the grid structure, the second color filter, and the third color filter.

5. The image sensor of claim 4, wherein each color filter of the plurality of color filters vertically overlaps two or more of the photodiodes.

6. The image sensor of claim 5, wherein the grid structure includes
a first portion between color filters configured to selectively transmit light of wavelength spectra associated with different colors among the plurality of color filters, and
a second portion crossing each color filter of the plurality of color filters in a first direction and a second direction perpendicular to the first direction.

7. The image sensor of claim 1,
wherein the plurality of color filters further include a third color filter configured to selectively transmit a wavelength spectrum of light that is different from wavelength spectra of light selectively transmitted by either of the first color filter or the second color filter,
wherein the first color filter is a blue color filter configured to selectively transmit blue light,
wherein the second color filter is a green color filter configured to selectively transmit green light,
wherein the third color filter is a red color filter configured to selectively transmit red light,
wherein the insulating structure further includes a third region having a third thickness greater than the second thickness,
wherein the first region vertically overlaps at least a portion of the first color filter,
wherein the second region vertically overlaps at least the second color filter and the grid structure, and
wherein the third region vertically overlaps at least a portion of the third color filter.

8. The image sensor of claim 7, wherein each color filter of the plurality of color filters vertically overlaps two or more of the photodiodes.

9. The image sensor of claim 8, wherein the grid structure includes
a first portion between color filters configured to selectively transmit light of wavelength spectra associated with different colors among the plurality of color filters, and
a second portion crossing each color filter of the plurality of color filters in a first direction and a second direction perpendicular to the first direction.

10. The image sensor of claim 1,
wherein the color filters further include a third color filter configured to selectively transmit a wavelength spectrum of light that is different from wavelength spectra of light selectively transmitted by either of the first color filter or the second color filter,
wherein the first color filter is a blue color filter configured to selectively transmit blue light,
wherein the second color filter is a green color filter configured to selectively transmit green light,
wherein the third color filter is a red color filter configured to selectively transmit red light,
wherein the insulating structure further includes a third region having a third thickness greater than the second thickness,
wherein the first region vertically overlaps at least a portion of the first color filter,
wherein the second region vertically overlaps at least a portion of the second color filter, and
wherein the third region vertically overlaps at least the grid structure and the third color filter.

11. The image sensor of claim 10, wherein each of the plurality of color filters vertically overlaps two or more of the photodiodes.

12. The image sensor of claim 10, wherein the grid structure includes
a first portion between color filters configured to selectively transmit light of wavelength spectra associated with different colors among the plurality of color filters, and
a second portion crossing each color filter of the plurality of color filters in a first direction and a second direction perpendicular to the first direction.

13. The image sensor of claim 1,
wherein the insulating structure includes a sequential stack of a lower layer, an intermediate layer and an upper layer,
wherein the lower layer has a substantially uniform thickness,
wherein the upper layer has a substantially uniform thickness, and
wherein the intermediate layer includes two or more regions having different thicknesses from each other.

14. An image sensor, comprising:
a substrate having a first surface and a second surface opposing each other;
photodiodes in the substrate;
circuit and wiring structures below the first surface of the substrate;
an insulating structure on the second surface of the substrate; and
a plurality of color filters on the insulating structure,
wherein the plurality of color filters include a first color filter and a second color filter configured to selectively transmit light of different wavelength spectra associated with different colors,
wherein the insulating structure includes a sequential stack of a lower layer, an intermediate layer and an upper layer,
wherein the lower layer has a substantially uniform thickness,
wherein the upper layer has a substantially uniform thickness, and
wherein the intermediate layer includes two or more regions having different thicknesses from each other.

15. The image sensor of claim 14,
wherein the intermediate layer includes a first intermediate layer and a second intermediate layer on the first intermediate layer,
wherein the first intermediate layer includes two or more regions having different thicknesses from each other, and
wherein the second intermediate layer has a substantially uniform thickness.

16. The image sensor of claim 14,
wherein the intermediate layer includes a first intermediate layer and a second intermediate layer on the first intermediate layer,
wherein the second intermediate layer includes two or more regions having different thicknesses from each other, and
wherein the first intermediate layer has a substantially uniform thickness.

17. The image sensor of claim 14,
wherein the intermediate layer includes a first intermediate layer and a second intermediate layer on the first intermediate layer;
wherein the upper layer includes at least two layers,
wherein one of the first and second intermediate layers includes two or more regions having different thicknesses from each other, and
wherein a first upper layer of the at least two layers includes the same material as a material of the lower layer, and a second upper layer of the at least two layers includes the same material as a material of the first intermediate layer.

18. The image sensor of claim 14,
wherein the substrate includes one or more inner sidewall surfaces at least partially defining an opening extending into the substrate from the second surface of the substrate,
wherein the lower layer of the insulating structure further includes a portion extending into the opening.

19. The image sensor of claim 14, wherein the second surface of the substrate has an uneven structure.

20. An image sensor, comprising:
a substrate having a first surface and a second surface opposing each other;
photodiodes in the substrate;
a separation structure between the photodiodes in the substrate;
circuit and wiring structures below the first surface of the substrate;
an insulating structure on the second surface of the substrate;
a plurality of color filters on the insulating structure; and
a grid structure on the insulating structure,
wherein at least a portion of the grid structure is between adjacent color filters of the plurality of color filters,
wherein the portion of the grid structure vertically overlaps at least a portion of the separation structure,
wherein the plurality of color filters include a blue color filter configured to selectively transmit blue light, a green color filter configured to selectively transmit green light, and a red color filter configured to selectively transmit red light,
wherein the insulating structure includes a sequential stack of a lower layer, an intermediate layer and an upper layer,
wherein the lower layer has a substantially uniform thickness,
wherein the upper layer has a substantially uniform thickness,
wherein the intermediate layer includes two or more regions having different thicknesses from each other,
wherein a minimum thickness of a first portion of the insulating structure vertically overlapping the blue color filter is smaller than a maximum thickness of a second portion of the insulating structure vertically overlapping the red color filter, and
wherein the lower surface of the grid structure is flat such that the lower surface of the grid structure at least partially defines a plane extending parallel to at least one of the first surface or the second surface of the substrate.
